(19) United States
(12) Patent Application Publication
(10) Pub. No.: US 2009/0246700 A1
(43) Pub. Date: Oct. 1, 2009

(54) PLATE-MAKING METHOD OF LITHOGRAPHIC PRINTING PLATE PRECURSOR

(76) Inventor: Koji SONOKAWA, Shizuoka (JP)

Correspondence Address: BIRCH STEWART KOLASCH & BIRCH, PO BOX 747, FALLS CHURCH, VA, 22040-0747, US

(21) Appl. No.: 12/411,200

(22) Filed: Mar. 25, 2009

(30) Foreign Application Priority Data
Mar. 26, 2008 (JP) P2008-082234

(51) Int. Cl. G03F 7/00

(52) U.S. Cl. 430/302

(57) ABSTRACT

A plate-making method of a lithographic printing plate precursor including an image forming layer and a support, includes: (a) a step of preparing a lithographic printing plate precursor containing, in the image forming layer, an infrared absorber, a polymerization initiator, a polymerizable compound, a hydrophobic binder polymer and a compound represented by the formula (1) or (2) as defined herein; (b) a step of imagewise exposing the lithographic printing plate precursor; and (C) a step of developing the exposed lithographic printing plate precursor with an aqueous solution containing at least one water-soluble polymer selected from the group consisting of gum arabic and starch with an automatic processor equipped with a rubbing member.

### CROSS-REFERENCE TO RELATED APPLICATIONS

This application claims the benefit of Japanese Patent Application JP 2008-082234, filed Mar. 26, 2008, the entire content of which is hereby incorporated by reference, the same as if set forth at length.

### FIELD OF THE INVENTION

The present invention relates to a plate-making method using a lithographic printing plate precursor. More specifically, the present invention relates to a plate-making method using a lithographic printing plate precursor capable of preventing a component removed by development from reattaching to the plate surface and suitable for obtaining a good printing performance.

### BACKGROUND OF THE INVENTION

The lithographic printing plate generally consists of a lipophilic (oleophilic) image part of receiving an ink in the printing process and a hydrophilic non-image part of receiving a fountain solution. The lithographic printing is a printing method where the attachment of ink to the surface of a lithographic printing plate is made to differ between the ink-receiving part assigned to the lipophilic image part of the lithographic printing plate and the fountain solution-receiving part (ink non-receiving part) assigned to the hydrophilic non-image part by utilizing the property of water and printing ink repelling each other and after inking only the image part, the ink is transferred to a printing material such as paper.

For producing such a lithographic printing plate, a lithographic printing plate precursor (PS plate) comprising a hydrophilic support having provided thereon a lipophilic photosensitive resin layer (photosensitive layer, image forming layer) has been heretofore widely used. Usually, a lithographic printing plate is obtained by a plate-making method of exposing the lithographic printing plate precursor through an original image such as lith film, and dissolving and removing the image forming layer in the unnecessary portion working out to a non-image part with a strongly alkaline developer at a pH of 12 or more or an organic solvent-containing developer to reveal the hydrophilic support surface and thereby form a non-image part, while leaving the image forming layer in the portion working out to an image part.

In the plate-making process using a conventional lithographic printing plate precursor, a step of dissolving and removing the unnecessary image forming layer with a developer or the like must be provided after exposure but as one of problems to be solved, simplification of such an additive wet processing is demanded. In particular, the treatment of a waste solution discharged in the course of processing with a high pH alkali developer is recently a great concern to the entire industry in view of consideration for global environment, and it is strongly demanded as one of means for simplification that development can be effected with a nearly neutral aqueous solution.

On the other hand, a digitization technique of electronically processing, storing and outputting image information by using a computer has been recently widespread and various new image-output systems coping with such a digitization technique have been put into practical use. Along with this trend, a computer-to-plate technique is attracting attention, where digitized image information is carried on a highly converging radiant ray such as laser light and a lithographic printing plate precursor is scan-exposed by this light to directly produce a lithographic printing plate without intervention of a lith film. Accordingly, one of important technical problems to be solved is to obtain a lithographic printing plate precursor suited for such a technique.

In the case of performing such a simplified plate-making operation in a printing environment, since the image forming layer after exposure may be fogged in a bright room of the printing environment until development, an image forming layer and a light source, which can be handled in a bright room or under a yellow lamp, are required.

As for such a laser light source, a solid laser of emitting an infrared ray at a wavelength of 760 to 1,200 nm, such as semiconductor laser and YAG laser, is very useful, because a high-output and compact laser becomes available at a low cost. A UV laser may also be used.

Under these circumstances, adaptability of the plate-making operation to both simplification and digitization is being strongly demanded at present than ever before.

To meet such a requirement, for example, European Patent 1,342,568 describes a plate-making method of developing a lithographic printing plate precursor having an image forming layer on a hydrophilic support with a gum solution, where the image forming layer contains hydrophobic thermoplastic polymer particles dispersed in a hydrophilic binder. In this plate-making method, after the lithographic printing plate precursor is imagewise exposed using an infrared laser to fuse the hydrophobic thermoplastic polymer particles and thereby form an image, development can be performed by removing the unexposed area with a gum solution.

However, the method of developing a lithographic printing plate precursor subjected to image formation by thermal fusion of fine particles with a gum solution has a problem that the sensitivity or press life is low and fine particles in the unexposed area removed readily undergo aggregation or precipitation in the developer, allowing the component removed by development to reattach to the plate surface after development processing and cause ink staining.

International Publication No. 05/111727 describes a method for processing a lithographic printing plate precursor, comprising imagewise exposing a lithographic printing plate precursor comprising (i) a hydrophilic support and (ii) a photosensitive layer containing a radical polymerizable ethylenically unsaturated monomer, a radical polymerization initiator and an infrared absorbing dye, with an infrared laser, and removing the uncured portion of the photosensitive layer with a gum solution. U.S. Pat. No. 6,902,865 describes a method for developing a lithographic printing plate precursor, comprising curing a radical polymerization-type photosensitive layer by infrared laser exposure and removing the unexposed area with an aqueous developer at a pH or 2 to 10. Also, JP-A-2006-106700 (the term “JP-A” as used herein means an “unexamined published Japanese patent application”) describes a method for developing a lithographic printing plate precursor, comprising curing a radical polymerization-type photosensitive layer containing a hydrophobic binder polymer by infrared laser exposure and developing the plate with an aqueous solution containing a surfactant. In these methods, the sensitivity is high because radical polymerization is used for the image formation, and above all, in the method using a hydrophobic binder polymer, the press life is also high, but use of a hydrophobic binder polymer is still burdened with a problem that the component removed by development undergoes aggregation and precipitation in the developer and reattaches to the plate surface after the development processing, giving rise to generation of ink staining.

In addition, use of a hydrophobic binder polymer also raises a problem that developability with an aqueous developer at a pH of 2 to 10 deteriorates. To solve such a problem, as described in JP-A-2007-276454 which is related to an on-press developable lithographic printing plate, the developability may be enhanced by adding a low-molecular hydrophilic compound, but this technique has a problem that the image part surface becomes excessively hydrophilic and inking property deteriorates.

### SUMMARY OF THE INVENTION

Accordingly, an object of the present invention is to provide a plate-making method using a lithographic printing plate precursor, which can prevent a component removed by development from reattaching to the plate surface while maintaining good developability and is suited for obtaining good inking property and good press life.

As a result of various studies to solve those problems, the present inventors have found that when a hydrophobic binder polymer and a specific carboxylic acid compound are contained in the image forming layer and an aqueous solution containing a specific water-soluble polymer is used as the developer, the above-described object can be obtained. The present invention has been accomplished based on this finding.

That is, the present invention is as follows.

1. A plate-making method using a lithographic printing plate precursor having an image forming layer on a support, comprising the following steps:

(a) a step of preparing a lithographic printing plate precursor containing, in the image forming layer, an infrared absorber, a polymerization initiator, a polymerizable compound, a hydrophobic binder polymer and a compound represented by the following formula (1) or (2),

(b) a step of imagewise exposing the lithographic printing plate precursor, and

(C) a step of developing the exposed lithographic printing plate precursor with an aqueous solution containing at least one water-soluble polymer selected from the group consisting of gum arabic and starch by using an automatic processor equipped with a rubbing member:

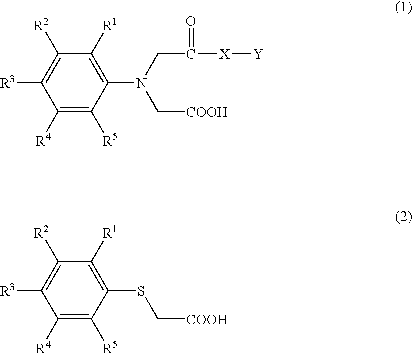

wherein R¹ to R⁵ each independently represents a hydrogen atom, an alkyl group having a carbon number of 1 to 6, an alkoxy group having a carbon number of 1 to 6, a phenyl group, a halogen atom, an amino group or a nitro group, each of these groups may be partially substituted by an alkyl group having a carbon number of 4 or less or a hydroxyl group, at least two members out of R¹ to R⁵ may combine to form an aliphatic or aromatic ring, X represents —O— or —NH—, Y represents a hydrogen atom, an alkyl group having a carbon number of 1 to 6, a phenyl group or a benzyl group, and each of these groups may be partially substituted by an alkyl group having a carbon number of 4 or less or a hydroxyl group.

2. The plate-making method using a lithographic printing plate precursor as described in 1, wherein the carboxylic acid compound represented by formula (1) or (2) is at least one compound selected from the group consisting of N-phenyliminodiacetic acid, monomethyl N-phenyliminodiacetate, N-phenyliminodiacetic acid monoanilide and (3,4-dimethoxyphenylthio)acetic acid.

3. The plate-making method using a lithographic printing plate precursor as described in 1 or 2, wherein the water-soluble polymer-containing aqueous solution has a pH of 2 to 9.8.

4. The plate-making method using a lithographic printing plate precursor as described in any one of 1 to 3, wherein the water-soluble polymer-containing aqueous solution contains at least gum arabic.

5. The plate-making method using a lithographic printing plate precursor as described in any one of 1 to 4, wherein the step (c) is continuously performed two or more times.

6. The plate-making method using a lithographic printing plate precursor as described in any one of 1 to 5, which further comprises (d) a step of water-washing the surface of the developed lithographic printing plate after the step (c).

7. The plate-making method using a lithographic printing plate precursor as described in any one of 1 to 6, wherein the water-soluble polymer-containing aqueous solution used in the step (c) is used repeatedly by passing the solution through a filter.

8. The plate-making method using a lithographic printing plate precursor as described in any one of 1 to 7, wherein the infrared absorber is a cyanine dye and the polymerization initiator is an onium salt.

9. The plate-making method using a lithographic printing plate precursor as described in any one of 1 to 8, wherein the lithographic printing plate precursor has a protective layer on the image forming layer and the protective layer contains an anion-modified polyvinyl alcohol in an amount of 10 to 50 mass % based on the entire solid content of the protective layer.

10. The plate-making method using a lithographic printing plate precursor as described in any one of 1 to 9, wherein the lithographic printing plate precursor has an undercoat layer containing a compound having a substrate-adsorbing group and a crosslinking group within the molecule, between the support and the image forming layer.

11. The plate-making method using a lithographic printing plate precursor as described in any one of 1 to 10, wherein the lithographic printing plate precursor has a support treated by anodization with a phosphoric acid.

12. The plate-making method using a lithographic printing plate precursor as described in any one of 1 to 11, wherein the lithographic printing plate precursor has a support hydrophilic-treated with a polyvinylsulfonic acid.

In the present invention, a lithographic printing plate precursor containing a specific carboxylic acid represented by formula (1) or (2) in the image forming layer is used and the plate is developed with an aqueous solution containing a water-soluble polymer, whereby the above-described problems could be solved.

The mechanism of bringing out the effects of the present invention is considered as follows. That is, the specific carboxylic acid exhibits good compatibility with the hydrophobic binder by virtue of having a phenyl group or the like and when removed by development in this state, a good affinity is produced between the specific water-soluble polymer in the developer and the component removed by development, as a result, the removed component is presumed to scarcely undergo aggregation and precipitation and be prevented from reattaching to the plate surface.

Also, the specific carboxylic acid is considered to disappear resulting from decarboxylation upon exposure, that is, in the unexposed area, contribute to enhancement of the developability by introducing a hydrophilic moiety into a bulk structure containing a hydrophobic binder as the main component, while contributing, in the exposed area, to enhancement of the inking property on the image part surface which is made hydrophobic by the decarboxylation above.

According to the present invention, a plate-making method using a lithographic printing plate precursor, which allows processing with a relatively neutral developer instead of a high pH alkali developer after exposure and is capable of preventing a component removed by development from reattaching to the plate surface and suitable for obtaining good inking property and good press life, can be provided.

### BRIEF DESCRIPTION OF THE DRAWINGS

FIG. 1 is a view showing the construction of the automatic developing apparatus for a lithographic printing plate according to the present invention.

FIG. 2 is a view showing the construction of the automatic developing apparatus only with a developing part according to the present invention.

### DESCRIPTION OF REFERENCE NUMERALS AND SIGNS

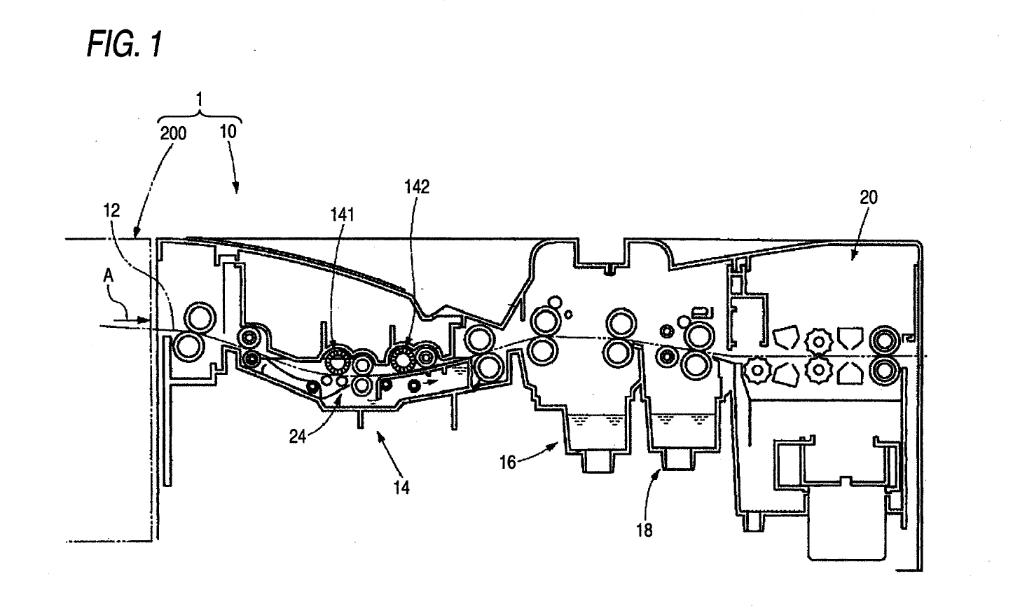

### (FIG. 1)

1: Automatic developing apparatus
10: Development processing part
12: Printing plate
14: Developing part
16: Water washing part
18: Desensitization processing part
20: Drying part
24: Developing tank
141, 142: Brush roller (rubbing member)
200: Preprocessing part

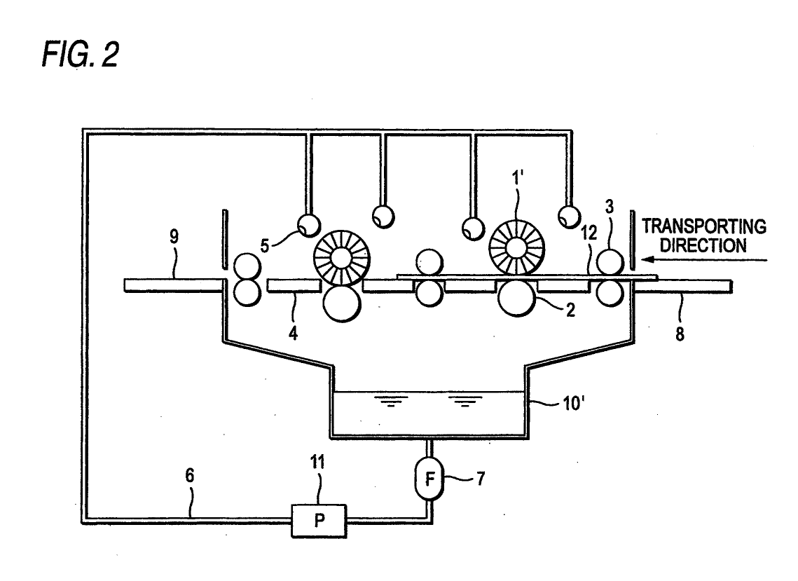

### (FIG. 2)

1′: Rotating brush roller
2: Backing roller
3: Conveying roller
4: Conveying guide plate
5: Spray pipe
6: Pipe line
7: Filter
8: Plate supply table
9: Plate discharge table
10′: Developer tank
11: Circulating pump
12: Plate

### DETAILED DESCRIPTION OF THE INVENTION

### Plate-Making Method

The method for producing a lithographic printing plate of the present invention comprises, after imagewise exposure, performing a treatment for desensitization simultaneously with removal of the unexposed area of the image forming layer by using an aqueous solution containing at least one water-soluble polymer selected from the group consisting of gum arabic and starch (hereinafter referred to as “the developer of the present invention”). The desensitization is effected by the at least one water-soluble polymer selected from the group consisting of gum arabic and starch.

The starch for use in the developer of the present invention includes sweet potato starch, potato starch, tapioca starch, wheat starch, corn starch and derivatives of these starches.

As for the starch derivative, a roast starch such as British gum, an enzymatically modified dextrin such as enzyme dextrin and Shardinger dextrin, an oxidized starch such as solubilized starch, an alphatized starch such as modified alphatized starch and unmodified alphatized starch, and esterified starch such as starch phosphate, starch of fatty acid, starch sulfate, starch nitrate, starch xanthate and starch carbamate, an etherified starch such as carboxyalkyl starch, hydroxyalkyl starch, sulfoalkyl starch, cyanoethyl starch, allyl starch, benzyl starch, carbamylethyl starch and dialkylamino starch, a crosslinked starch such as methylol crosslinked starch, hydroxyalkyl crosslinked starch, phosphoric acid crosslinked starch and dicarboxylic acid crosslinked starch, and a starch graft copolymer such as starch-polyacrylamide copolymer, starch-polyacrylic acid copolymer, starch-polyvinyl acetate copolymer, starch-polyacrylonitrile copolymer, cationic starch-polyacrylic acid ester copolymer, cationic starch-polyvinyl copolymer, starch-polystyrene-maleic acid copolymer, starch-polyethylene oxide copolymer and starch-polypropylene copolymer are preferred.

Among these water-soluble polymers, gum arabic is most preferred.

Two or more kinds of these water-soluble polymers may be used in combination, and the developer for use in the present invention may contain the water-soluble polymer in an amount of preferably from 1 to 50 mass %, more preferably from 3 to 30 mass %.

The developer for use in the present invention is advantageously used at a pH of 2 to 9.8, more preferably at a pH of 3 to 9.5, still more preferably at a pH or 3.5 to 8.

In order to adjust the pH to this range, a pH adjusting agent is generally added. For adjusting the developer to a pH of 2 to 9.8, a mineral acid, an organic acid, an inorganic salt or the like is generally added to the gum solution. The amount added thereof is from 0.01 to 2 mass %. Examples of the mineral acid include nitric acid, sulfuric acid, phosphoric acid and metaphosphoric acid. Examples of the organic acid include acetic acid, oxalic acid, malonic acid, p-toluenesulfonic acid, levulinic acid, phytic acid, an organic phosphonic acid, polystyrenesulfonic acid, and an amino acid such as glycine, α-alanine and β-alanine. Examples of the inorganic salt include magnesium nitrate, sodium primary phosphate, sodium secondary phosphate, nickel sulfate, sodium hexametaphosphate and sodium tripolyphosphate. At least one of these mineral acids, organic acids, inorganic salts and the like may be used, or two or more thereof may be used in combination.

The developer for use in the present invention may contain, for example, a surfactant, an antiseptic agent, an antifungal, a lipophilic substance, a wetting agent, a chelating agent and a defoaming agent, in addition to the water-soluble polymer and pH adjusting agent described above.

The surfactant contained in the developer of the present invention includes an anionic surfactant, a cationic surfactant, an amphoteric surfactant and a nonionic surfactant. Examples of the anionic surfactant include fatty acid salts, abietates, hydroxyalkanesulfonates, alkanesulfonates, α-olefinsulfonates, dialkylsulfosuccinates, alkyldiphenyl ether disulfonates, linear alkylbenzenesulfonates, branched alkyl-benzenesulfonates, alkylnaphthalenesulfonates, alkyl-phenoxypolyoxyethylenepropylsulfonates, polyoxyethylenealkylsulfophenyl ether salts, N-methyl-N-oleyltaurine sodium salts, monoamide disodium N-alkylsulfosuccinates, petroleum sulfonates, sulfated castor oil, sulfated beef tallow oil, sulfuric ester salts of fatty acid alkyl ester, alkylsulfuric ester salts, polyoxyethylene alkyl ether sulfuric ester salts, fatty acid monoglyceride sulfuric ester salts, polyoxyethylene alkylphenyl ether sulfuric ester salts, polyoxyethylene styrylphenyl ether sulfuric ester salts, alkylphosphoric ester salts, polyoxyethylene alkyl ether phosphoric ester salts, polyoxyethylene alkylphenyl ether phosphoric ester salts, partially saponified styrene/maleic anhydride copolymers, partially saponified olefin/maleic anhydride copolymers, and naphthalenesulfonate formalin condensates. Among these, dialkylsulfosuccinates, alkylsulfuric ester salts, alkylnaphthalenesulfonates, α-olefinsulfonates and alkyldiphenyl ether disulfonates are preferred.

Examples of the cationic surfactant which can be used include alkylamine salts and quaternary ammonium salts.

Examples of the amphoteric surfactant which can be used include alkylcarboxybetaines, alkylimidazolines and alkylaminocarboxylic acids.

Examples of the nonionic surfactant include polyoxyethylene alkyl ethers, polyoxyethylene alkylphenyl ethers, polyoxyethylene polystyrylphenyl ethers, polyoxyethylene polyoxypropylene alkyl ethers, glycerin fatty acid partial esters, sorbitan fatty acid partial esters, pentaerythritol fatty acid partial esters, propylene glycol monofatty acid esters, sucrose fatty acid partial esters, polyoxyethylene sorbitan fatty acid partial esters, polyoxyethylene sorbitol fatty acid partial esters, polyethylene glycol fatty acid esters, polyglycerin fatty acid partial esters, polyoxyethylenated castor oils, polyoxyethylene glycerin fatty acid partial esters, fatty acid diethanolamides, N,N-bis-2-hydroxyalkylamines, polyoxyethylene alkylamines, triethanolamine fatty acid esters, trialkylamine oxides, polypropylene glycol having a molecular weight of 200 to 5,000, trimethylolpropane, a polyoxyethylene or polyoxypropylene adduct of glycerin or sorbitol, and acetylene glycol. A fluorine-containing or silicon-containing nonionic surfactant may also be similarly used.

Two or more kinds of these surfactants may be used in combination. The amount of the surfactant used is not particularly limited and is preferably from 0.01 to 20 mass %, more preferably from 0.05 to 10 mass %, based on the total mass of the developer for use in the present invention.

As for the antiseptic, those known and used in the fields of fiber, wood processing, food, medicine, cosmetic, agriculture and the like can be employed. Examples of the known antiseptic which can be used include a quaternary ammonium salt, a monovalent phenol derivative, a divalent phenol derivative, a polyvalent phenol derivative, an imidazole derivative, a pyrazolopyrimidine derivative, a monovalent naphthol, carbonates, a sulfone derivative, an organic tin compound, a cyclopentane derivative, a phenyl derivative, a phenol ether derivative, a phenol ester derivative, a hydroxylamine derivative, a nitrile derivative, naphthalenes, a pyrrole derivative, a quinoline derivative, a benzothiazole derivative, a secondary amine, a 1,3,5-triazine derivative, a thiadiazole derivative, an anilide derivative, a pyrrole derivative, a halogen derivative, a dihydric alcohol derivative, dithiols, a cyanic acid derivative, a thiocarbamide acid derivative, a diamine derivative, an isothiazole derivative, a monohydric alcohol, a saturated aldehyde, an unsaturated monocarboxylic acid, a saturated ether, an unsaturated ether, lactones, an amino acid derivative, hydantoin, a cyanuric acid derivative, a guanidine derivative, a pyridine derivative, a saturated monocarboxylic acid, a benzenecarboxylic acid derivative, a hydroxycarboxylic acid derivative, biphenyl, a hydroxamic acid derivative, an aromatic alcohol, a halogenophenol derivative, a benzenecarboxylic acid derivative, a mercaptocarboxylic acid derivative, a quaternary ammonium salt derivative, a triphenylmethane derivative, hinokitiol, a furan derivative, a benzofuran derivative, an acridine derivative, an isoquinoline derivative, an arsine derivative, a thiocarbamic acid derivative, a phosphoric acid ester, a halogenobenzene derivative, a quinone derivative, a benzenesulfonic acid derivative, a monoamine derivative, an organic phosphoric acid ester, a piperazine derivative, a phenazine derivative, a pyrimidine derivative, a thiophanate derivative, an imidazoline derivative, an isoxazole derivative and an ammonium salt derivative. Above all, preferred antiseptics are a salt of pyridinethiol-1-oxide, salicylic acid and a salt thereof, 1,3,5-trishydroxyethylhexahydro-S-triazine, 1,3,5-trishydroxymethylhexahydro-S-triazine, 1,2-benzisothiazolin-3-one, 5-chloro-2-methyl-4-isothiazolin-3-one and 2-bromo-2-nitro-1,3-propanediol. The amount of the antiseptic added is preferably an amount large enough to be stably effective against bacterium, mold, yeast or the like and although depending on the kind of bacterium, mold, yeast or the like, the amount added is preferably from 0.01 to 4 mass % based on the developer of the present invention in use. Also, two or more kinds of antiseptics may be preferably used in combination to effectively work against various kinds of molds and bacteria.

The developer for use in the present invention may also contain a lipophilic substance. Preferable examples of the lipophilic substance include an organic carboxylic acid having a carbon number of 5 to 25, such as oleic acid, lanolin acid, valeric acid, nonylic acid, capric acid, myristic acid and palmitic acid, and a castor oil. One of these lipophilic substances may be used alone, or two or more thereof may be used in combination. The content of the lipophilic substance in the developer for use in the present invention is from 0.005 to 10 mass %, preferably from 0.05 to 5 mass %, based on the total mass of the developer.

In addition, a wetting agent such as glycerin, ethylene glycol, propylene glycol, triethylene glycol, butylene glycol, hexylene glycol, diethylene glycol, dipropylene glycol, glycerin, trimethylol propane, diglycerin or polyoxyethylene may be added, if desired, to the developer for use in the present invention. One of these wetting agents may be used alone, or two or more thereof may be used in combination. The amount of the wetting agent used is preferably from 0.1 to 5 mass %.

Also, a chelating compound may be added to the developer for use in the present invention. The developer for use in the present invention is, similarly to the normal developer, distributed or marketed as a concentrated solution and is diluted in use by adding tap water, well water or the like. Calcium ion or the like contained in the tap water or well water used for dilution adversely affects the printing and may give rise to easy staining of the printed material. This problem can be solved by adding a chelating compound. Preferable examples of the chelating compound include organic phosphonic acids and phosphonoalkane tricarboxylic acids, such as ethylene-diaminetetraacetic acid and its potassium and sodium salts; diethylenetriaminepentaacetic acid and its potassium and sodium salts; triethylenetetraminehexaacetic acid and its potassium and sodium salts; hydroxyethylethylenediaminetriacetic acid and its potassium and sodium salts; nitrilotriacetic acid and its sodium salt; 1-hydroxyethane-1,1-diphosphonic acid and its potassium and sodium salts; aminotri(methylenephosphonic acid) and its potassium and sodium salts. In place of the sodium and potassium salts of these chelating agents, organic amine salts are also effective. As for the chelating agent, a compound which is stably present in the developer composition for use in the present invention and does not inhibit printing is selected. The amount of the chelating compound added is suitably from 0.001 to 1.0 mass % based on the developer of the present invention in use.

In the developer for use in the present invention, a defoaming agent may also be added. In particular, a silicon defoaming agent is preferred. The silicone defoaming agent may be, for example, either an emulsion dispersion type or a solubilization type. The amount of the defoaming agent added is optimally from 0.001 to 1.0 mass % based on the developer of the present invention in use.

The developer for use in the present invention may also be prepared as an emulsion dispersion type, and an organic solvent is used for the oil phase. Alternatively, the developer may be prepared as a solubilization type (emulsification type) by the aid of a surfactant described above.

The organic solvent is preferably an organic solvent having solubility of 5 mass % or less in water at 20° C. and a boiling point of 160° C. or more. The organic solvent includes a plasticizer having a solidification point of 15° C. or less and a boiling point of 300° C. or more at 1 atm pressure, and examples thereof include phthalic acid diesters such as dibutyl phthalate, diheptyl phthalate, di-n-octyl phthalate, di(2-ethylhexyl)phthalate, dinonyl phthalate, didecyl phthalate, dilauryl phthalate and butyl benzyl phthalate, aliphatic dibasic acid esters such as dioctyl adipate, butyl glycol adipate, dioctyl azelate, dibutyl sebacate, di(2-ethylhexyl)sebacate and dioctyl sebacate, epoxidized triglycerides such as epoxidized soybean oil, phosphates such as tricresyl phosphate, trioctyl phosphate and trischloroethyl phosphate, and benzoic acid esters such as benzyl benzoate.

Other examples include an alcohol-based organic solvent such as 2-octanol, 2-ethylhexanol, nonanol, n-decanol, undecanol, n-dodecanol, trimethylnonyl alcohol, tetradecanol and benzyl alcohol, and a glycol-based organic solvent such as ethylene glycol isoamyl ether, ethylene glycol monophenyl ether, ethylene glycol benzyl ether, ethylene glycol hexyl ether and octylene glycol.

The condition that is taken into account when selecting the compound includes odor in particular. The amount of such a solvent used is preferably from 0.1 to 5 mass %, more preferably from 0.5 to 3 mass %, based on the plate surface protective agent. One kind of these solvents may be used, or two or more kinds thereof may be used in combination.

In regards to the developer for use in the present invention, as long as the water-soluble polymer specified in the present invention is contained, the gum solutions described in European Patent No. 1,342,568 and EP-A-1788444 may also be suitably used.

The developer for use in the present invention is produced by preparing an aqueous phase at a temperature of 40° C.±5° C., stirring the aqueous phase at a high speed, gradually adding dropwise an oil phase prepared to the aqueous phase, and after thorough stirring, emulsion-dispersing the phase mixture through a pressure homogenizer.

The balance component of the developer for use in the present invention is water. It is advantageous in view of transportation that the developer for use in the present invention is prepared as a concentrated solution having a smaller content of water than in use and is diluted with water in use. In this case, the concentration degree is suitably to such an extent as causing no separation or no precipitation of each component.

The development processing in the present invention is preformed using an automatic processor equipped with a rubbing member. Furthermore, the development processing in the present invention can be suitably preformed using an automatic processor equipped with means for supplying the developer or the like of the present invention. Examples of the automatic processor include an automatic processor described in JP-A-2006-235227, where a rubbing treatment is performed while conveying a lithographic printing plate precursor after image recording. Above all, an automatic processor using a rotating brush roller as the rubbing member is preferred.

The rotating brush roller which can be preferably used in the present invention can be appropriately selected by taking into account, for example, scratch resistance of the image part and flexible strength of the support of the lithographic printing plate precursor.

As for the rotating brush roller, a known rotating brush roller produced by implanting a brush material in a plastic or metal roller can be used. For example, a rotating brush roller described in JP-A-58-159533 and JP-A-3-100554, or a brush roller described in JP-UM-B-62-167253 (the term “JP-UM-B” as used herein means an “examined Japanese utility model publication”), in which a metal or plastic groove-type member having implanted therein a brush material in rows is gaplessly and radially wound around a plastic or metal roller acting as a core, can be used.

The usable brush material is a plastic fiber (for example, a polyester-based synthetic fiber such as polyethylene terephthalate or polybutylene terephthalate, a polyamide-based synthetic fiber such as nylon 6.6 or nylon 6.10, a polyacrylic synthetic fiber such as polyacrylonitrile or polyalkyl (meth)acrylate, or a polyolefin-based synthetic fiber such as polypropylene or polystyrene). For example, a brush material having a fiber bristle diameter of 20 to 400 μm and a bristle length of 5 to 30 mm can be suitably used.

The outer diameter of the rotating brush roller is preferably from 30 to 200 mm, and the peripheral velocity at the tip of the brush rubbing the plate surface is preferably from 0.1 to 5 m/sec.

The rotational direction of the rotating brush roller for use in the present invention may be the same direction or the opposite direction with respect to the conveying direction of the lithographic printing plate precursor of the present invention, but in the case of using two or more rotating brush rollers as in the automatic processor illustrated in FIG. 1, it is preferred that at least one rotating brush roller rotates in the same direction and at least one rotating brush roller rotates in the opposite direction. By such arrangement, the image forming layer in the unexposed area can be more unfailingly removed. Furthermore, a technique of rocking the rotating brush roller in the rotation axis direction of the brush roller is also effective.

As for the plate-making method of the present invention, a method of continuously performing the step (c) two or more times is also suitable. Specific examples of the method of continuously performing the development processing two or more times include a method of repeatedly performing the development processing two or more times by using an automatic processor comprising only a developing part equipped with a rubbing member described above (see, FIG. 2) (in this case, the development processing may performed by connecting two or more units of the automatic developing machine), and a method of using an automatic processor having a plurality of developing parts equipped with a rubbing member described above.

In another preferred embodiment of the plate-making method of the present invention, a water washing step may be performed subsequently to the development step using the developer for use in the present invention. By performing the water washing step, the component removed by development is more successfully prevented from reattaching to the plate surface.

As for the water used in the water washing step of the present invention, any water in general, such as tap water, well water, ion-exchanged water or distilled water, may be used, but from the economical standpoint, tap water or well water is preferred. For the water used in the water washing step, it is preferred to always use fresh water or reuse the water used in the water washing step by circulating it through a filter described later.

As to the developer for use in the present invention, a fresh developer may be always used, but the developer of the present invention after the development processing is preferably used repeatedly by circulating it through a filter.

The filter employed in the development step using the developer of the present invention as well as in the water washing step may be any filter as long as it can filter out the image forming layer component that is removed and mixed in each solution. Preferred examples of the material for the filter include a polyester resin, a polypropylene resin, a polyethylene resin, a cellulose resin and cotton. The filter is preferably an exchangeable filter that is housed in the form of a cartridge in a housing. The cartridge is preferably a pleat type obtained by subjecting a cellulose fiber-made filter paper to finishing with epoxy resin so as to reinforce the strength or prevent separation of fibers and then to shaping into a pleat form for increasing the filtration area; a depth type obtained by winding a yarn (fiber bundle) comprising many fibers to obtain a gradual density gradient from a center cylinder; or an adsorption type obtained by loading an adsorbent such as activated carbon onto a medium composed mainly of a resin, a cellulose, a glass fiber and a water-absorptive polymer. As for the adsorbent, a material selected from silica gel, activated carbon, activated aluminum, molecular sieve, clay, superabsorbent fiber, calcium carbonate, calcium sulfate, potassium permanganate, sodium carbonate, potassium carbonate, sodium phosphate and activated metal, or an ion-exchanger used for various filters, may be employed.

Preferred examples of the filter that is available include cartridge filters “TCW Type”, “TCP Type” and “TCS Type” produced by ADVANTEC.

The mesh size of the filter is preferably from 5 to 500 μm, more preferably from 10 to 200 μm, still more preferably from 20 to 100 μm.

After the development and the desensitization are performed at the same time by using the developer of the present invention, drying is continuously performed. Also, in the case where the water washing step is performed after the development step using the developer of the present invention, a step of desensitizing the non-image part with a gum solution may also be further performed subsequently to the drying.

After the water washing step, a gum solution is supplied to the plate surface, whereby the non-image part can be sufficiently desensitized. In this desensitizing step, a gum solution in general or the developer for use in the present invention may be used. In the latter case, it is preferred in view of structure of the apparatus to use a solution having fundamentally the same composition as the developer of the present invention used in the developing step. This means that the developer of the present invention charged into a tank of a development unit and the solution charged into a tank of a desensitization unit are the same, and does not mean a change in the composition due to carry over of the developer component or mixing of the lithographic printing plate precursor component during the development or further resulting from evaporation of water or dissolution of carbon dioxide. Also, by having the same composition, a charge solution or replenisher can be shared in common between solutions used in respective steps. Furthermore, a cascade system of supplying a required amount of a replenisher to the developing part by overflowing a circulated solution in the desensitizing part can be employed.

The developer for use in the present invention, the water in the water washing step and the gum solution in the desensitizing step may be used at respective arbitrary temperatures, but the temperature is preferably from 10 to 50° C.

Incidentally, in the present invention, a drying step can be arbitrarily provided after each step. In particular, a drying step is preferably provided as a final step of the automatic processor. In the case of having a water washing step and a desensitizing step, it is more preferred to provide a drying step also therebetween. This drying step is generally performed by blowing dry air at an arbitrary temperature after removing almost all the processing solution by roller nips.

In advance of the above-described development processing, the lithographic printing plate precursor is imagewise exposed, for example, by exposure through a transparent original having a line image, a halftone image or the like or by laser light scanning based on digital data. Examples of the light source suitable for the exposure include a carbon arc lamp, a mercury lamp, a xenon lamp, a metal halide lamp, a strobe, an ultraviolet ray, an infrared ray and a laser beam. In particular, a laser beam is preferred, and the laser therefor is preferably a solid or semiconductor laser that emits an infrared ray at 760 to 1,200 nm. An infrared laser enables operation under a white or yellow light lamp and is preferred also in view of simplification of the plate making.

As for the infrared laser, the output is preferably 100 mW or more, the exposure time per pixel is preferably within 20 μs, and the irradiation energy amount is preferably from 10 to 300 mJ/cm². In order to shorten the exposure time, it is preferred to use a multibeam laser device.

The constituent elements and components of the lithographic printing plate precursor for use in the present invention are described below.

### [Lithographic Printing Plate Precursor]

The lithographic printing plate precursor for use in the present invention has an image forming layer on a support, wherein the image forming layer contains an infrared absorber, a polymerization initiator, a polymerizable compound, a hydrophobic binder polymer and a compound represented by formula (1) or (2) (hereinafter referred to as a “carboxylic acid compound of the present invention”) and an image can be formed in the image forming layer by supplying the above-described developer of the present invention after exposure and thereby removing the unexposed area.

By containing an infrared absorber, a polymerization initiator and a polymerizable compound, the exposed area is polymerized and cured to form an image part.

Incidentally, the expression “has an image forming layer on a support” as used in the present invention does not deny the presence of an arbitrary layer provided, if desired, such as protective layer, undercoat layer, intermediate layer and backcoat layer.

### (Image Forming Layer)

### <Hydrophobic Binder Polymer>

As regards the hydrophobic binder polymer for use in the present invention, conventionally known binder polymers can be used without limitation as long as the polymer is substantially not dissolved in water, and a polymer having a film property is preferred. Examples of such a binder polymer include acrylic resin, polyvinyl acetal resin, polyurethane resin, polyurea resin, polyimide resin, polyamide resin, epoxy resin, methacrylic resin, polystyrene-based resin, novolak-type phenol-based resin, polyester resin, synthetic rubber and natural rubber.

The binder polymer for use in the present invention may have a crosslinking property so as to enhance the film strength in the image part. The crosslinking property may be imparted to the binder polymer by introducing a crosslinking functional group such as ethylenically unsaturated bond into the main or side chain of the polymer. The crosslinking functional group may also be introduced by copolymerization.

Examples of the polymer having an ethylenically unsaturated bond in the main chain of the molecule include poly-1,4-butadiene and poly-1,4-isoprene.

Examples of the polymer having an ethylenically unsaturated bond in the side chain of the molecule include a polymer which is a polymer of acrylic or methacrylic acid ester or amide and in which the ester or amide residue (R in —COOR or —CONHR) has an ethylenically unsaturated bond.

Examples of the residue (R above) having an ethylenically unsaturated bond include —CH═CH₂, —C(CH₃)═CH₂, —(CH₂)ₙCR¹═CR²R³, —(CH₂O)ₙCH₂CR¹═CR²R³, —(CH₂CH₂O)ₙCH₂CR¹═CR²R³, —(CH₂)ₙNH—CO—O—CH₂CR¹═CR²R³, —(CH₂)ₙ—O—CO—CR¹═CR²R³ and —(CH₂CH₂O)₂—X (wherein R¹ to R³ each represents a hydrogen atom, a halogen atom or an alkyl, aryl, alkoxy or aryloxy group having from 1 to 20 carbon atoms, R¹ and R² or R³ may combine together to form a ring, n represents an integer of 1 to 10, and X represents a dicyclopentadienyl residue).

Specific examples of the ester residue include —CH═CH₂, —C(CH₃)═CH₂, —CH₂CH═CH₂ (described in JP-B-7-21633), —CH₂CH₂O—CH₂CH═CH₂, —CH₂C(CH₃)═CH₂, —CH₂CH═CH—C₆H₅, —CH₂CH₂OCOCH═CH—C₆H₅, —CH₂CH₂—NHCOO—CH₂CH═CH₂ and —CH₂CH₂O—X (wherein X represents a dicyclopentadienyl residue).

Specific examples of the amide residue include —CH═CH₂, —C(CH₃)═CH₂, —CH₂CH═CH₂, —CH₂CH₂—Y (wherein Y represents a cyclohexene residue) and —CH₂CH₂—OCO—CH═CH₂.

In the binder polymer having a crosslinking property, for example, a free radical (a polymerization initiating radical or a radical grown in the course of polymerization of a polymerizable compound) is added to the crosslinking functional group to cause addition-polymerization between polymers directly or through a polymerization chain of the polymerizable compound, as a result, crosslinking is formed between polymer molecules and thereby curing is effected. Alternatively, an atom (for example, a hydrogen atom on the carbon atom adjacent to the functional crosslinking group) in the polymer is withdrawn by a free radical to produce a polymer radical and the polymer radicals combine together to form crosslinking between polymer molecules, thereby effecting curing.

The content of the crosslinking group (content of radical-polymerizable unsaturated double bond determined by iodine titration) in the binder polymer is preferably from 0.1 to 10.0 mmol, more preferably from 1.0 to 7.0 mmol, and most preferably from 2.0 to 5.5 mmol, per g of the binder polymer. Within this range, good sensitivity and good storage stability can be obtained.

The binder polymer for use in the present invention preferably has a hydrophilic group so as to enhance the dispersibility in a developer. The hydrophilic group is preferably an ethyleneoxy repeating unit. Specific examples thereof include an alkoxy polyethylene glycol acrylate or methacrylate, such as methoxy polyethylene glycol acrylate or methacrylate, and this may be contained as a copolymerization component.

The binder polymer for use in the present invention preferably has a mass average molar mass of 5,000 or more, more preferably from 10,000 to 300,000. The number average molar mass thereof is preferably 1,000 or more, more preferably from 2,000 to 250,000. The polydispersity (mass average molar mass/number average molar mass) is preferably from 1.1 to 10.

The binder polymer for use in the present invention is available by purchasing a commercial product or synthesizing the polymer according to a known method.

For example, the binder polymer described above may be prepared by radical polymerization. The radical polymerization is well known to one skilled in the art and is described, for example, in H. G. Elias (compiler), Macromolecules, Vol. 2, 2nd Ed., Chapters 20 and 21, Plenum, New York (1984). Useful free radical initiators are a peroxide such as benzoyl peroxide, a hydroperoxide such as cumyl hydroperoxide, and an azo compound such as 2,2′-azo-bis-isobutyronitrile (AIBN). A chain transfer agent such as dodecyl mercaptan may be used to control the molecular weight of the compound.

As to the solvent suitable for radical polymerization, a liquid that is inert to the reactant and does not cause any particular adverse effect on the reaction is generally selected. Examples thereof include esters such as ethyl acetate and butyl acetate; ketones such as methyl ethyl ketone, methyl isobutyl ketone, methyl propyl ketone and acetone; alcohols such as methanol, ethanol, isopropyl alcohol and butanol; ethers such as dioxane and tetrahydrofuran; and a mixture thereof.

The binder polymer for use in the present invention may be a linear polymer or may be a partially crosslinked polymer or a polymer particle. The polymer particle is preferably a particle having an average particle diameter of 0.05 to 0.8 μm, more preferably from 0.1 to 0.5 μm.

In order to obtain the binder polymer for use in the present invention in the shape of a particle, the polymer is preferably produced by emulsion polymerization in a hydrophilic medium (water or a mixture of water and an alcohol).

The content of the binder polymer is from 5 to 90 mass %, preferably from 5 to 80 mass %, more preferably from 10 to 70 mass %, based on the entire solid content of the image forming layer. Within this range, good strength of image part and good image-forming property can be obtained.

The polymerizable compound (C) and the binder polymer are preferably used in amounts giving a mass ratio of 0.5/1 to 4/1.

### <Carboxylic Acid Compound of the Present Invention>

The carboxylic acid compound of the present invention is represented by the following formula (1) or (2):

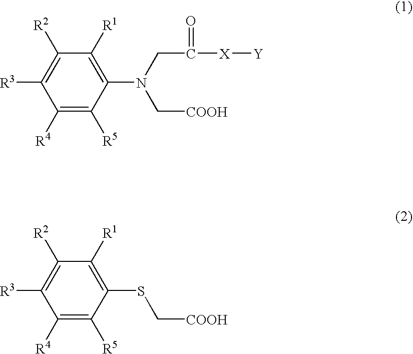

In the formulae above, R¹ to R⁵ each independently represents a hydrogen atom, an alkyl group having a carbon number of 1 to 6, an alkoxy group having a carbon number of 1 to 6, a phenyl group, a halogen atom, an amino group or a nitro group, each of these groups may be partially substituted by an alkyl group having a carbon number of 4 or less or a hydroxyl group, and at least two members out of R¹ to R⁵ may combine to form an aliphatic or aromatic ring. For example, the aromatic ring moiety of the formulae above may be a naphthyl group or an indenyl group.

X represents —O— or —NH—, Y represents a hydrogen atom, an alkyl group having a carbon number of 1 to 6, a phenyl group or a benzyl group, and each of these groups may be partially substituted by an alkyl group having a carbon number of 4 or less or a hydroxyl group.

Specific examples of Y include a hydrogen atom, a methyl group, an ethyl group, a propyl group, a butyl group, a pentyl group, a hexyl group, an isopropyl group, an isobutyl group, an s-butyl group, a tert-butyl group, an isopentyl group, a neopentyl group, a 1-methylbutyl group, an isohexyl group, a cyclohexyl group, a cyclopentyl group, a 2-hydroxyethyl group, a 2-hydroxypropyl group, a phenyl group, a 2-methylphenyl group, a 3-methylphenyl group, a 4-methylphenyl group, a 2-hydroxyphenyl group, a 3-hydroxyphenyl group, a 4-hydroxyphenyl group, a 4-methylbenzyl group and a 4-hydroxybenzyl group. Among these, a hydrogen atom, an alkyl group having a carbon number of 1 to 3, and an unsubstituted phenyl group are preferred.

Specific examples (C-1) to (C-48), (A-1) to (A-48) and (T-1) to (T-13) of the carboxylic acid compound represented by formula (1) or (2) are set forth below, but the present invention is not limited thereto.

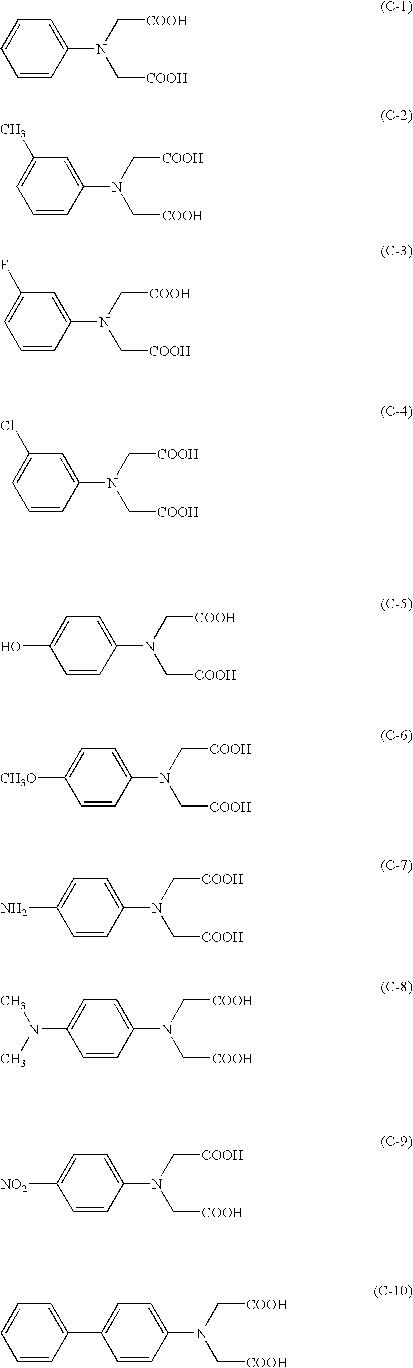

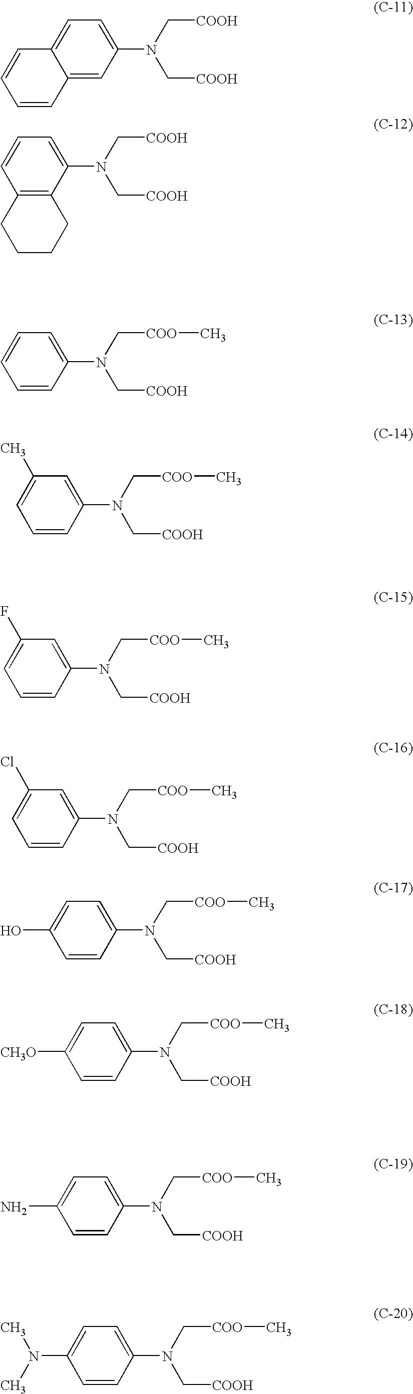

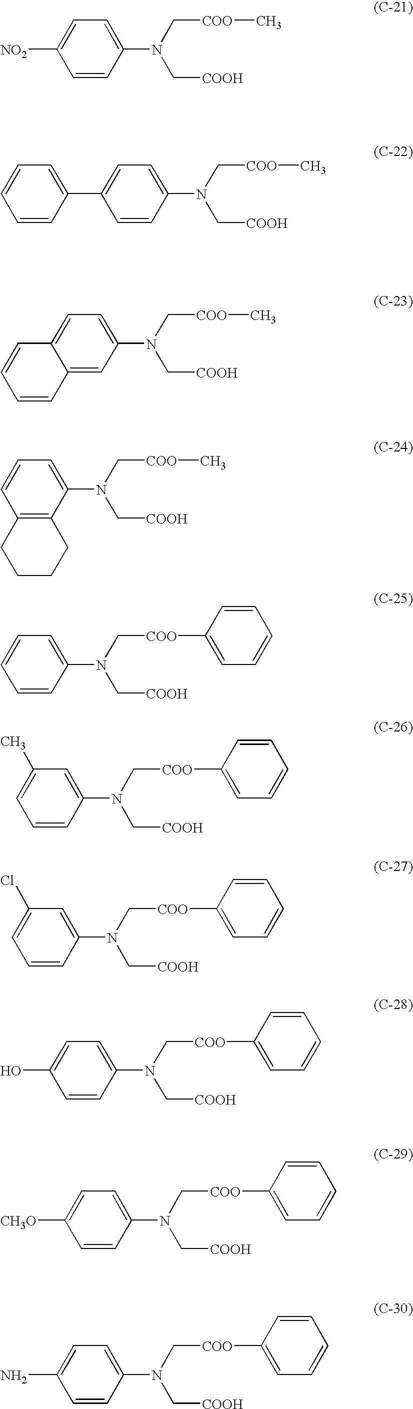

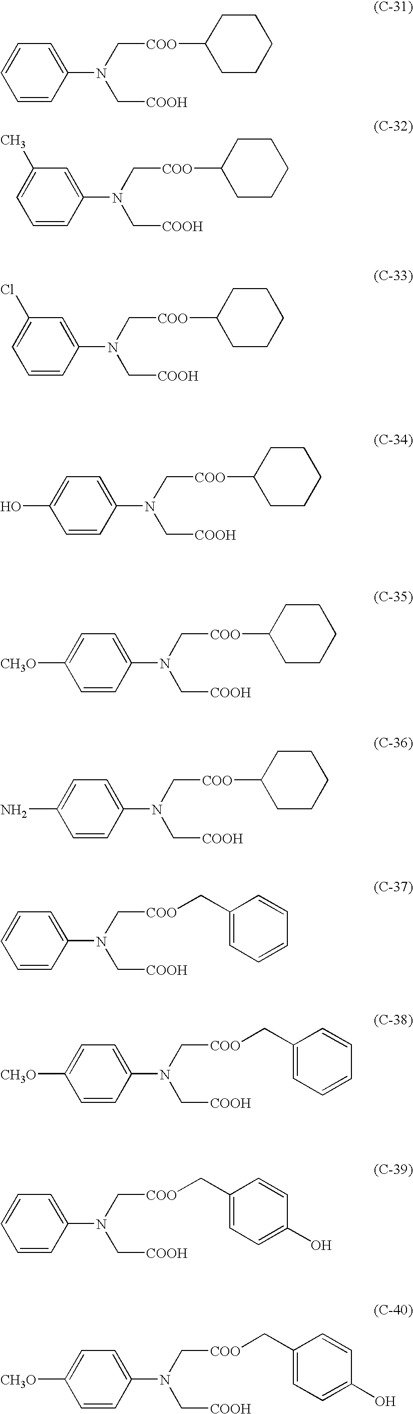

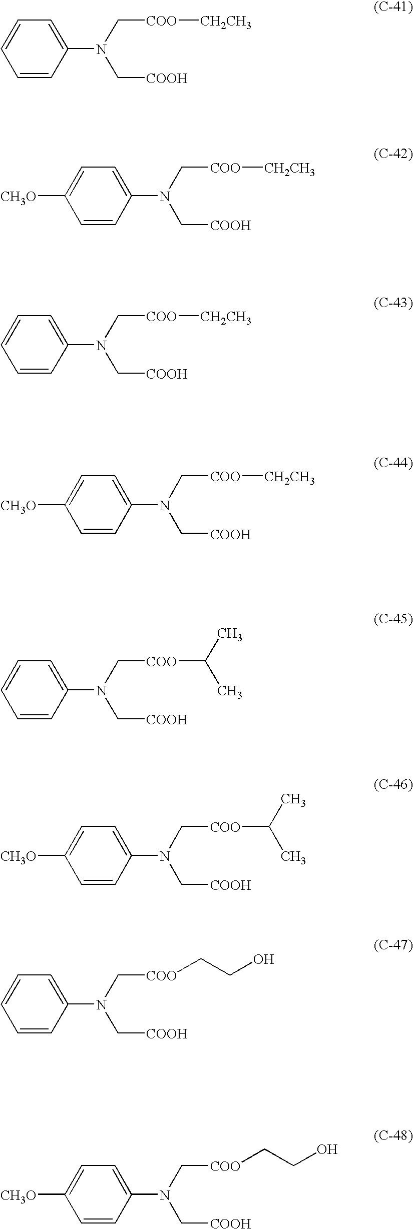

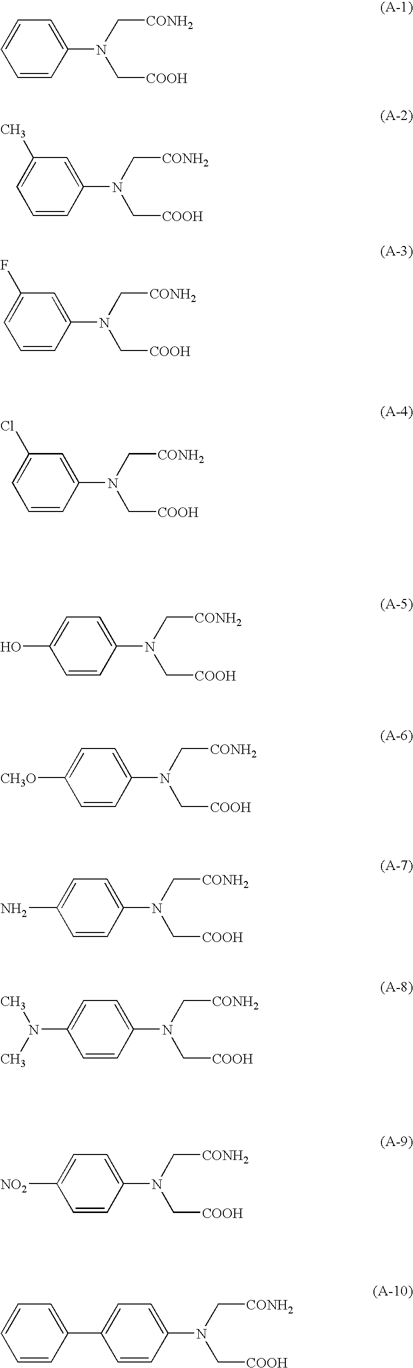

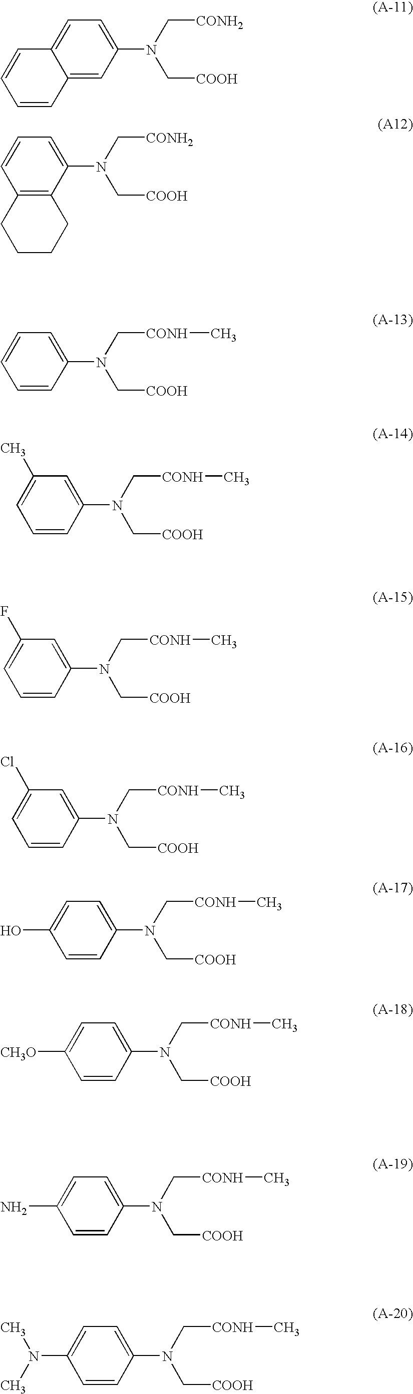

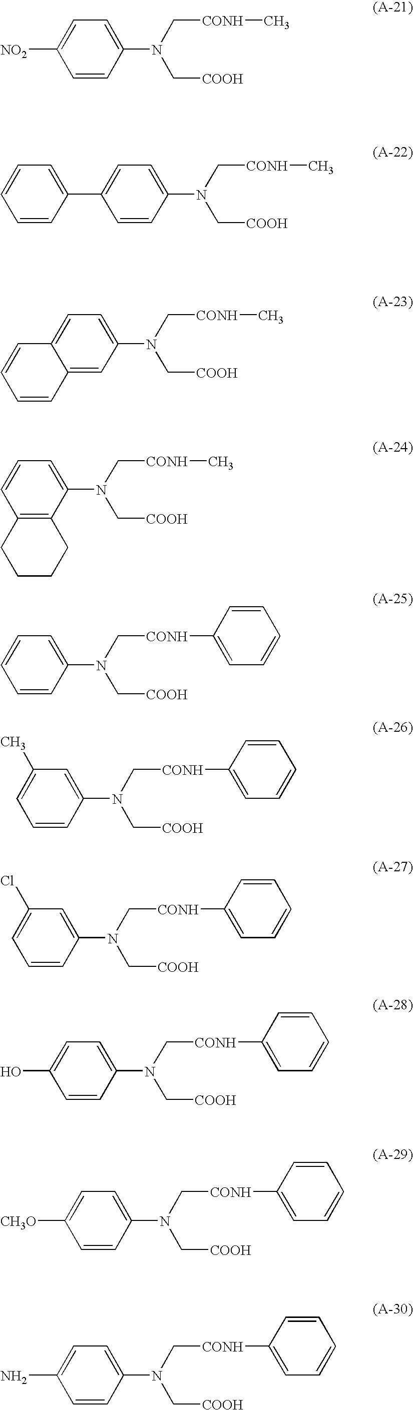

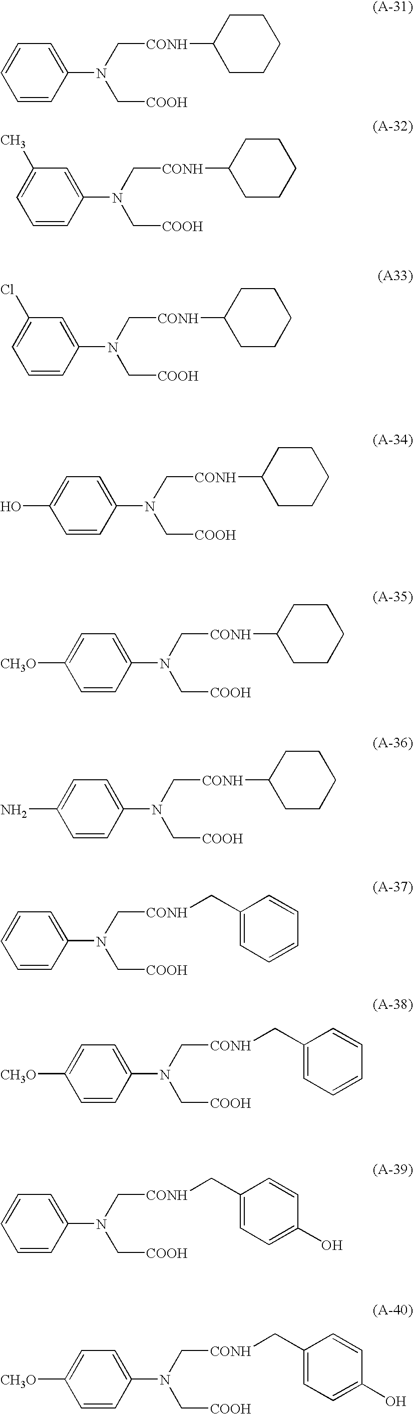

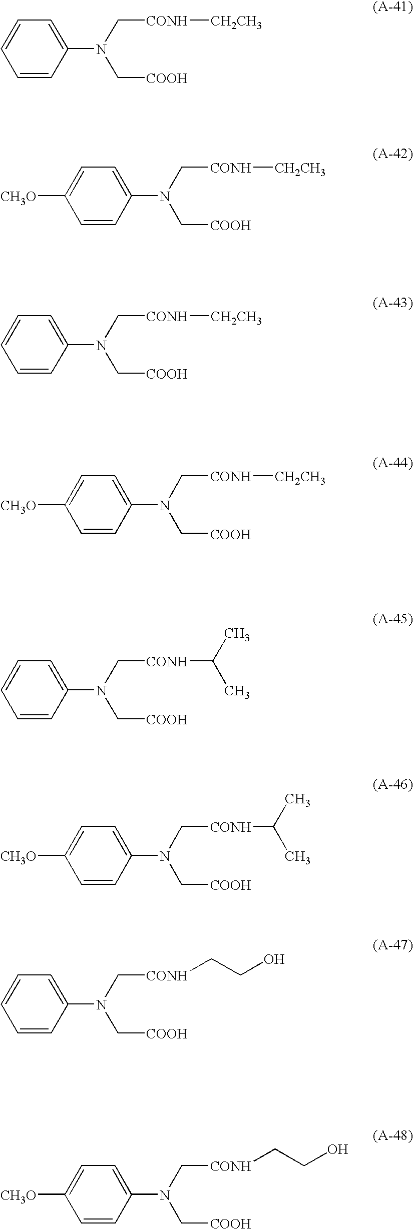

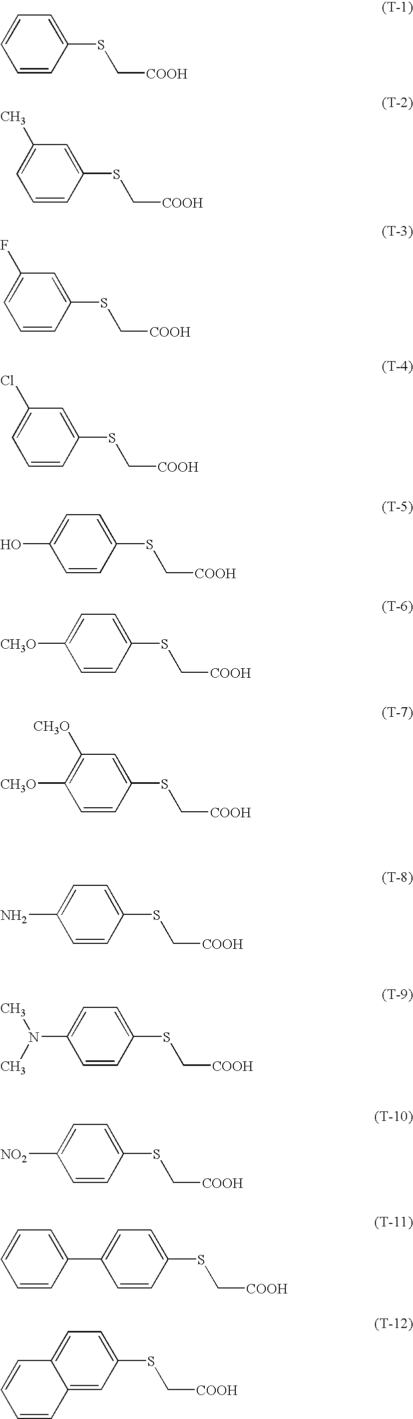

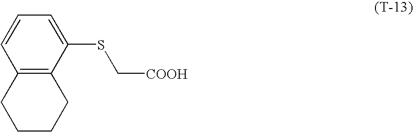

Representative synthesis examples of the carboxylic acid compound for use in the present invention are described below, but the present invention is not limited thereto.

### <Synthesis of Compound (C-13)>

In a nitrogen stream, 62.8 g of N-phenyliminodiacetic acid was charged into a 2-L Kjeldahl flask and dissolved with 500 mL of toluene, and 32.0 g of acetic anhydride was added thereto, The mixture was refluxed under heating and stirred. After 1 hour, the reaction mixture was cooled to room temperature, and 3 L of hexane was added thereto with stirring to cause precipitation. The precipitate was filtered to obtain 52.0 g of N-phenyliminodiacetic anhydride.

Subsequently, in a nitrogen stream, 5.1 g of N-phenyliminodiacetic anhydride obtained above was charged into a 200-mL Kjeldahl flask, and 60 mL of methanol was added thereto. After stirring at room temperature for 6 hours, the solvent was removed by distillation under reduced pressured. The residue was purified by silica gel chromatography (elution solvent: hexane/ethyl acetate) to obtain 5.7 g of Compound (C-13). The compound obtained was confirmed as Compound (C-13) by NMR spectrum, IR spectrum, and mass analysis spectrum.

### <Synthesis of Compound (C-37)>

In a nitrogen stream, 62.8 g of N-phenyliminodiacetic acid was charged into a 2-L Kjeldahl flask and dissolved with 500 mL of toluene, and 32.0 g of acetic anhydride was added thereto, The mixture was refluxed under heating and stirred. After 1 hour, the reaction mixture was cooled to room temperature, and 3 L of hexane was added thereto with stirring to cause precipitation. The precipitate was filtered to obtain 52.0 g of N-phenyliminodiacetic anhydride.

In a nitrogen stream, 5.1 g of N-phenyliminodiacetic anhydride obtained above was charged into a 200-mL Kjeldahl flask, and 50 mL of benzyl alcohol was added thereto. After stirring at room temperature for 8 hours, the solvent was removed by distillation under reduced pressured. The residue was purified by silica gel chromatography (elution solvent: hexane/ethyl acetate) to obtain 7.2 g of Compound (C-37). The compound obtained was confirmed as Compound (C-37) by NMR spectrum, IR spectrum, and mass analysis spectrum.

Only one of these compounds having a carboxylic acid group according to the present invention may be used, or two or more kinds thereof may be used in combination. As for the amount added of this specific carboxylic acid compound, the compound is preferably added in a ratio of 0.5 to 20 mass %, more preferably from 1 to 10 mass %, still more preferably from 1.5 to 6 mass %, based on all solid contents constituting the image forming layer.

### <(A) Infrared Absorbent>

The lithographic printing plate precursor of the present invention contains (A) an infrared absorbent, whereby image formation using an infrared ray for the light source, such as laser that emits an infrared ray at 760 to 1,200 nm, can be performed.

The infrared absorbent has a function of converting the absorbed infrared ray into heat and a function of being excited by an infrared ray and effecting electron transfer and/or energy transfer to a polymerization initiator (radical generator) described later. The infrared absorbent for use in the present invention is a dye or pigment having an absorption maximum at a wavelength of 760 to 1,200 nm.

As for the dye, commercially available dyes and known dyes described in publications such as Senryo Binran (Handbook of Dyes) (compiled by The Synthetic Organic Chemistry, Japan (1970)) may be used. Specific examples thereof include a dye such as azo dye, metal complex salt azo dye, pyrazolone azo dye, naphthoquinone dye, anthraquinone dye, phthalocyanine dye, carbonium dye, quinoneimine dye, methine dye, cyanine dye, squarylium dye, pyrylium salt and metal thiolate complex.

Preferred examples of the dye include cyanine dyes described in JP-A-58-125246, JP-A-59-84356 and JP-A-60-78787, methine dyes described in JP-A-58-173696, JP-A-58-181690 and JP-A-58-194595, naphthoquinone dyes described in JP-A-58-112793, JP-A-58-224793, JP-A-59-48187, JP-A-59-73996, JP-A-60-52940 and JP-A-60-63744, squarylium dyes described in JP-A-58-112792, and cyanine dyes described in British Patent 434,875.

Also, near infrared absorbing sensitizers described in U.S. Pat. No. 5,156,938 may be suitably used. Furthermore, substituted arylbenzo(thio)pyrylium salts described in U.S. Pat. No. 3,881,924, trimethinethiapyrylium salts described in JP-A-57-142645 (corresponding to U.S. Pat. No. 4,327,169), pyrylium-based compounds described in JP-A-58-181051, JP-A-58-220143, JP-A-59-41363, JP-A-59-84248, JP-59-84249, JP-A-59-146063 and JP-A-59-146061, cyanine dyes described in JP-A-59-216146, pentamethinethiapyrylium salts described in U.S. Pat. No. 4,283,475, and pyrylium compounds described in JP-B-5-13514 and JP-B-5-19702 may also be preferably used. Other preferred examples of the dye include near infrared absorbing dyes represented by formulae (I) and (II) of U.S. Pat. No. 4,756,993.

Also, other preferred examples of the infrared absorbing dye for use in the present invention include specific indolenine cyanine dyes described in JP-A-2002-278057, which are illustrated below.

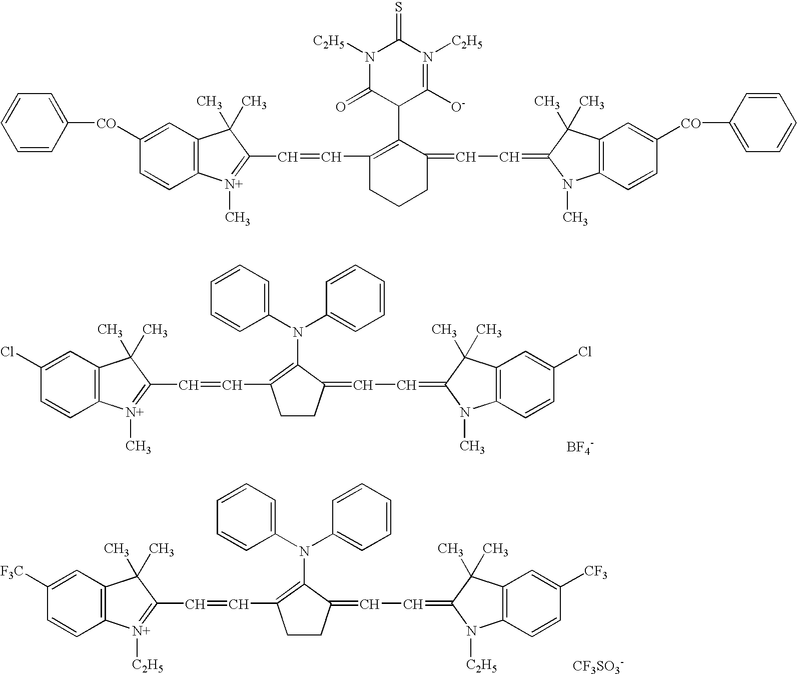

Among these dyes, preferred are a cyanine dye, a squarylium dye, a pyrylium salt, a nickel thiolate complex and an indolenine cyanine dye, more preferred are a cyanine dye and an indolenine cyanine dye, still more preferred is, for example, a cyanine dye represented by the following formula (i):

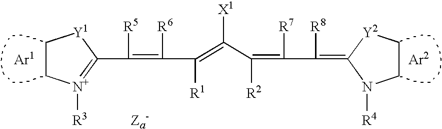

In formula (i), X¹ represents a hydrogen atom, a halogen atom, —NPh₂, X²-L¹ or a group represented by the following structural formula. Here, X² represents an oxygen atom, a nitrogen atom or a sulfur atom, and L¹ represents a hydrocarbon group having a carbon number of 1 to 12, an aromatic ring having a heteroatom, or a hydrocarbon group having a carbon number of 1 to 12 and containing a heteroatom. Incidentally, the heteroatom as used herein indicates a nitrogen atom, a sulfur atom, an oxygen atom, a halogen atom or a selenium atom. R^{a} represents a substituent selected from a hydrogen atom, an alkyl group, an aryl group, a substituted or unsubstituted amino group and a halogen atom, and Xₐ⁻ has the same definition as Za⁻ described later.

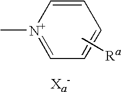

R¹ and R² each independently represents a hydrocarbon group having a carbon number of 1 to 12. In view of storage stability of the coating solution for image forming layer, R¹ and R² each is preferably a hydrocarbon group having a carbon number of 2 or more. It is more preferred that R¹ and R² combine together to form a 5- or 6-membered ring.

Ar¹ and Ar² may be the same or different and each represents an aromatic hydrocarbon group which may have a substituent. Preferred examples of the aromatic hydrocarbon group include a benzene ring and a naphthalene ring. Preferred examples of the substituent include a hydrocarbon group having a carbon number of 12 or less, a halogen atom and an alkoxy group having a carbon number of 12 or less, with a hydrocarbon group having a carbon number of 12 or less and an alkoxy group having a carbon number of 12 or less being most preferred. Y¹ and Y² may be the same or different and each represents a sulfur atom or a dialkylmethylene group having a carbon number of 12 or less. R³ and R⁴ may be the same or different and each represents a hydrocarbon group having a carbon number of 20 or less, which may have a substituent. Preferred examples of the substituent include an alkoxy group having a carbon number of 12 or less, a carboxyl group and a sulfo group, with an alkoxy group having a carbon number of 12 or less being most preferred. R⁵, R⁶, R⁷ and R⁸, which may be the same or different, each represents a hydrogen atom or a hydrocarbon group having a carbon number of 12 or less and in view of availability of the raw material, is preferably a hydrogen atom. Za⁻ represents a counter anion, but when the cyanine dye represented by formula (i) has an anionic substituent in its structure and neutralization of the electric charge is not necessary, Za⁻ can be omitted. In view of storage stability of the coating solution for image forming layer, Za⁻ is preferably halide ion, perchlorate ion, tetrafluoroborate ion, hexafluorophosphate ion or sulfonate ion, more preferably perchlorate ion, tetrafluoroborate ion, hexafluorophosphate ion or arylsulfonate ion.

Specific examples of the cyanine dye represented by formula (i), which can be suitably used in the present invention, include those described in paragraphs [0017] to of JP-A-2001-133969.

Other particularly preferred examples include specific indolenine cyanine dyes described in JP-A-2002-278057 supra.

As for the pigment used in the present invention, commercially available pigments and pigments described in Color Index (C.I.) Binran (C.I. Handbook), Saishin Ganryo Binran (Handbook of Latest Pigments), compiled by Nippon Ganryo Gijutsu Kyokai (1977), Saishin Ganryo Oyo Gijutsu (Latest Pigment Application Technology), CMC Shuppan (1986), and Insatsu Ink Gijutsu (Printing Ink Technology), CMC Shuppan (1984) can be used.

The kind of the pigment includes black pigment, yellow pigment, orange pigment, brown pigment, red pigment, violet pigment, blue pigment, green pigment, fluorescent pigment, metal powder pigment and polymer-bound dye. Specific examples of the pigment which can be used include an insoluble azo pigment, an azo lake pigment, a condensed azo pigment, a chelate azo pigment, a phthalocyanine-based pigment, an anthraquinone-based pigment, a perylene- or perynone-based pigment, a thioindigo-based pigment, a quinacridone-based pigment, a dioxazine-based pigment, an isoindolinone-based pigment, a quinophthalone-based pigment, a dyed lake pigment, an azine pigment, a nitroso pigment, a nitro pigment, a natural pigment, a fluorescent pigment, an inorganic pigment and carbon black. Among these pigments, carbon black is preferred.

These pigments may or may not be surface-treated before use. Examples of the method for surface treatment include a method of coating the surface with resin or wax, a method of attaching a surfactant, and a method of bonding a reactive substance (for example, a silane coupling agent, an epoxy compound or an isocyanate) to the pigment surface. These surface-treating methods are described in Kinzoku Sekken no Seishitsu to Oyo (Properties and Application of Metal Soap), Saiwai Shobo, Insatsu Ink Gijutsu (Printing Ink Technology), CMC Shuppan (1984), and Saishin Ganryo Oyo Gijutsu (Latest Pigment Application Technology), CMC Shuppan (1986).

The particle diameter of the pigment is preferably from 0.01 to 10 μm, more preferably from 0.05 to 1 μm, still more preferably from 0.1 to 1 μm. Within this range, good stability of the pigment dispersion in the coating solution for image forming layer and good uniformity of the image forming layer can be obtained.

As for the method of dispersing the pigment, a known dispersion technique employed in the production of ink, toner or the like may be used. Examples of the dispersing machine include an ultrasonic disperser, a sand mill, an attritor, a pearl mill, a super-mill, a ball mill, an impeller, a disperser, a KD mill, a colloid mill, a dynatron, a three-roll mill and a pressure kneader. These are described in detail in Saishin Ganryo Oyo Gijutsu (Latest Pigment Application Technology), CMC Shuppan (1986).

The infrared absorbent may be added together with other components in the same layer or may be added to another image forming layer provided separately, but the infrared absorbent is added such that when a lithographic printing plate precursor is produced, the absorbancy of the image forming layer at a maximum absorption wavelength in the wavelength range of 760 to 1,200 nm becomes from 0.3 to 1.2, preferably from 0.4 to 1.1, as measured by a reflection measuring method. Within this range, a uniform polymerization reaction proceeds in the depth direction of the image forming layer, and the image part can have good film strength and good adherence to the support.

The absorbancy of the image forming layer can be adjusted by the amount of the infrared absorbent added to the image forming layer and the thickness of the image forming layer. The absorbancy can be measured by an ordinary method. Examples of the measuring method include a method where an image forming layer having a thickness appropriately selected in the range giving a dry coated amount necessary as a lithographic printing plate is formed on a reflective support such as aluminum and the reflection density is measured by an optical densitometer, and a method of measuring the absorbancy by a spectrophotometer according to a reflection method using an integrating sphere.

In the present invention, the content of the infrared absorbent (A) in the image forming layer is, in terms of the specific added amount, preferably from 0.1 to 10.0 mass %, more preferably from 0.5 to 5.0 mass %, based on the entire solid content of the image forming layer.

### <(B) Polymerization Initiator>

The polymerization initiator (B) for use in the present invention indicates a compound capable of generating a radical by the effect of light or heat energy or both and thereby initiating or accelerating the polymerization of the polymerizable compound (C). Examples of the polymerization initiator usable in the present invention include a known thermal polymerization initiator, a compound having a bond of small bond-dissociation energy, and a photopolymerization initiator.

Examples of the polymerization initiator for use in the present invention include (a) an organic halide, (b) a carbonyl compound, (c) an azo-based polymerization initiator, (d) an organic peroxide, (e) a metallocene compound, (f) an azide compound, (g) a hexaarylbiimidazole compound, (h) an organic borate compound, (i) a disulfone compound, (j) an oxime ester compound and (k) an onium salt compound.

Specific examples of the organic halide (a) include the compounds described in Wakabayashi et al., Bull. Chem. Soc. Japan, 42, 2924 (1969), U.S. Pat. No. 3,905,815, JP-B-46-4605, JP-A-48-36281, JP-A-55-32070, JP-A-60-239736, JP-A-61-169835, JP-A-61-169837, JP-A-62-58241, JP-A-62-212401, JP-A-63-70243, JP-A-63-298339, and M. P. Hutt, Journal of Heterocyclic Chemistry, 1, No. 3 (1970). In particular, an oxazole compound substituted by a trihalomethyl group, and an s-triazine compound are preferred.

An s-triazine derivative having bonded thereto at least one mono-, di- or trihalogen-substituted methyl group and an oxadiazole derivative are more preferred. Specific examples thereof include 2,4,6-tris(monochloromethyl)-s-triazine, 2,4,6-tris(dichloromethyl)-s-triazine, 2,4,6-tris(trichloromethyl)-s-triazine, 2-methyl-4,6-bis(trichloromethyl)-s-triazine, 2-n-propyl-4,6-bis(trichloromethyl)-s-triazine, 2-(α,α,β-trichloroethyl)-4,6-bis(trichloromethyl)-s-triazine, 2-phenyl-4,6-bis(trichloromethyl)-s-triazine, 2-(p-methoxyphenyl)-4,6-bis(trichloromethyl)-s-triazine, 2-(3,4-epoxyphenyl)-4,6-bis(trichloromethyl)-s-triazine, 2-(p-chlorophenyl)-4,6-bis(trichloromethyl)-s-triazine, 2-(p-bromophenyl)-4,6-bis(trichloromethyl)-s-triazine, 2-(p-fluorophenyl)-4,6-bis(trichloromethyl)-s-triazine, 2-(p-trifluoromethylphenyl)-4,6-bis(trichloromethyl)-s-triazine, 2-(2,6-dichlorophenyl)-4,6-bis(trichloromethyl)-s-triazine, 2-(2,6-difluorophenyl)-4,6-bis(trichloromethyl)-s-triazine, 2-(2,6-dibromophenyl)-4,6-bis(trichloromethyl)-s-triazine, 2-(4-biphenylyl)-4,6-bis(trichloromethyl)-s-triazine, 2-(4′-chloro-4-biphenylyl)-4,6-bis(trichloromethyl)-s-triazine, 2-(p-cyanophenyl)-4,6-bis(trichloromethyl)-s-triazine, 2-(p-acetylphenyl)-4,6-bis(trichloromethyl)-s-triazine, 2-(p-ethoxycarbonylphenyl)-4,6-bis(trichloromethyl)-s-triazine, 2-(p-phenoxycarbonylphenyl)-4,6-bis(trichloromethyl)-s-triazine, 2-(p-methylsulfonyl-phenyl)-4,6-bis(trichloromethyl)-s-triazine, 2-(p-dimethylsulfoniumphenyl)-4,6-bis(trichloromethyl)-s-triazine.tetrafluoroborate, 2-(2,4-difluorophenyl)-4,6-bis(trichloromethyl)-s-triazine, 2-(p-diethoxyphosphorylphenyl)-4,6-bis(trichloromethyl)-s-triazine, 2-[4-(4-hydroxyphenylcarbonylamino)phenyl]-4,6-bis(trichloromethyl)-s-triazine, 2-[4-(p-methoxyphenyl)-1,3-butadienyl]-4,6-bis(trichloromethyl)-s-triazine, 2-styryl-4,6-bis(trichloromethyl)-s-triazine, 2-(p-methoxystyryl)-4,6-bis(trichloromethyl)-s-triazine, 2-(p-i-propyloxystyryl)-4,6-bis(trichloromethyl)-s-triazine, 2-(p-tolyl)-4,6-bis(trichloromethyl)-s-triazine, 2-(4-methoxynaphthyl)-4,6-bis(trichloromethyl)-s-triazine, 2-phenylthio-4,6-bis(trichloromethyl)-s-triazine, 2-benzylthio-4,6-bis(trichloromethyl)-s-triazine, 2,4,6-tris(dibromomethyl)-s-triazine, 2,4,6-tris(tribromomethyl)-s-triazine, 2-methyl-4,6-bis(tribromomethyl)-s-triazine, 2-methoxy-4,6-bis(tribromomethyl)-s-triazine, 2-(o-methoxystyryl)-5-trichloromethyl-1,3,4-oxadiazole, 2-(3,4-epoxystyryl)-5-trichloromethyl-1,3,4-oxadiazole, 2-[1-phenyl-2-(4-methoxyphenyl)vinyl]-5-trichloromethyl-1,3,4-oxadiazole, 2-(p-hydroxystyryl)-5-trichloromethyl-1,3,4-oxadiazole, 2-(3,4-dihydroxystyryl)-5-trichloromethyl-1,3,4-oxadiazole and 2-(p-tert-butoxystyryl)-5-trichloromethyl-1,3,4-oxadiazole.

Examples of the carbonyl compound (b) include a benzophenone derivative such as benzophenone, Michler's ketone, 2-methylbenzophenone, 3-methylbenzophenone, 4-methylbenzophenone, 2-chlorobenzophenone, 4-bromobenzophenone and 2-carboxybenzophenone, an acetophenone derivative such as 2,2-dimethoxy-2-phenylacetophenone, 2,2-diethoxyacetophenone, 1-hydroxycyclohexyl phenyl ketone, α-hydroxy-2-methylphenylpropanone, 1-hydroxy-1-methylethyl-(p-isopropylphenyl)ketone, 1-hydroxy-1-(p-dodecylphenyl)ketone, 2-methyl-(4′-(methylthio)phenyl)-2-morpholino-1-propanone and 1,1,1-trichloromethyl-(p-butylphenyl)ketone, a thioxanthone derivative such as thioxanthone, 2-ethylthioxanthone, 2-isopropylthioxanthone, 2-chlorothioxanthone, 2,4-dimethylthioxanthone, 2,4-diethylthioxanthone and 2,4-diisopropylthioxanthone, and a benzoic acid ester derivative such as ethyl p-dimethylaminobenzoate and ethyl p-diethylaminobenzoate.

Examples of the azo compound (c) which can be used include azo compounds described in JP-A-8-108621.

Examples of the organic peroxide (d) include trimethylcyclohexanone peroxide, acetylacetone peroxide, 1,1-bis(tert-butylperoxy)-3,3,5-trimethylcyclohexane, 1,1-bis(tert-butylperoxy)cyclohexane, 2,2-bis(tert-butylperoxy)butane, tert-butyl hydroperoxide, cumene hydroperoxide, diisopropylbenzene hydroperoxide, 2,5-dimethylhexane-2,5-dihydroperoxide, 1,1,3,3-tetramethylbutyl hydroperoxide, tert-butylcumyl peroxide, dicumyl peroxide, 2,5-dimethyl-2,5-di(tert-butylperoxy)hexane, 2,5-oxanoyl peroxide, succinic peroxide, benzoyl peroxide, 2,4-dichlorobenzoyl peroxide, diisopropyl peroxydicarbonate, di-2-ethylhexyl peroxydicarbonate, di-2-ethoxyethyl peroxydicarbonate, dimethoxyisopropyl peroxycarbonate, di(3-methyl-3-methoxybutyl) peroxydicarbonate, tert-butyl peroxyacetate, tert-butyl peroxypivalate, tert-butyl peroxyneodecanoate, tert-butyl peroxyoctanoate, tert-butyl peroxylaurate, tertiary carbonate, 3,3′,4,4′-tetra(tert-butylperoxycarbonyl)benzophenone, 3,3′,4,4′-tetra(tert-hexylperoxycarbonyl)benzophenone, 3,3′,4,4′-tetra(p-isopropylcumylperoxycarbonyl)benzophenone, carbonyl di(tert-butylperoxy dihydrogen diphthalate) and carbonyl di(tert-hexylperoxy dihydrogen diphthalate).

Examples of the metallocene compound (e) include various titanocene compounds described in JP-A-59-152396, JP-A-61-151197, JP-A-63-41484, JP-A-2-249, JP-A-2-4705 and JP-A-5-83588, such as dicyclopentadienyl-Ti-bisphenyl, dicyclopentadienyl-Ti-bis-2,6-difluorophen-1-yl, dicyclopentadienyl-Ti-bis-2,4-difluorophen-1-yl, dicyclopentadienyl-Ti-bis-2,4,6-trifluorophen-1-yl, dicyclopentadienyl-Ti-bis-2,3,5,6-tetrafluorophen-1-yl, dicyclopentadienyl-Ti-bis-2,3,4,5,6-pentafluorophen-1-yl, dimethylcyclopentadienyl-Ti-bis-2,6-difluorophen-1-yl, dimethylcyclopentadienyl-Ti-bis-2,4,6-trifluorophen-1-yl, dimethylcyclopentadienyl-Ti-bis-2,3,5,6-tetrafluorophen-1-yl, dimethylcyclopentadienyl-Ti-bis-2,3,4,5,6-pentafluorophen-1-yl and dicyclopentadienyl-Ti-bis-2,6-difluoro-3-(pyrrol-1-yl)phen-1-yl, and iron-arene complexes described in JP-A-1-304453 and JP-A-1-152109.

Examples of the azide compound (f) include 2,6-bis(4-azidobenzylidene)-4-methylcyclohexanone.

Examples of the hexaarylbiimidazole compound (g) include various compounds described in JP-B-6-29285 and U.S. Pat. Nos. 3,479,185, 4,311,783 and 4,622,286, such as 2,2′-bis(o-chlorophenyl)-4,4′,5,5′-tetraphenylbiimidazole, 2,2′-bis(o-bromophenyl)-4,4′,5,5′-tetraphenylbiimidazole, 2,2′-bis(o,p-dichlorophenyl)-4,4′,5,5′-tetraphenylbiimidazole, 2,2′-bis(o-chlorophenyl)-4,4′,5,5′-tetrakis(m-methoxy-phenyl)biimidazole, 2,2′-bis(o,o′-dichlorophenyl)-4,4′,5,5′-tetraphenylbiimidazole, 2,2′-bis(o-nitrophenyl)-4,4′,5,5′-tetraphenylbiimidazole, 2,2′-bis(o-methylphenyl)-4,4′,5,5′-tetraphenylbiimidazole and 2,2′-bis(o-trifluorophenyl)-4,4′,5,5′-tetraphenylbiimidazole.

Examples of the organic borate compound (h) include organic borate salts described in JP-A-62-143044, JP-A-62-150242, JP-A-9-188685, JP-A-9-188686, JP-A-9-188710, JP-A-2000-131837, JP-A-2002-107916, Japanese Patent 2764769, JP-A-2002-116539 and Martin Kunz, Rad Tech '98. Proceeding Apr. 19-22, 1998, Chicago; organoboron sulfonium complexes and organoboron oxosulfonium complexes described in JP-A-6-157623, JP-A-6-175564 and JP-A-6-175561; organoboron iodonium complexes described in JP-A-6-175554 and JP-A-6-175553; organoboron phosphonium complexes described in JP-A-9-188710; and organoboron transition metal coordination complexes described in JP-A-6-348011, JP-A-7-128785, JP-A-7-140589, JP-A-7-306527 and JP-A-7-292014.

Examples of the disulfone compound (i) include compounds described in JP-A-61-166544 and JP-A-2003-328465.

Examples of the oxime ester compound (j) include compounds described in J. C. S. Perkin II, 1653-1660 (1979), J. C. S. Perkin II, 156-162 (1979), Journal of Photopolymer Science and Technology, 202-232 (1995), JP-A-2000-66385 and JP-A-2000-80068. Specific examples thereof include the compounds shown by the following structural formulae.

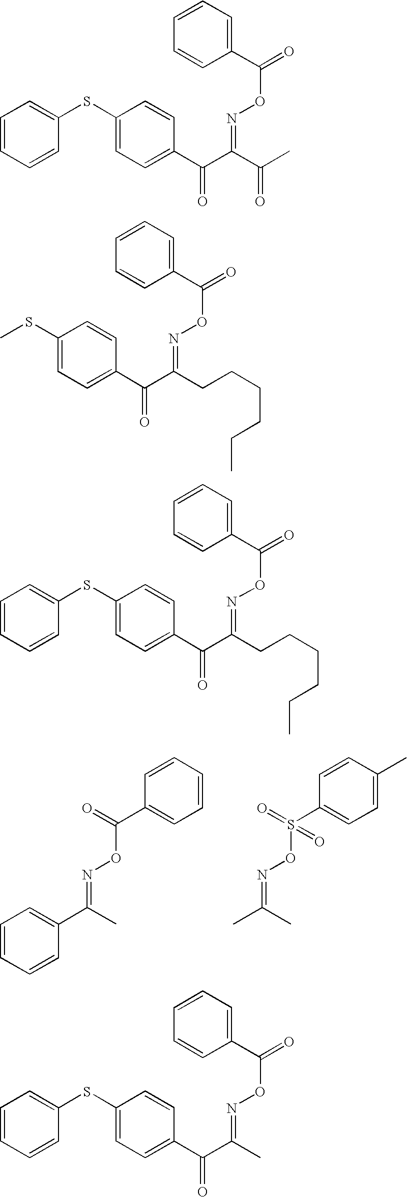

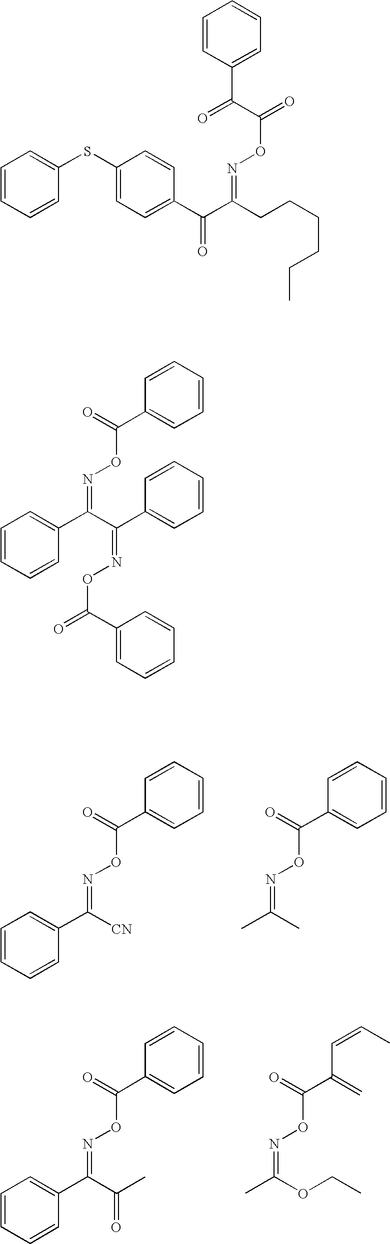

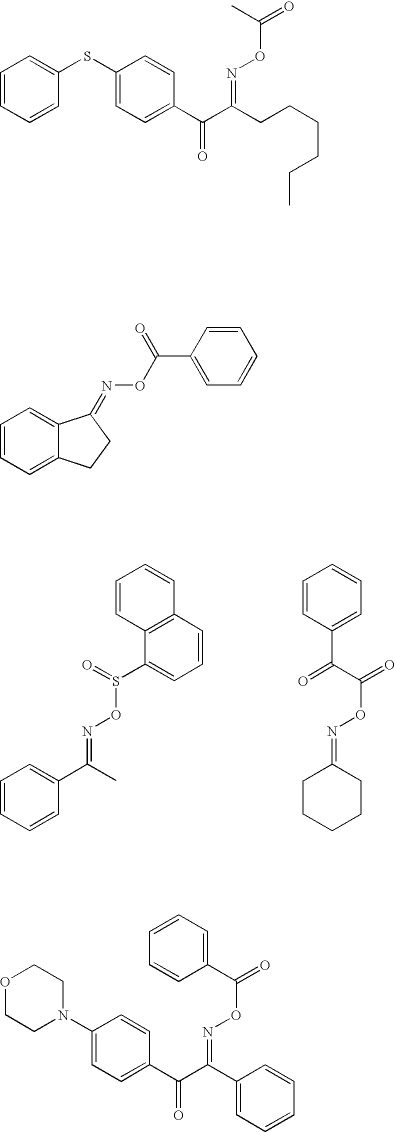

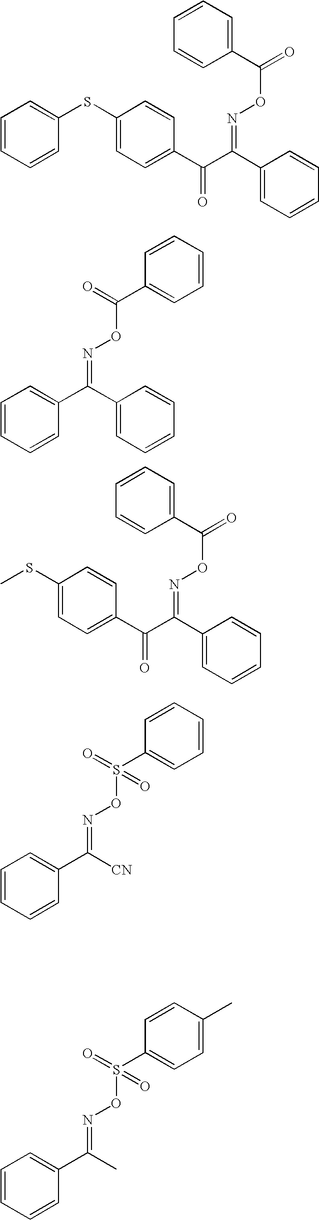

Examples of the onium salt compound (k) include onium salts such as diazonium salts described in S. I. Schlesinger, Photogr. Sci. Eng., 18, 387 (1974) and T. S. Bal et al., Polymer, 21, 423 (1980), ammonium salts described in U.S. Pat. No. 4,069,055 and JP-A-4-365049, phosphonium salts described in U.S. Pat. Nos. 4,069,055 and 4,069,056, iodonium salts described in European Patent 104,143, U.S. Pat. Nos. 339,049 and 410,201, JP-A-2-150848 and JP-A-2-296514, sulfonium salts described in European Patents 370,693, 390,214, 233,567, 297,443 and 297,442, U.S. Pat. Nos. 4,933,377, 161,811, 410,201, 339,049, 4,760,013, 4,734,444 and 2,833,827, and German Patents 2,904,626, 3,604,580 and 3,604,581, selenonium salts described in J. V. Crivello et al., Macromolecules, 10 (6), 1307 (1977) and J. V. Crivello et al., J. Polymer Sci., Polymer Chem. Ed., 17, 1047 (1979), and arsonium salts described in C. S. Wen et al., Teh. Proc. Conf. Rad. Curing ASIA, p. 478, Tokyo, Oct. (1988).

Above all, an oxime ester compound, a diazonium salt, an iodonium salt and a sulfonium salt are preferred in view of reactivity and stability. In the present invention, such an onium salt acts as an ionic radical polymerization initiator but not as an acid generator.

The onium salt suitably used in the present invention is an onium salt represented by any one of the following formulae (RI-I) to (RI-III):

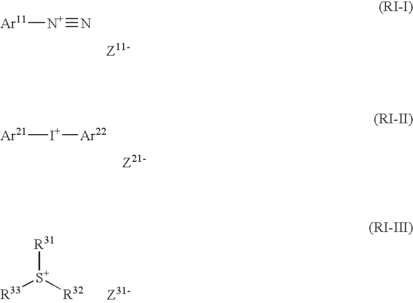

In formula (RI-I), Ar¹¹ represents an aryl group having a carbon number of 20 or less, which may have from 1 to 6 substituents, and preferred examples of the substituent include an alkyl group having a carbon number of 1 to 12, an alkenyl group having a carbon number of 1 to 12, an alkynyl group having a carbon number of 1 to 12, an aryl group having a carbon number of 1 to 12, an alkoxy group having a carbon number of 1 to 12, an aryloxy group having a carbon number of 1 to 12, a halogen atom, an alkylamino group having a carbon number of 1 to 12, a dialkylamino group having a carbon number of 1 to 12, an alkylamido or arylamido group having a carbon number of 1 to 12, a carbonyl group, a carboxyl group, a cyano group, a sulfonyl group, a thioalkyl group having a carbon number of 1 to 12, and a thioaryl group having a carbon number of 1 to 12. Z¹¹⁻ represents a monovalent anion and is a halide ion, a perchlorate ion, a hexafluorophosphate ion, a tetrafluoroborate ion, a sulfonate ion, a sulfinate ion, a thiosulfonate ion or a sulfate ion. In view of stability and visibility of the print-out image, the anion is preferably a perchlorate ion, a hexafluorophosphate ion, a tetrafluoroborate ion, a sulfonate ion or a sulfinate ion.

In formula (RI-II), Ar²¹ and Ar²² each independently represents an aryl group having a carbon number of 20 or less, which may have from 1 to 6 substituents, and preferred examples of the substituent include an alkyl group having a carbon number of 1 to 12, an alkenyl group having a carbon number of 1 to 12, an alkynyl group having a carbon number of 1 to 12, an aryl group having a carbon number of 1 to 12, an alkoxy group having a carbon number of 1 to 12, an aryloxy group having a carbon number of 1 to 12, a halogen atom, an alkylamino group having a carbon number of 1 to 12, a dialkylamino group having a carbon number of 1 to 12, an alkylamido or arylamido group having a carbon number of 1 to 12, a carbonyl group, a carboxyl group, a cyano group, a sulfonyl group, a thioalkyl group having a carbon number of 1 to 12, and a thioaryl group having a carbon number of 1 to 12. Z²¹⁻ represents a monovalent anion and is a halide ion, a perchlorate ion, a hexafluorophosphate ion, a tetrafluoroborate ion, a sulfonate ion, a sulfinate ion, a thiosulfonate ion or a sulfate ion. In view of stability and visibility of the print-out image, the anion is preferably a perchlorate ion, a hexafluorophosphate ion, a tetrafluoroborate ion, a sulfonate ion, a sulfinate ion or a carboxylate ion.

In formula (RI-III), R³¹, R³² and R³³ each independently represents an aryl, alkyl, alkenyl or alkynyl group having a carbon number of 20 or less, which may have from 1 to 6 substituents, and in view of reactivity and stability, is preferably an aryl group. Preferred examples of the substituent include an alkyl group having a carbon number of 1 to 12, an alkenyl group having a carbon number of 1 to 12, an alkynyl group having a carbon number of 1 to 12, an aryl group having a carbon number of 1 to 12, an alkoxy group having a carbon number of 1 to 12, an aryloxy group having a carbon number of 1 to 12, a halogen atom, an alkylamino group having a carbon number of 1 to 12, a dialkylamino group having a carbon number of 1 to 12, an alkylamido or arylamido group having a carbon number of 1 to 12, a carbonyl group, a carboxyl group, a cyano group, a sulfonyl group, a thioalkyl group having a carbon number of 1 to 12, and a thioaryl group having a carbon number of 1 to 12. Z³¹⁻ represents a monovalent anion and is a halide ion, a perchlorate ion, a hexafluorophosphate ion, a tetrafluoroborate ion, a sulfonate ion, a sulfinate ion, a thiosulfonate ion or a sulfate ion. In view of stability and visibility of the print-out image, the anion is preferably a perchlorate ion, a hexafluorophosphate ion, a tetrafluoroborate ion, a sulfonate ion, a sulfinate ion or a carboxylate ion, more preferably a carboxylate ion described in JP-A-2001-343742, still more preferably a carboxylate ion described in JP-A-2002-148790.

Examples of the onium salt compound suitably used as the polymerization initiator in the present invention are set forth below, but the present invention is not limited thereto.

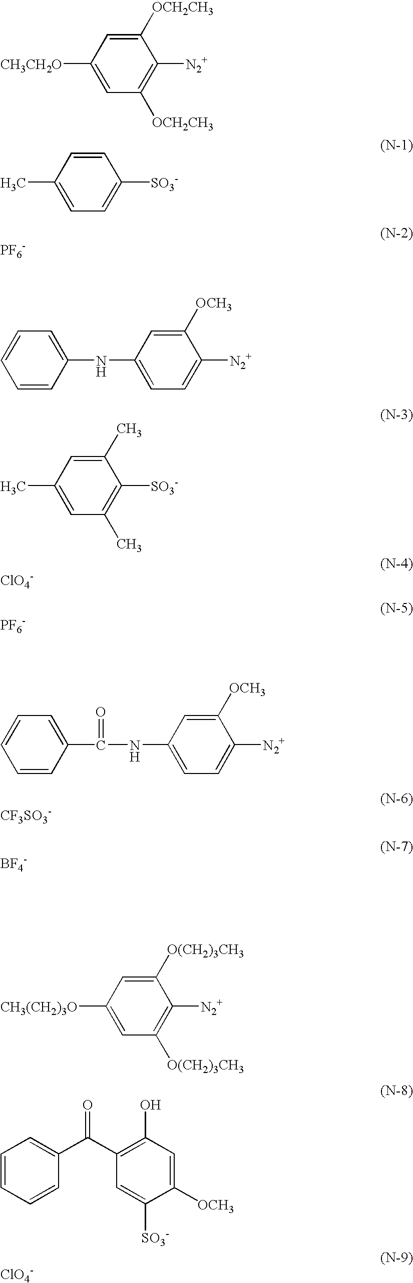

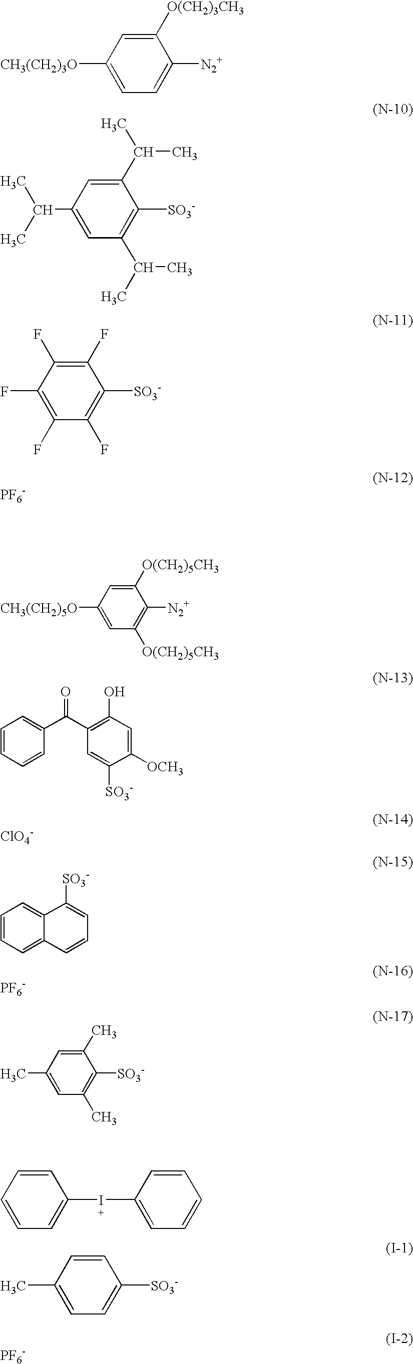

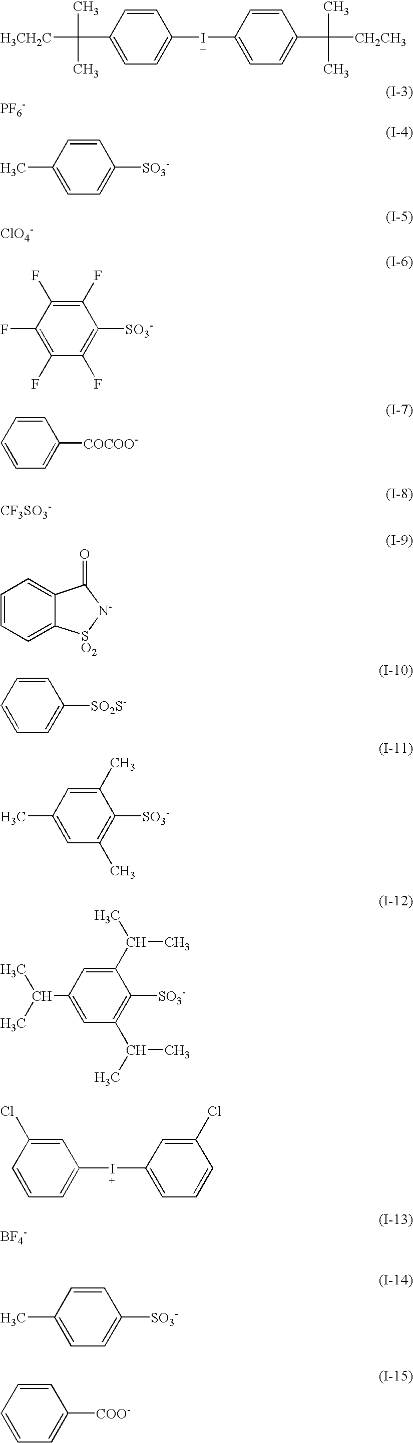

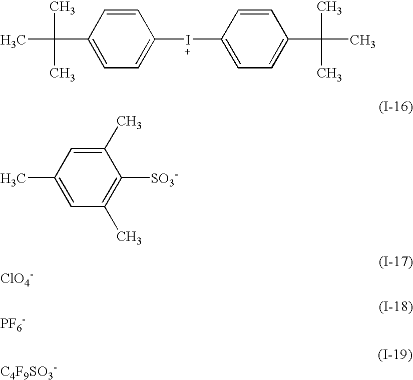

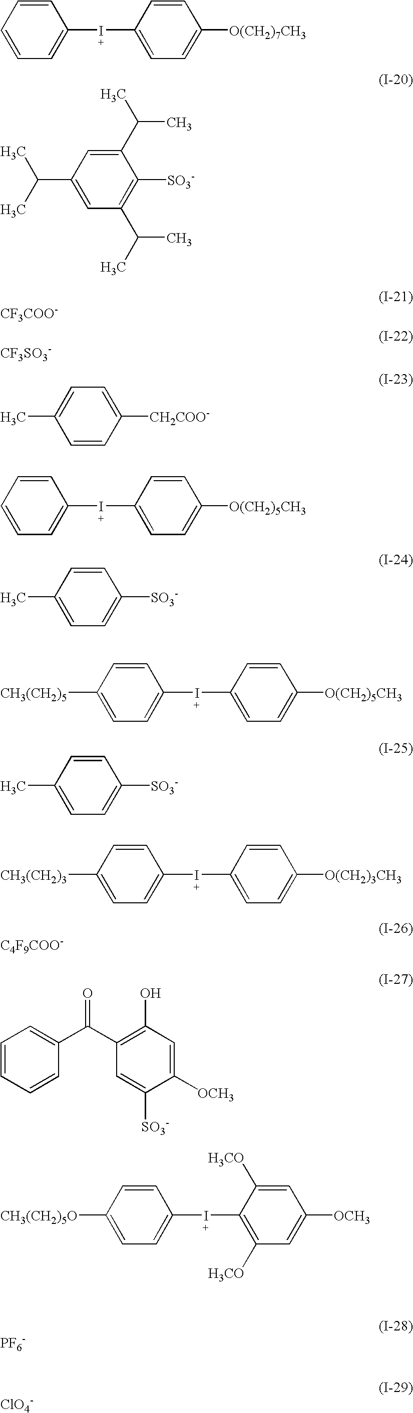

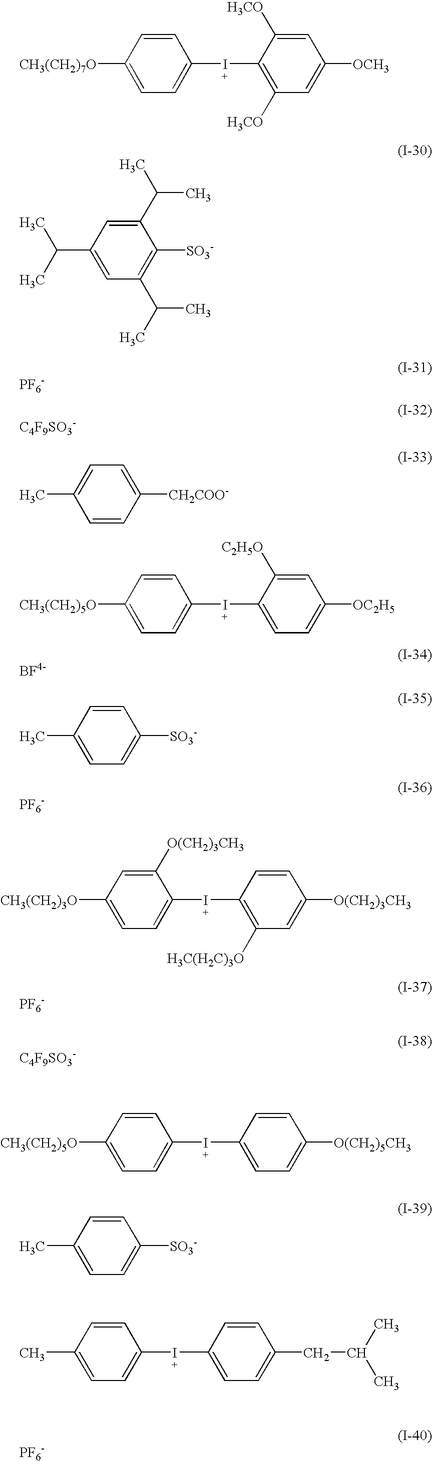

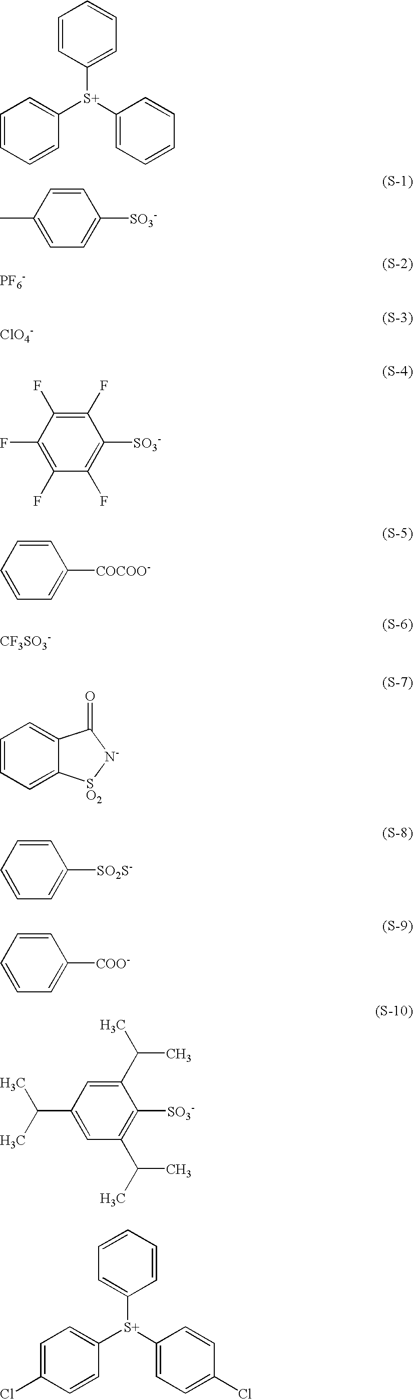

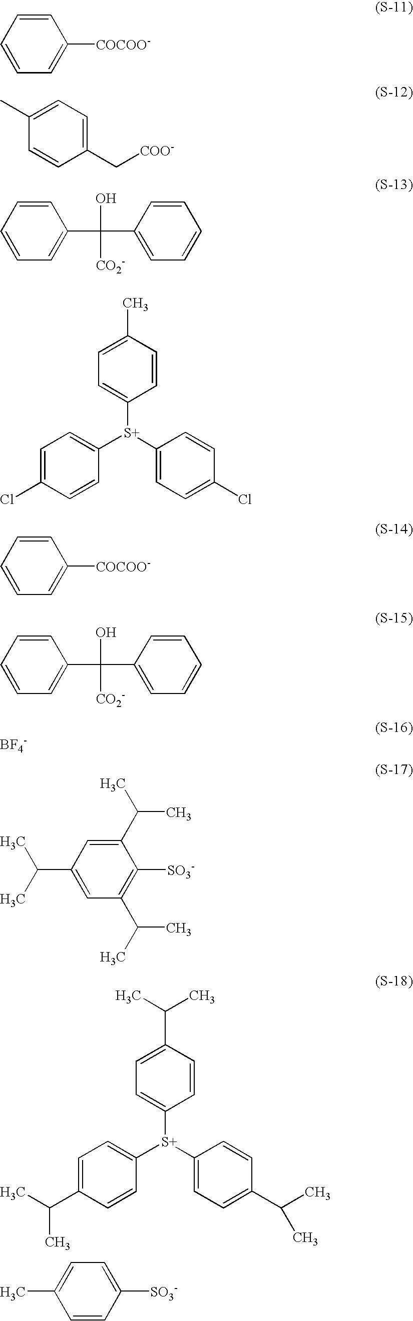

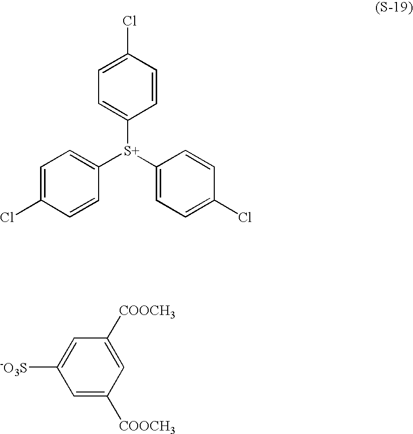

The polymerization initiator (B) is not limited to those described above, but above all, in view of reactivity and stability, (a) an organic halide, particularly a triazine-based initiator, (j) an oxime ester compound, and (k) an onium salt compound including a diazonium salt, an iodonium salt and a sulfonium salt are more preferred. Out of these polymerization initiators, from the standpoint of enhancing the visibility of the print-out image by the combination with an infrared absorbent, an onium salt having, as the counter ion, an inorganic anion such as PF₆⁻ or BF₄⁻ is preferred. Furthermore, the onium salt is preferably diaryl iodonium because of excellent color formation.

One of these polymerization initiators (B) may be used alone, or two or more thereof may be used in combination.

The polymerization initiator (B) may be added in a ratio of preferably 0.1 to 50 mass %, more preferably from 0.5 to 30 mass %, still more preferably from 0.8 to 20 mass %, based on all solid contents constituting the image forming layer. Within this range, good sensitivity and good staining resistance of the non-image part at the printing can be obtained.

The polymerization initiator (B) may be added together with other components in the same layer or may be added to another image forming layer separately provided or a layer adjacent thereto.

### <(C) Polymerizable Compound>

The polymerizable compound (C) which can be used in the present invention is an addition-polymerizable compound having at least one ethylenically unsaturated double bond and is selected from compounds having at least one, preferably two or more, terminal ethylenically unsaturated bonds. Such compounds are widely known in this industrial field and these known compounds can be used in the present invention without any particular limitation. These compounds have a chemical mode such as monomer, prepolymer (that is, dimer, trimer or oligomer) or a mixture or (co)polymer thereof.

Examples of the monomer and its copolymer include an unsaturated carboxylic acid (e.g., acrylic acid, methacrylic acid, itaconic acid, crotonic acid, isocrotonic acid, maleic acid), and esters and amides thereof. Among these, preferred are esters of an unsaturated carboxylic acid with an aliphatic polyhydric alcohol compound, and amides of an unsaturated carboxylic acid with an aliphatic polyvalent amine compound. Also, an addition reaction product of unsaturated carboxylic acid esters or amides having a nucleophilic substituent such as hydroxyl group, amino group or mercapto group with monofunctional or polyfunctional isocyanates or epoxies, and a dehydrating condensation reaction product with a monofunctional or polyfunctional carboxylic acid, may be suitably used. Furthermore, an addition reaction product of unsaturated carboxylic acid esters or amides having an electrophilic substituent such as isocyanate group or epoxy group with monofunctional or polyfunctional alcohols, amines or thiols, and a displacement reaction product of unsaturated carboxylic acid esters or amides having a leaving substituent such as halogen group or tosyloxy group with monofunctional or polyfunctional alcohols, amines or thiols, may also be suitably used. In addition, compounds where the unsaturated carboxylic acid of the above-described compounds is replaced by an unsaturated phosphonic acid, styrene, vinyl ether or the like, may also be used.

Specific examples of the ester monomer of an aliphatic polyhydric alcohol compound with an unsaturated carboxylic acid include the followings. Examples of the acrylic acid ester include ethylene glycol diacrylate, triethylene glycol diacrylate, 1,3-butanediol diacrylate, tetramethylene glycol diacrylate, propylene glycol diacrylate, neopentyl glycol diacrylate, trimethylolpropane triacrylate, trimethylolpropane tri(acryloyloxypropyl)ether, trimethylolethane triacrylate, hexanediol diacrylate, 1,4-cyclohexanediol diacrylate, tetraethylene glycol diacrylate, pentaerythritol diacrylate, pentaerythritol triacrylate, pentaerythritol tetraacrylate, dipentaerythritol diacrylate, dipentaerythritol hexaacrylate, sorbitol triacrylate, sorbitol tetraacrylate, sorbitol pentaacrylate, sorbitol hexaacrylate, tri(acryloyloxyethyl)isocyanurate and polyester acrylate oligomer.

Examples of the methacrylic acid ester include tetramethylene glycol dimethacrylate, triethylene glycol dimethacrylate, neopentyl glycol dimethacrylate, trimethylolpropane trimethacrylate, trimethylolethane trimethacrylate, ethylene glycol dimethacrylate, 1,3-butanediol dimethacrylate, hexanediol dimethacrylate, pentaerythritol dimethacrylate, pentaerythritol trimethacrylate, pentaerythritol tetramethacrylate, dipentaerythritol dimethacrylate, dipentaerythritol hexamethacrylate, sorbitol trimethacrylate, sorbitol tetramethacrylate, bis[p-(3-methacryloxy-2-hydroxypropoxy)-phenyl]dimethylmethane and bis[p-(methacryloxyethoxy)phenyl]dimethylmethane.

Examples of the itaconic acid ester include ethylene glycol diitaconate, propylene glycol diitaconate, 1,3-butanediol diitaconate, 1,4-butanediol diitaconate, tetramethylene glycol diitaconate, pentaerythritol diitaconate and sorbitol tetraitaconate.

Examples of the crotonic acid ester include ethylene glycol dicrotonate, tetramethylene glycol dicrotonate, pentaerythritol dicrotonate and sorbitol tetradicrotonate.

Examples of the isocrotonic acid ester include ethylene glycol diisocrotonate, pentaerythritol diisocrotonate and sorbitol tetraisocrotonate.

Examples of the maleic acid ester include ethylene glycol dimaleate, triethylene glycol dimaleate, pentaerythritol dimaleate and sorbitol tetramaleate.

Other suitable examples of the ester include aliphatic alcohol-based esters described in JP-B-51-47334 and JP-A-57-196231, those having an aromatic skeleton described in JP-A-59-5240, JP-A-59-5241 and JP-A-2-226149, and those containing an amino group described in JP-A-1-165613. Such ester monomers may also be used as a mixture.

Specific examples of the amide monomer of an aliphatic polyvalent amine compound with an unsaturated carboxylic acid include methylenebis-acrylamide, methylenebis-methacrylamide, 1,6-hexamethylenebis-acrylamide, 1,6-hexamethylenebis-methacrylamide, diethylenetriaminetrisacrylamide, xylylenebisacrylamide and xylylenebismethacrylamide. Other preferred examples of the amide-based monomer include those having a cyclohexylene structure described in JP-B-54-21726.

A urethane-based addition-polymerizable compound produced using an addition reaction of an isocyanate with a hydroxyl group is also preferred, and specific examples thereof include a vinyl urethane compound having two or more polymerizable vinyl groups within one molecule described in JP-B-48-41708, which is obtained by adding a vinyl monomer having a hydroxyl group represented by the following formula (ii) to a polyisocyanate compound having two or more isocyanate groups within one molecule:

CH₂═C(R⁴)COOCH₂CH(R⁵)OH (ii)

(wherein R⁴ and R⁵ each represents H or CH₃).

Also, urethane acrylates described in JP-A-51-37193, JP-B-2-32293 and JP-B-2-16765, and urethane compounds having an ethylene oxide-type skeleton described in JP-B-58-49860, JP-B-56-17654, JP-B-62-39417 and JP-B-62-39418 may be suitably used. Furthermore, when an addition-polymerizable compound having an amino or sulfide structure within the molecule described in JP-A-63-277653, JP-A-63-260909 and JP-A-1-105238 is used, a photopolymerizable composition very excellent in the photosensitization speed can be obtained.

Other examples include a polyfunctional acrylate or methacrylate such as polyester acrylates and epoxy acrylates obtained by the reaction of an epoxy resin with an acrylic or methacrylic acid, described in JP-A-48-64183, JP-B-49-43191 and JP-B-52-30490. In addition, specific unsaturated compounds described in JP-B-46-43946, JP-B-1-40337 and JP-B-1-40336, and a vinyl phosphonic acid-based compound described in JP-A-2-25493 may also be used. In some cases, a structure containing a perfluoroalkyl group described in JP-A-61-22048 is suitably used. Furthermore, those described as a photocurable monomer or oligomer in Adhesion, Vol. 20, No. 7, pp. 300-308 (1984) may also be used.

Details of the use method of these addition-polymerizable compounds, such as structure, single or combination use and amount added, can be freely selected in accordance with the performance design of the final lithographic printing plate precursor, for example, from the following standpoints.

In view of sensitivity, a structure having a large unsaturated group content per molecule is preferred and in most cases, a bifunctional or greater functional compound is preferred. For increasing the strength of the image part, namely, the cured film, a trifunctional or greater functional compound is preferred. Also, a method of controlling both the sensitivity and the strength by using a combination of compounds differing in the functional number or in the polymerizable group (for example, an acrylic acid ester, a methacrylic acid ester, a styrene-based compound or a vinyl ether-based compound) is effective.

The selection and use method of the addition-polymerizable compound are important factors also for the compatibility and dispersibility with other components (e.g., binder polymer, polymerization initiator, colorant) in the image forming layer. For example, the compatibility may be improved in some cases by using a low purity compound or using two or more compounds in combination. Also, a specific structure may be selected for the purpose of improving the adherence to the support, protective layer described later, or the like.

In the present invention, the polymerizable compound (C) is preferably used in an amount of 5 to 80 mass %, more preferably from 25 to 75 mass %, based on nonvolatile components in the image forming layer.

Other than these, as for the use method of the addition-polymerizable compound, an appropriate structure, formulation or amount added may be freely selected by taking into account the degree of polymerization inhibition due to oxygen, resolution, fogging, change in refractive index, surface tackiness and the like. Depending on the case, such a layer structure or a coating method as undercoat and overcoat may also be employed.

### <Other Components>

### (1) Surfactant

In the present invention, a surfactant may be used in the image forming layer so as to accelerate the development or enhance the coated surface state.

The surfactant includes, for example, a nonionic surfactant, an anionic surfactant, a cationic surfactant, an amphoteric surfactant and a fluorine-containing surfactant. One of these surfactants may be used alone, or two or more thereof may be used in combination.

The nonionic surfactant for use in the present invention is not particularly limited and a conventionally known nonionic surfactant can be used. Examples thereof include polyoxyethylene alkyl ethers, polyoxyethylene alkylphenyl ethers, polyoxyethylene polystyrylphenyl ethers, polyoxyethylene polyoxypropylene alkyl ethers, glycerin fatty acid partial esters, sorbitan fatty acid partial esters, pentaerythritol fatty acid partial esters, propylene glycol monofatty acid esters, sucrose fatty acid partial esters, polyoxyethylene sorbitan fatty acid partial esters, polyoxyethylene sorbitol fatty acid partial esters, polyethylene glycol fatty acid esters, polyglycerin fatty acid partial esters, polyoxyethylenated castor oils, polyoxyethylene glycerin fatty acid partial esters, fatty acid diethanolamides, N,N-bis-2-hydroxyalkylamines, a polyoxyethylene alkylamine, a triethanolamine fatty acid ester, a trialkylamine oxide, a polyethylene glycol, and a copolymer of polyethylene glycol and polypropylene glycol.

The anionic surfactant for use in the present invention is not particularly limited and a conventionally known anionic surfactant can be used. Examples thereof include fatty acid salts, abietates, hydroxyalkanesulfonates, alkanesulfonates, dialkylsulfosuccinic ester salts, linear alkylbenzenesulfonates, branched alkyl-benzenesulfonates, alkylnaphthalenesulfonates, alkyl-phenoxypolyoxyethylenepropylsulfonates, polyoxyethylenealkylsulfophenyl ether salts, an N-methyl-N-oleyltaurine sodium salt, a monoamide disodium N-alkylsulfosuccinate, petroleum sulfonates, sulfated beef tallow oil, sulfuric ester salts of fatty acid alkyl ester, alkylsulfuric ester salts, polyoxyethylene alkyl ether sulfuric ester salts, fatty acid monoglyceride sulfuric ester salts, polyoxyethylene alkylphenyl ether sulfuric ester salts, polyoxyethylene styrylphenyl ether sulfuric ester salts, alkylphosphoric ester salts, polyoxyethylene alkyl ether phosphoric ester salts, polyoxyethylene alkylphenyl ether phosphoric ester salts, partially saponified styrene/maleic anhydride copolymerization products, partially saponified olefin/maleic anhydride copolymerization products, and naphthalenesulfonate formalin condensates.

The cationic surfactant for use in the present invention is not particularly limited and a conventionally known cationic surfactant can be used. Examples thereof include alkylamine salts, quaternary ammonium salts, polyoxyethylene alkylamine salts and polyethylene polyamine derivatives.

The amphoteric surfactant for use in the present invention is not particularly limited and a conventionally known amphoteric surfactant can be used. Examples thereof include carboxybetaines, aminocarboxylic acids, sulfobetaines, aminosulfuric esters and imidazolines.

The term “polyoxyethylene” in the above-described surfactants can be instead read as “polyoxyalkylene” such as polyoxymethylene, polyoxypropylene and polyoxybutylene, and these surfactants can also be used in the present invention.

The surfactant is more preferably a fluorine-containing surfactant containing a perfluoroalkyl group within the molecule. This fluorine-containing surfactant includes an anionic type such as perfluoroalkylcarboxylate, perfluoroalkylsulfonate and perfluoroalkylphosphoric ester; an amphoteric type such as perfluoroalkylbetaine; a cationic type such as perfluoroalkyltrimethylammonium salt; and a nonionic type such as perfluoroalkylamine oxide, perfluoroalkyl ethylene oxide adduct, oligomer containing a perfluoroalkyl group and a hydrophilic group, oligomer containing a perfluoroalkyl group and a lipophilic group, oligomer containing a perfluoroalkyl group, a hydrophilic group and a lipophilic group, and urethane containing a perfluoroalkyl group and a lipophilic group. In addition, fluorine-containing surfactants described in JP-A-62-170950, JP-A-62-226143 and JP-A-60-168144 may also be suitably used.

One of these surfactants may be used alone, or two or more kinds thereof may be used in combination.

The surfactant content is preferably from 0.001 to 10 mass %, more preferably from 0.01 to 5 mass %, based on the entire solid content of the image forming layer.

### (2) Colorant

In the image forming layer for use in the present invention, a dye having large absorption in the visible light region can be used as a colorant for image. Specific examples thereof include Oil Yellow #101, Oil Yellow #103, Oil Pink #312, Oil Green BG, Oil Blue BOS, Oil Blue #603, Oil Black BY, Oil Black BS, Oil Black T-505 (all produced by Orient Chemical Industry Co., Ltd.), Victoria Pure Blue, Crystal Violet (CI42555), Methyl Violet (CI42535), Ethyl Violet, Rhodamine B (CI145170B), Malachite Green (CI42000), Methylene Blue (CI52015), and dyes described in JP-A-62-293247. Also, a pigment such as phthalocyanine-based pigment, azo-based pigment, carbon black and titanium oxide may be suitably used.

The colorant is preferably added because when used, the image part and the non-image part can be clearly distinguished after image formation.

The amount of the colorant added is from 0.01 to 10 mass % based on the entire solid content of the image forming layer.

### (3) Printing-Out Agent

In the image forming layer of the present invention, a compound capable of discoloring by the effect of an acid or a radical can be added so as to produce a print-out image.

As for such a compound, various coloring matters such as diphenylmethane type, triphenylmethane type, thiazine type, oxazine type, xanthene type, anthraquinone type, iminoquinone type, azo type and azomethine type may be effectively used.

Specific examples thereof include a dye such as Brilliant Green, Ethyl Violet, Methyl Green, Crystal Violet, Basic Fuchsine, Methyl Violet 2B, Quinaldine Red, Rose Bengale, Metanil Yellow, Thymolsulfophthalein, Xylenol Blue, Methyl Orange, Paramethyl Red, Congo Red, Benzopurpurine 4B, α-Naphthyl Red, Nile Blue 2B, Nile Blue A, Methyl Violet, Malachite Green, Parafuchsine, Victoria Pure Blue BOH [produced by Hodogaya Chemical Co., Ltd.], Oil Blue #603 [produced by Orient Chemical Industry Co., Ltd.], Oil Pink #312 [produced by Orient Chemical Industry Co., Ltd.], Oil Red 5B [produced by Orient Chemical Industry Co., Ltd.], Oil Scarlet #308 [produced by Orient Chemical Industry Co., Ltd.], Oil Red OG [produced by Orient Chemical Industry Co., Ltd.], Oil Red RR [produced by Orient Chemical Industry Co., Ltd.], Oil Green #502 [produced by Orient Chemical Industry Co., Ltd.], Spiron Red BEH Special [produced by Hodogaya Chemical Co., Ltd.], m-Cresol Purple, Cresol Red, Rhodamine B, Rhodamine 6G, Sulforhodamine B, Auramine, 4-p-diethyl-aminophenyliminonaphthoquinone, 2-carboxyanilino-4-p-diethylaminophenyliminonaphthoquinone, 2-carboxystearylamino-4-p-N,N-bis(hydroxyethyl)aminophenyliminonaphthoquinone, 1-phenyl-3-methyl-4-p-diethylaminophenylimino-5-pyrazolone and 1-p-naphthyl-4-p-diethylaminophenylimino-5-pyrazolone, and a leuco dye such as p,p′,p″-hexamethyl-triaminotriphenyl methane (Leuco Crystal Violet) and Pergascript Blue SRB (produced by Ciba Geigy).

Other suitable examples include leuco dyes known as a material for heat-sensitive or pressure-sensitive paper. Specific examples thereof include Crystal Violet Lactone, Malachite Green Lactone, Benzoyl Leuco Methylene Blue, 2-(N-phenyl-N-methylamino)-6-(N-p-tolyl-N-ethyl)aminofluorane, 2-anilino-3-methyl-6-(N-ethyl-p-toluidino)fluorane, 3,6-dimethoxyfluorane, 3-(N,N-diethylamino)-5-methyl-7-(N,N-dibenzylamino)fluorane, 3-(N-cyclohexyl-N-methylamino)-6-methyl-7-anilinofluorane, 3-(N,N-diethylamino)-6-methyl-7-anilinofluorane, 3-(N,N-diethylamino)-6-methyl-7-xylidinofluorane, 3-(N,N-diethylamino)-6-methyl-7-chlorofluorane, 3-(N,N-diethylamino)-6-methoxy-7-aminofluorane, 3-(N,N-diethylamino)-7-(4-chloroanilino)fluorane, 3-(N,N-diethylamino)-7-chlorofluorane, 3-(N,N-diethylamino)-7-benzylaminofluorane, 3-(N,N-diethylamino)-7,8-benzofluorane, 3-(N,N-dibutylamino)-6-methyl-7-anilinofluorane, 3-(N,N-dibutylamino)-6-methyl-7-xylidinofluorane, 3-piperidino-6-methyl-7-anilinofluorane, 3-pyrrolidino-6-methyl-7-anilinofluorane, 3,3-bis(1-ethyl-2-methylindol-3-yl)phthalide, 3,3-bis(1-n-butyl-2-methylindol-3-yl)phthalide, 3,3-bis(p-dimethylaminophenyl)-6-dimethylaminophthalide, 3-(4-diethylamino-2-ethoxyphenyl)-3-(1-ethyl-2-methylindol-3-yl)-4-phthalide and 3-(4-diethylaminophenyl)-3-(1-ethyl-2-methylindol-3-yl)phthalide.

The dye capable of discoloring by the effect of an acid or a radical is preferably added in a ratio of 0.01 to 10 mass % based on the solid content of the image forming layer.

### (4) Polymerization Inhibitor

In the image forming layer of the present invention, a small amount of a thermal polymerization inhibitor is preferably added so as to prevent unnecessary thermal polymerization of the polymerizable compound (C) during preparation or storage of the image forming layer.

Suitable examples of the thermal polymerization inhibitor include hydroquinone, p-methoxyphenol, di-tert-butyl-p-cresol, pyrogallol, tert-butyl catechol, benzoquinone, 4,4′-thiobis(3-methyl-6-tert-butylphenol), 2,2′-methylenebis(4-methyl-6-tert-butylphenol) and N-nitroso-N-phenylhydroxylamine aluminum salt.

The amount of the thermal polymerization inhibitor added is preferably from about 0.01 to about 5 mass % based on the entire solid content of the image forming layer.

### (5) Higher Fatty Acid Derivative, Etc.

In the image forming layer of the present invention, for example, a higher fatty acid derivative such as behenic acid or behenic acid amide may be added and unevenly distributed to the surface of the image forming layer in the process of drying after coating so as to prevent polymerization inhibition by oxygen.

The amount of the higher fatty acid derivative added is preferably from about 0.1 to about 10 mass % based on the entire solid content of the image forming layer.

### (6) Plasticizer

The image forming layer for use in the present invention may contain a plasticizer so as to enhance the developability.

Suitable examples of the plasticizer include phthalic acid esters such as dimethyl phthalate, diethyl phthalate, dibutyl phthalate, diisobutyl phthalate, diocyl phthalate, octyl capryl phthalate, dicyclohexyl phthalate, ditridecyl phthalate, butyl benzyl phthalate, diisodecyl phthalate and diallyl phthalate; glycol esters such as dimethyl glycol phthalate, ethyl phthalylethyl glycolate, methyl phthalylethyl glycolate, butyl phthalylbutyl glycolate and triethylene glycol dicaprylic acid ester; phosphoric acid esters such as tricresyl phosphate and triphenyl phosphate; aliphatic dibasic acid esters such as diisobutyl adipate, dioctyl adipate, dimethyl sebacate, dibutyl sebacate, dioctyl azelate and dibutyl maleate; polyglycidyl methacrylate, triethyl citrate, glycerin triacetyl ester and butyl laurate.

The plasticizer content is preferably about 30 mass % or less based on the entire solid content of the image forming layer.

### (7) Inorganic Fine Particle

The image forming layer for use in the present invention may contain an inorganic fine particle so as to increase the cured film strength and enhance the on-press developability.

Suitable examples of the inorganic fine particle include silica, alumina, magnesium oxide, titanium oxide, magnesium carbonate, calcium alginate and a mixture thereof. Such an inorganic fine particle can be used, for example, for strengthening the film or roughening the surface to intensify the interfacial adhesion.

The inorganic fine particle preferably has an average particle diameter of 5 nm to 10 μm, more preferably from 0.5 to 3 μm. Within this range, the inorganic particle is stably dispersed in the image forming layer and this enables maintaining sufficiently high film strength of the image forming layer and forming a non-image part with excellent hydrophilicity and less occurrence of staining at printing.

Such an inorganic fine particle is easily available on the market as a colloidal silica dispersion or the like.

The content of the inorganic fine particle is preferably 40 mass % or less, more preferably 30 mass % or less, based on the entire solid content of the image forming layer.

### (8) Hydrophilic Low-Molecular Compound

The image forming layer for use in the present invention may contain a hydrophilic low-molecular compound, because the developability can be enhanced without deteriorating the press life.

Examples of the hydrophilic low-molecular compound include, as the water-soluble organic compound, glycols and ether or ester derivatives thereof, such as ethylene glycol, diethylene glycol, triethylene glycol, propylene glycol, dipropylene glycol and tripropylene glycol; polyhydroxys such as glycerin and pentaerythritol; organic amines and salts thereof, such as triethanolamine, diethanolamine and monoethanolamine; organic sulfonic acids and salts thereof, such as alkylsulfonic acid, toluenesulfonic acid and benzenesulfonic acid; organic sulfamic acids and salts thereof, such as alkylsulfamic acid; organic sulfuric acids and salts thereof, such as alkylsulfuric acid and alkyl ether sulfuric acid; organic phosphonic acids and salts thereof, such as phenylphosphonic acid; and organic carboxylic acids and salts thereof, such as tartaric acid, oxalic acid, citric acid, malic acid, lactic acid, gluconic acid and amino acids.

Among these, an organic sulfonic acid, an organic sulfamic acid, and an organic sulfate such as sodium or lithium salt of organic sulfinuric acid, are preferred.

Specific examples of the organic sulfonate include sodium n-butylsulfonate, sodium isobutylsulfonate, sodium sec-butylsulfonate, sodium tert-butylsulfonate, sodium n-pentylsulfonate, sodium 1-ethylpropylsulfonate, sodium n-hexylsulfonate, sodium 1,2-dimethylpropylsulfonate, sodium 2-ethylbutylsulfonate, sodium cyclohexylsulfonate, sodium n-heptylsulfonate, sodium n-octylsulfonate, sodium tert-octylsulfonate, sodium n-nonylsulfonate, sodium allylsulfonate, sodium 2-methylallylsulfonate, sodium benzenesulfonate, sodium p-toluenesulfonate, sodium p-hydroxybenzenesulfonate, sodium p-styrenesulfonate, sodium isophthalic acid dimethyl-5-sulfonate, disodium 1,3-benzenedisulfonate, trisodium 1,3,5-benzenetrisulfonate, sodium p-chlorobenzenesulfonate, sodium 3,4-dichloro-benzenesulfonate, sodium 1-naphthylsulfonate, sodium 2-naphthylsulfonate, sodium 4-hydroxynaphthylsulfonate, disodium 1,5-naphthalyldisulfonate, disodium 2,6-naphthyldisulfonate, trisodium 1,3,6-naphthyltrisulfonate, and lithium salt compounds where sodium of these compounds is exchanged with lithium.

Specific examples of the organic sulfamate include sodium n-butylsulfamate, sodium isobutylsulfamate, sodium tert-butylsulfamate, sodium n-pentylsulfamate, sodium 1-ethylpropylsulfamate, sodium n-hexylsulfamate, sodium 1,2-dimethylpropylsulfamate, sodium 2-ethylbutylsulfamate, sodium cyclohexylsulfamate, and lithium salt compounds where sodium of these compounds is exchanged with lithium.

Such a compound has almost no surface activity action because of the hydrophobic moiety having a small structure and can be clearly distinguished from the above-described surfactant that allows good use of a long-chain alkylsulfonate, a long-chain alkylbenzenesulfonate or the like.

The organic sulfate which is particularly preferred is a compound represented by the following formula (iii):

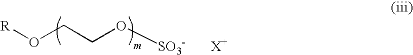

In formula (iii), R represents an alkyl group, an alkenyl group, an alkynyl group, an aryl group or a heterocyclic group, m represents an integer of 1 to 4, and X represents sodium, potassium or lithium.

R is preferably a linear, branched or cyclic alkyl group having a carbon number of 1 to 12, an alkenyl group having a carbon number of 1 to 12, an alkynyl group having a carbon number of 1 to 12, or an aryl group having a carbon number of 20 or less. These groups each may further has a substituent and in this case, examples of the substituent which can be introduced include a linear, branched or cyclic alkyl group having a carbon number of 1 to 12, an alkenyl group having a carbon number of 1 to 12, an alkynyl group having a carbon number of 1 to 12, a halogen atom, and an aryl group having a carbon number of 20 or less.

Preferred examples of the compound represented by formula (iii) include sodium oxyethylene-2-ethylhexyl ether sulfate, sodium dioxyethylene-2-ethylhexyl ether sulfate, potassium dioxyethylene-2-ethylhexyl ether sulfate, lithium dioxyethylene-2-ethylhexyl ether sulfate, sodium trioxyethylene-2-ethylhexyl ether sulfate, sodium tetraoxyethylene-2-ethylhexyl ether sulfate, sodium dioxyethylene-hexyl ether sulfate, sodium dioxyethylene-octyl ether sulfate, and sodium dioxyethylene-lauryl ether sulfate. Among these compounds, sodium dioxyethylene-2-ethylhexyl ether sulfate, potassium dioxyethylene-2-ethylhexyl ether sulfate and lithium dioxyethylene-2-ethylhexyl ether sulfate are most preferred.

The amount of the hydrophilic low-molecular compound added to the image forming layer is preferably from 0.5 to 20 mass %, more preferably from 1 to 10 mass %, still more preferably from 2 to 8 mass %, based on the entire solid content of the image forming layer. Within this range, good on-press developability and good press life are obtained.

One of these compounds may be used alone, or two or more kinds thereof may be mixed and used.

### (9) Ink Receptivity Agent

In the lithographic printing plate precursor of the present invention, a phosphonium compound may be added as an ink receptivity agent to the image forming layer and/or the protective layer for enhancing the inking property. Suitable phosphonium compounds include the compounds represented by the following formula (iv) described in JP-A-2006-297907 and the following formula (v) described in JP-A-2007-50660.

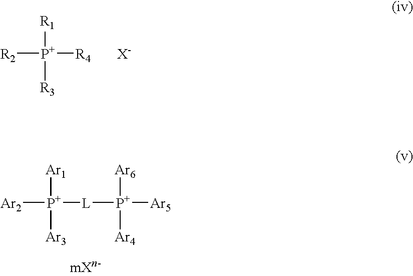

In formula (iv), R₁ to R₄ each independently represents an alkyl group, an alkenyl group, an alkynyl group, a cycloalkyl group, an alkoxy group, an aryl group, an aryloxy group, an alkylthio group, a heterocyclic group, each of which may have a substituent, or a hydrogen atom, at least two members out of R₁ to R₄ may combine to form a ring, and X⁻ represents a counter anion.

In formula (v), Ar₁ to Ar₆ each independently represents an aryl group or a heterocyclic group, L represents a divalent linking group, Xⁿ⁻ represents an n-valent counter anion, n represents an integer of 1 to 3, and m represents a number satisfying n×m=2. Suitable examples of the aryl group include a phenyl group, a naphthyl group, a tolyl group, a xylyl group, a fluorophenyl group, a chlorophenyl group, a bromophenyl group, a methoxyphenyl group, an ethoxyphenyl group, a dimethoxyphenyl group, a methoxycarbonylphenyl group and a dimethylaminophenyl group. Examples of the heterocyclic group include a pyridyl group, a quinolyl group, a pyrimidinyl group, a thienyl group and a furyl group. L represents a divalent linking group, and the number of carbon atoms in the linking group is preferably from 6 to 15, more preferably from 6 to 12. Preferred examples of the anion of Xⁿ⁻ include a halide anion such as Cl⁻, Br⁻ and I⁻, a sulfonate anion such as toluenesulfonate, naphthalene-1,7-disulfonate, naphthalene-1,3,6-trisulfonate and 5-benzoyl-4-hydroxy-2-methoxybenzene-4-sulfonate, a carboxylate anion, a sulfuric acid ester anion, PF₆⁻, BF₄⁻, and a perchlorate anion, with a sulfonate anion being more preferred.

Specific examples of the phosphonium compound represented by formula (iv) or (v) are set forth below.

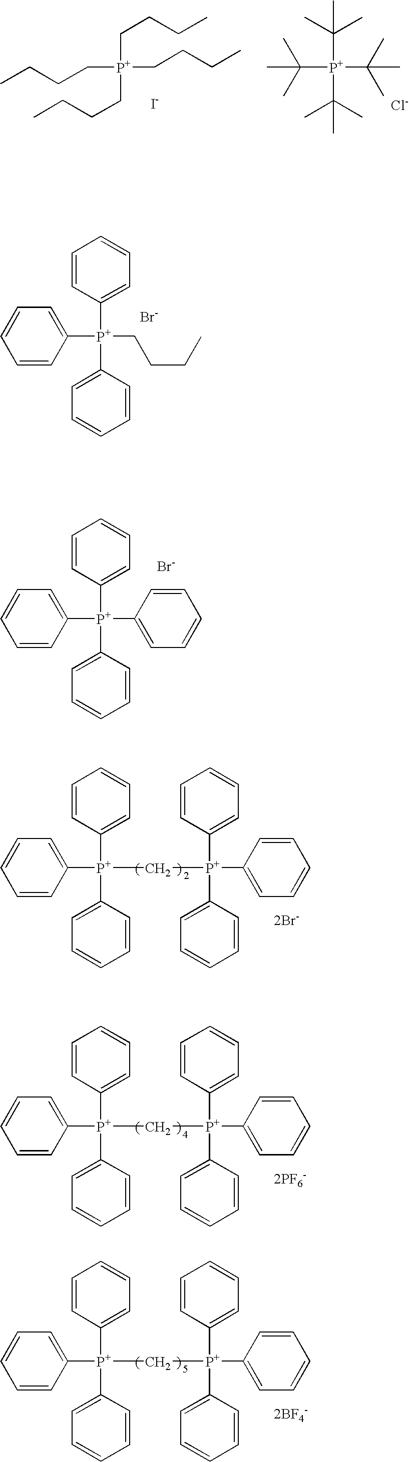

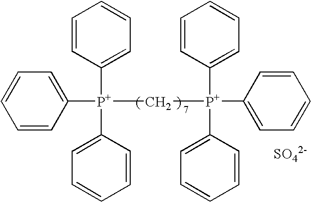

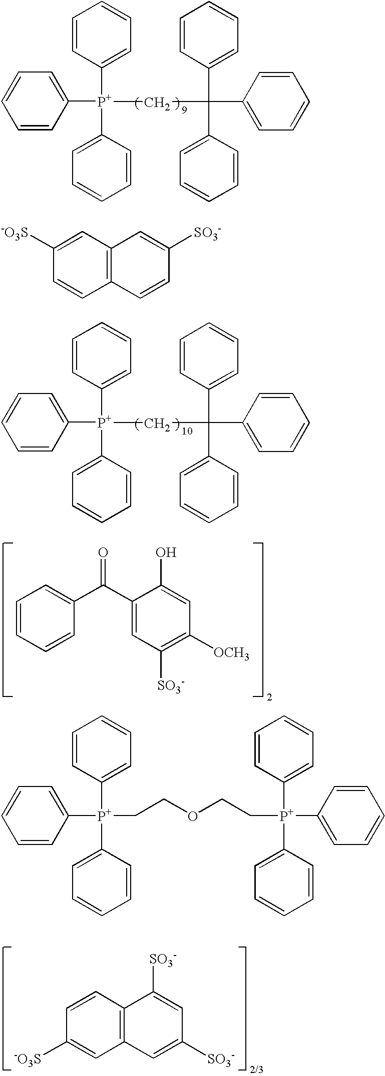

Other than the phosphonium compound, the nitrogen-containing low-molecular compound described below is also suitable as the ink receptivity agent. The nitrogen-containing compound is preferably a compound having a structure of the following formula (I).

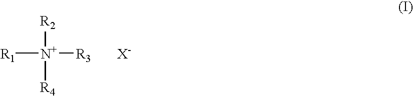

In the formula, R₁ to R₄ each independently represents a substituted or unsubstituted alkyl group, a substituted or unsubstituted alkenyl group, a substituted or unsubstituted alkynyl group, a substituted or unsubstituted cycloalkyl group, a substituted or unsubstituted alkoxy group, a substituted or unsubstituted aryl group, a substituted or unsubstituted aralkyl group, a substituted or unsubstituted heterocyclic group, or a hydrogen atom. At least two members out of R₁ to R₄ may combine to form a ring. X⁻ is an anion and represents PF₆⁻, BF₄⁻ or an organic sulfonate anion having a substituent selected from an alkyl group, an alkenyl group, an alkynyl group, a cycloalkyl group, an alkoxy group, an aryl group, an aralkyl group and a heterocyclic group.

That is, the nitrogen-containing compound for use in the present invention may be amine salts where at least one of R₁ to R₄ is a hydrogen atom, or quaternary ammonium salts where all of R₁ to R₄ are not a hydrogen atom, or may have a structure of imidazolinium salts represented by the following formula (II), benzimidazolinium salts represented by the following formula (III), pyridinium salts represented by the following formulas (IV), or quinolinium salts represented by the following formula (V).

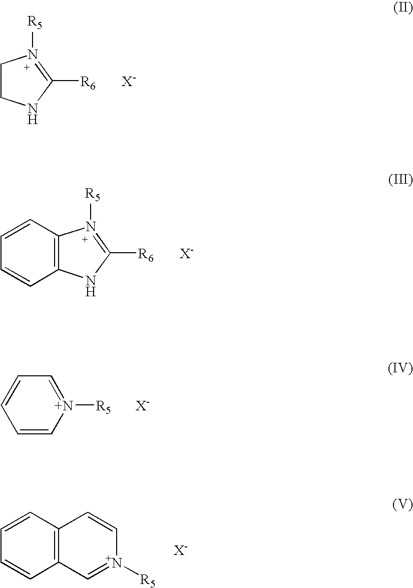

In the formulae, R₅ and R₆ each represents a substituted or unsubstituted alkyl group, a substituted or unsubstituted alkenyl group, a substituted or unsubstituted alkynyl group, a substituted or unsubstituted a cycloalkyl group, a substituted or unsubstituted alkoxy group, a substituted or unsubstituted aryl group, a substituted or unsubstituted aralkyl group, a substituted or unsubstituted heterocyclic group, or a hydrogen atom, and X⁻ is an anion and similarly to the above, represents PF₆⁻, BF₄⁻ or an organic sulfonate anion having a substituent selected from an alkyl group, an alkenyl group, an alkynyl group, a cycloalkyl group, an alkoxy group, an aryl group, an aralkyl group and a heterocyclic group.

Among these, quaternary ammonium salts and pyridinium salts are preferred.

Specific examples of the quaternary ammonium salts are set forth below.

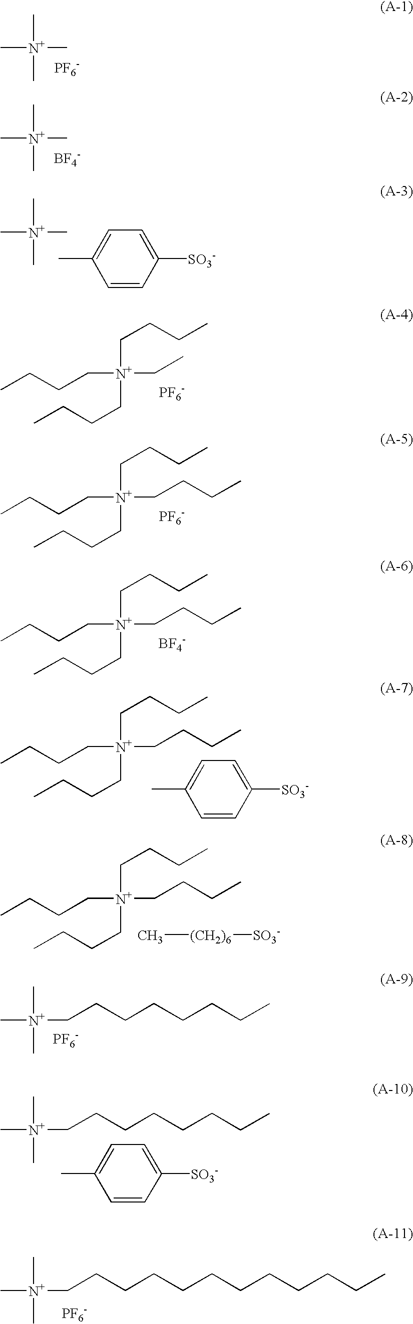

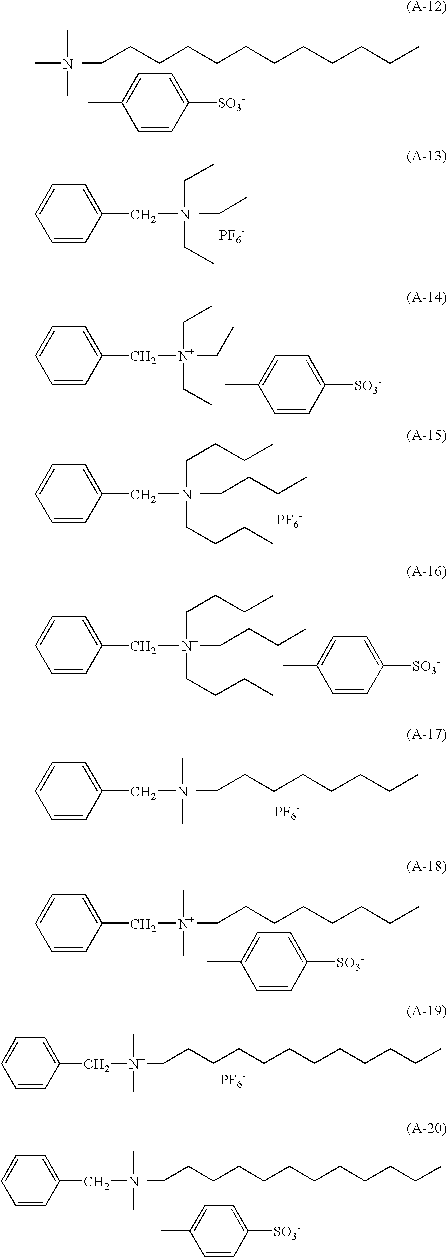

Specific examples of the pyridinium salts are set forth below.

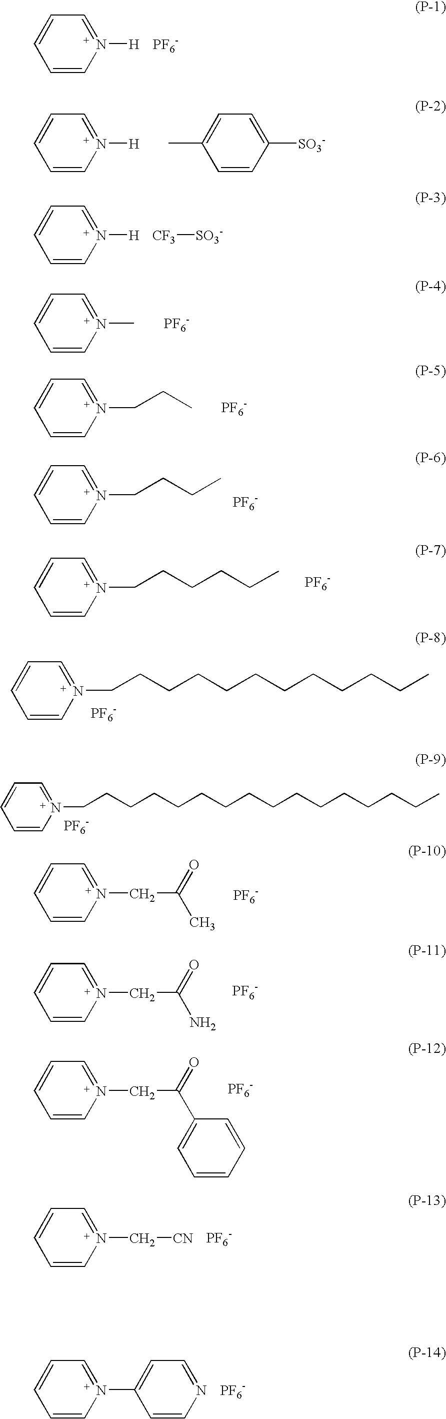

The amount of the ink receptivity agent added to the image forming layer or protective layer is preferably from 0.01 to 20 mass %, more preferably from 0.05 to 10 mass %, and most preferably from 0.1 to 5 mass %, based on the solid content of each layer. Within this range, good inking property can be obtained.

### (10) Co-Sensitizer

In the image recording layer for use in the present invention, a known compound called a chain transfer agent or a co-sensitizer having an action of, for example, more increasing the sensitivity or suppressing the polymerization inhibition due to oxygen may be added.

Examples of this compound include amines such as compounds described in M. R. Sander et al., Journal of Polymer Society, Vol. 10, page 3173 (1972), JP-B-44-20189, JP-A-51-82102, JP-A-52-134692, JP-A-59-138205, JP-A-60-84305, JP-A-62-18537, JP-A-64-33104 and Research Disclosure, No. 33825, and specific examples thereof include a triethanolamine, an N-phenylglycine, an N-phenylaspartic acid, and an N,N-dialkylaniline derivative such as ethyl p-dimethylaminobenzoate, p-formyldimethylaniline and p-methylthiodimethylaniline.

Other examples of the compound acting as the chain transfer agent include compounds having SH, PH, SiH or GeH in the molecule. Such a compound donates hydrogen to a radical species of low activity to generate a radical, or is oxidized and then deprotonated to generate a radical.

In the image recording layer for use in the present invention, a thiol compound (e.g., 2-mercaptobenzimidazoles, 2-mercaptobenzothiazoles, 2-mercaptobenzoxazoles, 3-mercaptotriazoles, 5-mercaptotetrazoles) may be preferably used as the chain transfer agent.

Above all, a thiol compound represented by the following formula (VI) described in JP-A-2006-091479 is particularly preferred. By using this thiol compound as the chain transfer agent, the problem of odor and the reduction in sensitivity due to evaporation of the compound from the image recording layer or diffusion into other layers can be avoided, and a lithographic printing plate precursor with excellent storage stability as well as high sensitivity and high press life can be obtained.

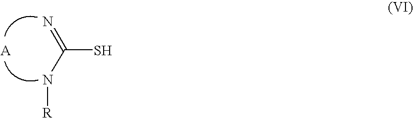

In formula (VI), R represents an alkyl group which may have a substituent or an aryl group which may have a substituent, A represents an atomic group necessary for forming a 5-membered or 6-membered heterocyclic ring containing a carbon atom together with the N═C—N moiety, and A may further have a substituent.

A compound represented by the following formula (VIA) or (VIB) is more preferred.

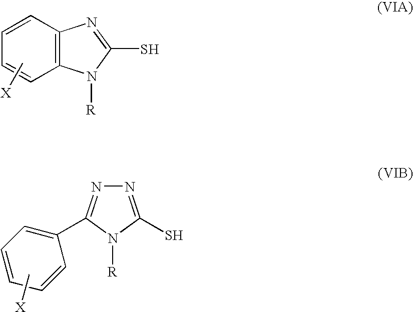

In formulae (VIA) and (VIB), R represents a hydrogen atom, an alkyl group which may have a substituent or an aryl group which may have a substituent, and X represents a halogen atom, an alkoxy group, an alkyl group which may have a substituent, or an aryl group which may have a substituent.

Specific examples of the compounds include 1-methyl-2-mercaptobenzimidazole, 1-propyl-2-mercaptobenzimidazole, 1-hexyl-2-mercaptobenzimidazole, 1-hexyl-2-mercapto-5-chlorobenzimidazole, 1-pentyl-2-mercaptobenzimidazole, 1-octyl-2-mercaptobenzimidazole, 1-octyl-2-mercapto-5-methoxybenzimidazole, 1-cyclohexyl-2-mercaptobenzimidazole, 1-phenyl-2-mercaptobenzimidazole, 1-phenyl-2-mercapto-5-methylsulfonylbenzimidazole, 1-(p-tolyl)-2-mercaptobenzimidazole, 1-methoxyethyl-2-mercaptobenzimidazole, 1-butyl-2-mercaptobenzimidazole, 1-methyl-2-mercapto-5-phenyl-1,3,5-triazole, 1-butyl-2-mercapto-5-phenyl-1,3,5-triazole, 1-heptyl-2-mercapto-5-phenyl-1,3,5-triazole, 1-phenyl-2-mercapto-5-phenyl-1,3,5-triazole, 1-benzyl-2-mercapto-5-phenyl-1,3,5-triazole, 1-phenethyl-2-mercapto-5-phenyl-1,3,5-triazole, 1-cyclohexyl-2-mercapto-5-phenyl-1,3,5-triazole, 1-phenethyl-2-mercapto-5-(3-fluorophenyl)-1,3,5-triazole, 1-phenethyl-2-mercapto-5-(3-trifluoromethylphenyl)-1,3,5-triazole, 1-benzyl-2-mercapto-5-(p-tolyl)-1,3,5-triazole, 1-benzyl-2-mercapto-5-(4-methoxyphenyl)-1,3,5-triazole, 1-benzyl-2-mercapto-5-(p-trifluoromethylphenyl)-1,3,5-triazole, 1-benzyl-2-mercapto-5-(3,5-dichlorophenyl)-1,3,5-triazole, 1-phenyl-2-mercapto-5-(p-tolyl)-1,3,5-triazole, 1-phenyl-2-mercapto-5-(4-methoxyphenyl)-1,3,5-triazole, 1-(1-naphthyl)-2-mercapto-5-phenyl-1,3,5-triazole, 1-(4-bromophenyl)-2-mercapto-5-phenyl-1,3,5-triazole, 1-(4-trifluorophenyl)-2-mercapto-5-phenyl-1,3,5-triazole and 6-bromo-2-mercapto-benzimidazole.

The amount of the chain transfer agent used is preferably from 0.01 to 20 mass %, more preferably from 0.1 to 15 mass %, still more preferably from 1.0 to 10 mass %, based on the mass of all solid components in the image recording layer.

### <Formation of Image Forming Layer>

The image forming layer for use in the present invention is formed by dispersing or dissolving the above-described necessary components in a solvent to prepare a coating solution, applying the coating solution on a support, and drying the coating.

Examples of the solvent used here include, but are not limited to, ethylene dichloride, cyclohexanone, methyl ethyl ketone, methanol, ethanol, propanol, ethylene glycol monomethyl ether, 1-methoxy-2-propanol, 2-methoxyethyl acetate, 1-methoxy-2-propyl acetate, dimethoxyethane, methyl lactate, ethyl lactate, N,N-dimethylacetamide, N,N-dimethylformamide, tetramethylurea, N-methylpyrrolidone, dimethylsulfoxide, sulfolane, γ-butyl lactone, toluene and water. One of these solvents may be used alone, or several kinds thereof may be mixed and used. The solid content concentration of the coating solution is preferably from 1 to 50 mass %.

The image forming layer for use in the present invention may also be formed as an image forming layer having a multilayer structure by dispersing or dissolving the same or different components described above in the same or different solvents to prepare a plurality of coating solutions and repeating the coating and drying a plurality of times.

The coated amount (as solid content) of the image forming layer obtained on the support after coating and drying varies depending on the use but, in general, is preferably from 0.3 to 3.0 g/m². Within this range, good sensitivity and good film properties of the image forming layer can be obtained.

For the coating, various methods may be used and examples thereof include bar coater coating, spin coating, spray coating, curtain coating, dip coating, air knife coating, blade coating and roll coating.

### (Protective Layer)

The lithographic printing plate precursor of the invention preferably comprises a protective layer (overcoat layer) on the image forming layer.

The protective layer has a function of blocking oxygen to prevent an image formation inhibiting reaction and also has a function of preventing, for example, scratching in the image forming layer or ablation at the exposure with a high illuminance laser.

Components and the like constituting the protective layer are described below.

Usually, exposure of a lithographic printing plate is performed in the air. The image forming reaction occurred in the image forming layer upon exposure may be inhibited by a low molecular weight compound such as oxygen or basic substance present in the air. The protective layer prevents the low molecular weight compound such as oxygen or basic substance from intermixing into the image forming layer and as a result, suppresses the reaction of inhibiting image formation in the air. Accordingly, the property required of the protective layer is low permeability to the low molecular compound such as oxygen. Furthermore, the protective layer is required to have good transparency to light used for exposure and excellent adherence to the image forming layer and be easily removable in the on-press development process after exposure. The protective layer having such properties is described, for example, in U.S. Pat. No. 3,458,311 and JP-B-55-49729.

As for the material used in the protective layer, both a water-soluble polymer and a water-insoluble polymer may be appropriately selected and used. Specific examples thereof include a water-soluble polymer such as polyvinyl alcohol, modified polyvinyl alcohol, polyvinylpyrrolidone, polyvinylimidazole, polyacrylic acid, polyacrylamide, partially saponified polyvinyl acetate, ethylene-vinyl alcohol copolymer, water-soluble cellulose derivative, gelatin, starch derivative and gum arabic; and a polymer such as polyvinylidene chloride, poly(meth)acrylonitrile, polysulfone, polyvinyl chloride, polyethylene, polycarbonate, polystyrene, polyamide and cellophane.

Two or more kinds of these materials may be used in combination, if desired.

Out of these materials, the relatively useful material includes a water-soluble polymer compound with excellent crystallinity. Specific suitable examples thereof include polyvinyl alcohol, polyvinylpyrrolidone, polyvinylimidazole, a water-soluble acrylic resin such as polyacrylic acid, gelatin and gum arabic. Among these, in view of being coatable by using water as a solvent and easily removable with a fountain solution at the printing, polyvinyl alcohol, polyvinylpyrrolidone and polyvinylimidazole are preferred. Above all, polyvinyl alcohol (PVA) provides best results in terms of fundamental properties such as oxygen blocking and removability in development.

The polyvinyl alcohol usable in the protective layer may be partially substituted by an ester, an ether or an acetal as long as it contains a substantial amount of an unsubstituted vinyl alcohol unit having necessary water solubility. Similarly, the polyvinyl alcohol may partially contain other copolymerization components. Examples of such a polyvinyl alcohol which can be preferably used include polyvinyl alcohols having various polymerization degrees and having various hydrophilic modified sites at random, such as anion-modified site modified with an anion (e.g., carboxyl, sulfo), cation-modified site modified with a cation (e.g., amino, ammonium), silanol-modified site and thiol-modified site; and polyvinyl alcohols having various polymerization degrees and having various modified sites at the polymer chain terminal, such as anion-modified site described above, cation modified site described above, silanol-modified site, thiol-modified site, alkoxy-modified site, sulfide-modified site, ester-modified site modified with an ester of vinyl alcohol and various organic acids, ester-modified site modified with an ester of the above-described anion-modified site and alcohols, and epoxy-modified site.

Among these, an anion-modified polyvinyl alcohol is most preferred because of good dispersion stability in the developer for use in the present invention. The content of the anion-modified polyvinyl alcohol is preferably from 10 to 50 mass %, more preferably from 20 to 40 mass %, based on the entire solid content of the protective layer.

The suitable modified polyvinyl alcohol includes a compound being hydrolyzed in a ratio of 71 to 100 mol % and having a polymerization degree of 300 to 2,400. Specific examples thereof include PVA-105, PVA-110, PVA-117, PVA-117H, PVA-120, PVA-124, PVA-124H, PVA-CS, PVA-CST, PVA-HC, PVA-203, PVA-204, PVA-205, PVA-210, PVA-217, PVA-220, PVA-224, PVA-217EE, PVA-217E, PVA-220E, PVA-224E, PVA-405, PVA-420, PVA-613 and L-8, produced by Kuraray Co., Ltd.

Other examples of the modified polyvinyl alcohol include KL-318, KL-118, KM-618, KM-118, SK-5102 and CKS-50 each having an anion-modified site; C-318, C-118 and CM-318 each having a cation-modified site; M-205 and M-115 each having a terminal thiol-modified site; MP-103, MP-203, MP-102 and MP-202 each having a terminal sulfide-modified site; HL-12E and HL-1203 each having an ester-modified site with a higher fatty acid at the terminal; and R-1130, R-2105 and R-2130 each having other reactive silane-modified site.

The protective layer preferably also contains an inorganic layered compound, that is, a compound which is an inorganic compound having a layered structure and has a tabular shape. By using such an inorganic layered compound in combination, the oxygen blocking property is more enhanced and not only the film strength of the protective layer is more increased to raise the scratch resistance but also a matting property can be imparted to a specific protective layer.

Examples of the inorganic layered compound include a mica family such as natural mica and synthetic mica, represented by the formula: A(B,C)₂-5D₄O₁₀(OH,F,O)₂, [wherein A is Li, K, Na, Ca, Mg or an organic cation, B and C each is Fe(II), Fe(III), Mn, Al, Mg or V, and D is Si or Al]; a talc represented by the formula: 3MgO.4SiO.H₂O; taeniolite; montmorillonite; saponite; hectorite; and zirconium phosphate.

Out of the mica compounds, examples of the natural mica include muscovite, paragonite, phlogopite, biotite and lepidolite. Examples of the synthetic mica include a non-swelling mica such as fluorophlogopite KMg₃(AlSi₃O₁₀)F₂ and potassium tetrasilicon mica KMg_{2.5}(Si₄O₁₀)F₂; and a swelling mica such as Na tetrasilicic mica NaMg_{2.5}(Si₄O₁₀)F₂, Na or Li taeniolite (Na,Li)Mg₂Li(Si₄O₁₀)F₂, and montmorillonite-based Na or Li hectorite (Na,Li)_{1/8}Mg_{2/5}Li_{1/8}(Si₄O₁₀)F₂. Synthetic smectite is also useful.

Among these mica compounds, a fluorine-based swelling mica that is a synthetic layered compound is particularly useful. More specifically, the swelling clay minerals such as mica, montmorillonite, saponite, hectorite and bentonite have a laminate structure comprising a unit crystal lattice layer having a thickness of approximately from 10 to 15 Å and are significantly larger in the extent of the intra-lattice metallic atom substitution than other clay minerals. As a result, the lattice layer causes lack of positive charge and in order to compensate for the lack, a cation such as Li⁺, Na⁺, Ca²⁺, Mg²⁺ and organic cation (e.g., amine salt, quaternary ammonium salt, phosphonium salt, sulfonium salt) is adsorbed between layers. The layered compound swells with water and when a shear force is applied in this state, the layers are easily cleaved to form a stable sol in water. This tendency is strong in bentonite and swelling synthetic mica, and these materials are useful in the present invention. Above all, in view of easy availability and uniform quality, swelling synthetic mica is preferred.

The shape of the layered compound is tabular and from the standpoint of diffusion control, the thickness is preferably as small as possible. Also, insofar as the smoothness of the coated surface or the transmission of the actinic ray is not inhibited, the plane size is preferably as large as possible. Accordingly, the aspect ratio is 20 or more, preferably 100 or more, more preferably 200 or more. Incidentally, the aspect ratio is a ratio of the thickness to the long diameter of a particle and may be determined, for example, from a projection drawing by a microphotograph of particles. As the aspect ratio is larger, the effect obtained is greater.

As for the particle diameter of the layered compound, the average long diameter is from 0.3 to 20 μm, preferably from 0.5 to 10 μm, more preferably from 1 to 5 μm. If the particle diameter is less than 0.3 μm, permeation of oxygen or moisture is insufficiently inhibited and the effect brought out is not enough, whereas if it exceeds 20 μm, dispersion stability in the coating solution is insufficient and this causes a problem that the coating cannot be stably performed. The average thickness of the particle is 0.1 μm or less, preferably 0.05 μm or less, more preferably 0.01 μm or less. For example, the swelling synthetic mica as a typical compound out of the inorganic layered compounds has a thickness of 1 to 50 nm and a plane size of approximately from 1 to 20 μm.

When a particle of such an inorganic layered compound having a large aspect ratio is incorporated into the protective layer, the coated film strength is increased and permeation of oxygen or moisture can be effectively inhibited, as a result, the protective layer is prevented from deterioration due to deformation or the like and the lithographic printing plate precursor obtained can have excellent storage stability without causing reduction in the image forming property due to change in the humidity even if stored under high humidity condition for a long period of time.

An example of the dispersion method in general when using a layered compound in the protective layer is described below.

First, from 5 to 10 parts by mass of the swelling layered compound described above as a preferred layered compound is added to 100 parts by mass of water and after well wetting and swelling with water, dispersed by means of a dispersing machine. Examples of the dispersing machine used here include various mills of directly applying a mechanical force to effect dispersing, a high-speed stirring dispersing machine having a high shear force, and a dispersing machine giving a high-intensity ultrasonic energy. Specific examples thereof include a ball mill, a sand grinder mill, a viscomill, a colloid mill, a homogenizer, a dissolver, a Polytron, a homomixer, a homoblender, a KD mill, a jet agitator, a capillary emulsifier, a liquid siren, an electromagnetic strain ultrasonic generator, and an emulsifier having a Pohlman whistle. The dispersion containing from 5 to 10 mass % of the inorganic layered compound dispersed by the method above is highly viscous or gelled and exhibits extremely good storage stability.

At the time of preparing the coating solution for protective layer by using this dispersion, the coating solution is preferably prepared by diluting the dispersion with water and after thoroughly stirring, blending it with a binder solution.

The content of the inorganic layered compound in the protective layer is preferably from 5/1 to 1/100 in terms of the mass ratio based on the amount of the binder used in the protective layer. Even in the case of using a plurality of kinds of inorganic layered compounds in combination, the total amount of these inorganic layered compounds is preferably in the range of mass ratio above.

As to other additives to the protective layer, for example, glycerin, dipropylene glycol, propionamide, cyclohexanediol or sorbitol may be added to the water-soluble or water-insoluble polymer in an amount of several mass % based on the polymer so as to impart flexibility. Also, a known additive such as water-soluble (meth)acrylic polymer or water-soluble plasticizer may be added so as to improve the physical properties of the film.

In the present invention, the protective layer is formed using the later-described coating solution for protective layer, and in this coating solution, known additives for enhancing the adherence to the image forming layer or the aging stability of the coating solution may be added.

That is, in the coating solution for protective layer, an anionic surfactant, a nonionic surfactant, a cationic surfactant or a fluorine-containing surfactant may be added for enhancing the coatability, and specific examples thereof include an anionic surfactant such as sodium alkylsulfate and sodium alkylsulfonate; an amphoteric surfactant such as alkylaminocarboxylate and alkylaminodicarboxylate; and a nonionic surfactant such as polyoxyethylene alkyl phenyl ether. The amount of the surfactant added may be from 0.1 to 100 mass % based on the water-soluble or water-insoluble polymer.

In addition, for improving the adherence to the image part, it is indicated, for example, in JP-A-49-70702 and British Patent Publication 1303578 that sufficiently high adhesion can be obtained when from 20 to 60 mass % of an acrylic emulsion, a water-insoluble vinylpyrrolidone-vinyl acetate copolymer or the like is mixed with a hydrophilic polymer mainly composed of polyvinyl alcohol and the polymer is stacked on the image forming layer. In the present invention, these known techniques all can be used.

Other functions may also be imparted to the protective layer. For example, by adding a colorant (e.g., water-soluble dye) having excellent transparency to the infrared light used for exposure and being capable of efficiently absorbing light at other wavelengths, the safelight immunity can be enhanced without causing reduction in the sensitivity.

The coating solution for protective layer prepared by dispersing or dissolving these protective layer components in a solvent is coated on the image forming layer and dried, whereby the protective layer is formed.

The coating solvent may be appropriately selected according to the binder but in the case of using a water-soluble polymer, distilled water or purified water is preferably used as the solvent.

The coating method of the protective layer is not particularly limited, and a known method such as method described in U.S. Pat. No. 3,458,311 and JP-B-55-49729 may be applied.

Specific examples of the coating method when forming the protective layer include a blade coating method, an air knife coating method, a gravure coating method, a roll coating method, a spray coating method, a dip coating method and a bar coating method.

The coated amount of the protective layer is, in terms of the coated amount after drying, preferably from 0.02 to 3 g/m², more preferably from 0.05 to 1 g/m², and most preferably from 0.1 to 0.4 g/m².

### (Support)

The support for use in the lithographic printing plate precursor of the present invention is not particularly limited and may be sufficient if it is a dimensionally stable plate-like material. Examples thereof include paper, paper laminated with plastic (e.g., polyethylene, polypropylene, polystyrene), metal plate (e.g., aluminum, zinc, copper), plastic film (e.g., cellulose diacetate, cellulose triacetate, cellulose propionate, cellulose butyrate, cellulose acetate butyrate, cellulose nitrate, polyethylene terephthalate, polyethylene, polystyrene, polypropylene, polycarbonate, polyvinyl acetal), and paper or plastic film laminated or vapor-deposited with the above-described metal.

Among these supports, polyester film and aluminum plate are preferred, and aluminum plate is more preferred because this is dimensionally stable and relatively inexpensive.

The aluminum plate is a pure aluminum plate, an alloy plate mainly comprising aluminum and containing trace heteroelements, or an aluminum or aluminum alloy thin film laminated with a plastic. Examples of the heteroelement contained in the aluminum alloy include silicon, iron, manganese, copper, magnesium, chromium, zinc, bismuth, nickel and titanium. The heteroelement content in the alloy is preferably 10 mass % or less. In the present invention, a pure aluminum plate is preferred, but perfectly pure aluminum is difficult to produce in view of refining technique and therefore, an aluminum plate containing trace heteroelements may be used. The composition of the aluminum plate is not particularly specified, and a conventionally known and commonly employed material can be appropriately used.

In advance of using the aluminum plate, the aluminum plate is preferably subjected to a surface treatment such as surface roughening and anodization. This surface treatment facilitates enhancing hydrophilicity and ensuring adherence between the image forming layer and the support. Before surface-roughening the aluminum plate, a degreasing treatment for removing the rolling oil on the surface is performed, if desired, by using a surfactant, an organic solvent, an alkaline aqueous solution or the like.

The surface-roughening treatment of the aluminum plate surface is performed by various methods, and examples thereof include a mechanical surface-roughening treatment, an electrochemical surface-roughening treatment (a surface-roughening treatment of electrochemically dissolving the surface) and a chemical surface-roughening treatment (a surface-roughening treatment of chemically and selectively dissolving the surface).

The mechanical surface-roughening treatment may be performed by a known method such as ball polishing, brush polishing, blast polishing and buff polishing. A transfer method of transferring an uneven profile in the rolling step of aluminum by using a roll having provided thereon irregularities may also be used.

The method for the electrochemical surface-roughening treatment includes, for example, a method of performing the treatment by passing an alternating or direct current in an electrolytic solution containing an acid such as hydrochloric acid or nitric acid. Furthermore, a method using a mixed acid described in JP-A-54-63902 may also be used.

The surface-roughened aluminum plate is, if desired, subjected to an alkali etching treatment using an aqueous solution of potassium hydroxide, sodium hydroxide or the like and after a neutralization treatment, further subjected to an anodization treatment, if desired, so as to enhance the abrasion resistance.

As for the electrolyte used in the anodization treatment of the aluminum plate, various electrolytes of forming a porous oxide film may be used. In general, a sulfuric acid, a hydrochloric acid, an oxalic acid, a phosphoric acid, a chromic acid or a mixed acid thereof is used. Among these, a sulfuric acid, an oxalic acid and a phosphoric acid are preferred, and a phosphoric acid is more preferred. The electrolyte concentration is appropriately determined according to the kind of the electrolyte.

The anodization treatment conditions vary depending on the electrolyte used and cannot be indiscriminately specified, but in general, the conditions are preferably such that the electrolyte concentration is from 1 to 80 mass %, the liquid temperature is from 5 to 70° C., the current density is from 5 to 60 A/dm², the voltage is from 1 to 100 V, and the electrolysis time is from 10 seconds to 5 minutes. The amount of the anodic oxide film formed is preferably from 1.0 to 5.0 g/m², more preferably from 1.5 to 4.0 g/m². Within this range, good press life and good scratch resistance of the non-image part of the lithographic printing plate can be obtained.

As for the support used in the present invention, the substrate having thereon an anodic oxide film after the above-described surface treatment may be directly used, but in order to more improve the performance such as adhesion to upper layer, hydrophilicity, difficult staining or heat insulation, for example, a treatment for enlarging or sealing micropores of the anodic oxide film described in JP-A-2001-253181 and JP-A-2001-322365, or a treatment for making the surface hydrophilic by dipping the substrate in an aqueous solution containing a hydrophilic compound, may be appropriately selected and applied. Of course, the enlarging treatment and pore-sealing treatment are not limited to those described in these patent publications and any conventionally known method may be employed. For example, the pore-sealing treatment may be pore-sealing with steam, pore-sealing with fluorozirconic acid alone, treatment with sodium fluoride, or pore-sealing with steam having added thereto lithium chloride.

The pore-sealing treatment for use in the present invention is not particularly limited, and a conventionally known method may be used. In particular, a pore-sealing treatment with an aqueous solution containing an inorganic fluorine compound, a pore-sealing treatment with water vapor, and a pore-sealing treatment with hot water are preferred. These are described below.

<1> Pore-Sealing Treatment with Aqueous Solution Containing Inorganic Fluorine Compound

The inorganic fluorine compound used in the pore-sealing treatment with an aqueous solution containing an inorganic fluorine compound is suitably a metal fluoride.

Specific examples thereof include sodium fluoride, potassium fluoride, calcium fluoride, magnesium fluoride, sodium fluorozirconate, potassium fluorozirconate, sodium fluorotitanate, potassium fluorotitanate, ammonium fluorozirconate, ammonium fluorotitanate, potassium fluorotitanate, fluorozirconic acid, fluorotitanic acid, hexafluorosilicic acid, nickel fluoride, iron fluoride, fluorophosphoric acid and ammonium fluorophosphate. Among these, sodium fluorozirconate, sodium fluorotitanate, fluorozirconic acid and fluorotitanic acid are preferred.

The concentration of the inorganic fluorine compound in the aqueous solution is, from the standpoint of satisfactorily sealing micropores of the anodic oxide film, preferably 0.01 mass % or more, more preferably 0.05 mass % or more, and in view of staining resistance, preferably 1 mass % or less, more preferably 0.5 mass % or less.

The aqueous solution containing an inorganic fluorine compound preferably further contains a phosphate compound. When a phosphate compound is contained, the hydrophilicity on the anodic oxide film surface increases and in turn, the on-press developability and staining resistance can be enhanced.

Suitable examples of the phosphate compound include a phosphate of metal such as alkali metal and alkaline earth metal.

Specific examples thereof include zinc phosphate, aluminum phosphate, ammonium phosphate, diammonium hydrogenphosphate, ammonium dihydrogenphosphate, monoammonium phosphate, monopotassium phosphate, monosodium phosphate, potassium dihydrogenphosphate, dipotassium hydrogenphosphate, calcium phosphate, sodium ammonium hydrogenphosphate, magnesium hydrogenphosphate, magnesium phosphate, ferrous phosphate, ferric phosphate, sodium dihydrogenphosphate, sodium phosphate, disodium hydrogen-phosphate, lead phosphate, diammonium phosphate, calcium dihydrogenphosphate, lithium phosphate, phosphotungstic acid, ammonium phosphotungstate, sodium phosphotungstate, ammonium phosphomolybdate, sodium phosphomolybdate, sodium phosphite, sodium tripolyphosphate and sodium pyrophosphate. Among these, sodium dihydrogenphosphate, disodium hydrogenphosphate, potassium dihydrogenphosphate and dipotassium hydrogenphosphate are preferred.

The combination of the inorganic fluorine compound and the phosphate compound is not particularly limited, but the aqueous solution preferably contains at least sodium fluorozirconate as the inorganic fluorine compound and at least sodium dihydrogenphosphate as the phosphate compound.

The concentration of the phosphate compound in the aqueous solution is, from the stand point of enhancing the on-press developability and staining resistance, preferably 0.01 mass % or more, more preferably 0.1 mass % or more, and in view of solubility, preferably 20 mass % or less, more preferably 5 mass % of less.

The ratio of respective compounds in the aqueous solution is not particularly limited, but the mass ratio between the inorganic fluorine compound and the phosphate compound is preferably from 1/200 to 10/1, more preferably from 1/30 to 2/1.

The temperature of the aqueous solution is preferably 20° C. or more, more preferably 40° C. or more, and preferably 100° C. or less, more preferably 80° C. or less.

The pH of the aqueous solution is preferably 1 or more, more preferably 2 or more, and preferably 11 or less, more preferably 5 or less. The method for the pore-sealing treatment with an aqueous solution containing an inorganic fluorine compound is not particularly limited, but examples thereof include a dipping method and a spray method. One of these methods may be used alone once or a plurality of times, or two or more thereof may be used in combination.

Above all, a dipping method is preferred. In the case of performing the treatment by using a dipping method, the treating time is preferably 1 second or more, more preferably 3 seconds or more, and preferably 100 seconds or less, more preferably 20 seconds or less.

<2> Pore-Sealing Treatment with Water Vapor

Examples of the pore-sealing treatment with water vapor include a method of continuously or discontinuously bringing water vapor under applied pressure or normal pressure into contact with the anodic oxide film.

The temperature of the water vapor is preferably 80° C. or more, more preferably 95° C. or more, and preferably 105° C. or less.

The pressure of the water vapor is preferably from (atmospheric pressure−50 mmAq) to (atmospheric pressure+300 mmAq) (from 1.008×10⁵ to 1.043×10⁵ Pa).

The time for which water vapor is contacted is preferably 1 second or more, more preferably 3 seconds or more, and preferably 100 seconds or less, more preferably 20 seconds or less.

<3> Pore-Sealing Treatment with Hot Water

Examples of the pore-sealing treatment with hot water include a method of dipping the aluminum plate having formed thereon the anodic oxide film in hot water.

The hot water may contain an inorganic salt (e.g., phosphate) or an organic salt.

The temperature of the hot water is preferably 80° C. or more, more preferably 95° C. or more, and preferably 100° C. or less.

The time for which the aluminum plate is dipped in hot water is preferably 1 second or more, more preferably 3 seconds or more, and preferably 100 seconds or less, more preferably 20 seconds or less.

The hydrophilic treatment includes an alkali metal silicate method described in U.S. Pat. Nos. 2,714,066, 3,181,461, 3,280,734 and 3,902,734. In this method, the support is subjected to a dipping or electrolysis treatment in an aqueous solution of sodium silicate or the like. Other examples include a method of treating the support with potassium fluorozirconate described in JP-B-36-22063, a method of treating the support with a polyacrylic acid described in U.S. Pat. No. 3,136,636, and a method of treating the support with a polyvinylphosphonic acid described in U.S. Pat. Nos. 3,276,868, 4,153,461 and 4,689,272. Among these, an alkali metal silicate treatment and a polyvinylphosphonic acid treatment are preferred, and a polyvinylphosphonic acid treatment is more preferred.

In the case where a support insufficient in the hydrophilicity on the surface, such as polyester film, is used as the support of the present invention, a hydrophilic layer is preferably coated to make the surface hydrophilic. The hydrophilic layer is preferably a hydrophilic layer formed by applying a coating solution containing a colloid of an oxide or hydroxide of at least one element selected from beryllium, magnesium, aluminum, silicon, titanium, boron, germanium, tin, zirconium, iron, vanadium, antimony and a transition metal described in JP-A-2001-199175, a hydrophilic layer having an organic hydrophilic matrix obtained by crosslinking or pseudo-crosslinking an organic hydrophilic polymer described in JP-A-2002-79772, a hydrophilic layer having an inorganic hydrophilic matrix obtained by sol-gel conversion comprising hydrolysis and condensation reaction of polyalkoxysilane, titanate, zirconate or aluminate, or a hydrophilic layer composed of an inorganic thin film having a metal oxide-containing surface. Among these, a hydrophilic layer formed by applying a coating solution containing a colloid of silicon oxide or hydroxide is more preferred.

In the case of using a polyester film or the like as the support of the present invention, an antistatic layer is preferably provided on the hydrophilic layer side or opposite side of the support or on both sides. When an antistatic layer is provided between the support and the hydrophilic layer, this contributes also to the enhancement of adherence to the hydrophilic layer. Examples of the antistatic layer which can be used include a polymer layer having dispersed therein a metal oxide fine particle or a matting agent described in JP-A-2002-79772.

The support preferably has a centerline average roughness of 0.10 to 1.2 μm. Within this range, good adherence to the image forming layer, good press life and good difficulty of staining can be obtained.

The thickness of the support is preferably from 0.1 to 0.6 mm, more preferably from 0.15 to 0.4 mm.

### (Backcoat Layer)

After the support is subjected to a surface treatment or an undercoat layer (described later) is formed, a backcoat may be provided on the back surface of the support, if desired.

Suitable examples of the backcoat layer include a coat layer composed of an organic polymer compound described in JP-A-5-45885 and a coat layer composed of a metal oxide obtained by hydrolyzing and polycondensing an organic or inorganic metal compound described in JP-A-6-35174. Above all, use of an alkoxy compound of silicon, such as Si(OCH₃)₄, Si(OC₂H₅)₄, Si(OC₃H₇)₄ and Si(OC₄H₉)₄, is preferred because the raw material is inexpensive and easily available.

### (Undercoat Layer)

In the lithographic printing plate precursor for use in the present invention, an undercoat layer may be provided between the image forming layer and the support, if desired.

The undercoat layer facilitates the separation of the image forming layer from the support in the unexposed area and therefore, the developability is enhanced. Also, in the case of infrared laser exposure, the undercoat layer functions as a heat insulating layer and the heat generated upon exposure can be efficiently utilized without diffusing into the support, so that high sensitivity can be advantageously achieved.

Specific suitable examples of the undercoat layer compound include a silane coupling agent having an addition-polymerizable ethylenic double bond reactive group described in JP-A-10-282679, and a phosphorus compound having an ethylenic double bond reactive group described in JP-A-2-304441.

A most preferred undercoat layer compound is a polymer resin having a substrate-adsorbing group (hereinafter, simply referred to as an “adsorbing group”), a hydrophilic group and a crosslinking group. This polymer resin is preferably obtained by copolymerizing a monomer having an adsorbing group, a monomer having a hydrophilic group and a monomer having a crosslinking group.

The polymer resin for undercoat layer preferably has an adsorbing group to the hydrophilic support surface. The presence or absence of adsorptivity to the hydrophilic support surface can be judged, for example, by the following method.

A test compound is dissolved in a solvent capable of easily dissolving the compound to prepare a coating solution, and the coating solution is coated and dried on a support such that the coated amount after drying becomes 30 mg/m². Thereafter, the support coated with the test compound is thoroughly washed with a solvent capable of easily dissolving the compound and after measuring the residual amount of the test compound that is not removed by washing, the amount adsorbed to the support is calculated. Here, in the measurement of the residual amount, the amount of the residual compound may be directly determined or the residual amount may be calculated after quantitatively determining the test compound dissolved in the washing solution. The quantitative determination of the compound may be performed, for example, by fluorescent X-ray measurement, reflection spectral absorbance measurement or liquid chromatography measurement. The support-adsorbing compound is a compound which remains in an amount of 1 mg/m² or more even when the above-described washing treatment is performed.

The adsorbing group to the hydrophilic support surface is a functional group capable of causing chemical bonding (for example, ionic bonding, hydrogen bonding, coordination bonding, or bonding by intermolecular force) with a substance (e.g., metal, metal oxide) or functional group (e.g., hydroxy group) present on the hydrophilic support surface. The adsorbing group is preferably an acid group or a cationic group.

The acid group preferably has an acid dissociation constant (pKa) of 7 or less. Examples of the acid group include a phenolic hydroxyl group, a carboxyl group, —SO₃H, —OSO₃H, —PO₃H₂, —OPO₃H₂, —CONHSO₂—, —SO₂NHSO₂ and —COCH₂COCH₃. Among these, —OPO₃H₂ and PO₃H₂ are preferred. Also, these acid groups each may be in the form of a metal salt.

The cationic group is preferably an onium group. Examples of the onium group include an ammonium group, a phosphonium group, an arsonium group, a stibonium group, an oxonium group, a sulfonium group, a selenonium group, a stannonium group and an iodonium group. Among these, an ammonium group, a phosphonium group and a sulfonium group are preferred, an ammonium group and a phosphonium group are more preferred, and an ammonium group is most preferred.

Particularly preferred examples of the monomer having an adsorbing group, which is used in the synthesis of a polymer resin suitable as the compound for the undercoat layer, include compounds represented by the following formulae (U1) and (U2).

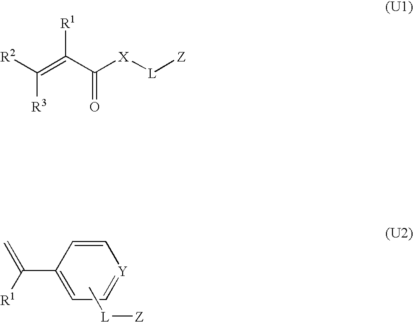

In formulae (U1) and (U2), R¹, R² and R³ each independently represents a hydrogen atom, a halogen atom or an alkyl group having a carbon number of 1 to 6.

R¹, R² and R³ each is independently preferably a hydrogen atom or an alkyl group having a carbon number of 1 to 6, more preferably a hydrogen atom or an alkyl group having a carbon number of 1 to 3, and most preferably a hydrogen atom or a methyl group. In particular, R² and R³ each is preferably a hydrogen atom.

Z is a functional group adsorbing to the hydrophilic support surface, and the adsorbing functional group is as described above.

In formulae (U1) and (U2), L represents a single bond or a divalent linking group.

L is preferably a divalent aliphatic group (e.g., alkylene, substituted alkylene, alkenylene, substituted alkenylene, alkynylene, substituted alkynylene), a divalent aromatic group (e.g., arylene, substituted arylene), a divalent heterocyclic group, or a combination of such a group with an oxygen atom (—O—), a sulfur atom (—S—), an imino (—NH—), a substituted imino (—NR—, wherein R is an aliphatic group, an aromatic group or a heterocyclic group) or a carbonyl (—CO—).

The divalent aliphatic group may have a cyclic structure or a branched structure. The number of carbon atoms in the divalent aliphatic group is preferably from 1 to 20, more preferably from 1 to 15, and most preferably from 1 to 10. Also, the divalent aliphatic group is preferably a saturated aliphatic group rather than an unsaturated aliphatic group. The divalent aliphatic group may have a substituent, and examples of the substituent include a halogen atom, a hydroxy group, an aromatic group and a heterocyclic group.

The number of carbon atoms in the divalent aromatic group is preferably from 6 to 20, more preferably from 6 to 15, and most preferably from 6 to 10. The divalent aromatic group may have a substituent, and examples of the substituent include a halogen atom, a hydroxy group, an aromatic group and a heterocyclic group.

The divalent heterocyclic group preferably contains a 5-membered or 6-membered ring as the heterocyclic ring. Also, another heterocyclic ring, an aliphatic ring or an aromatic ring may be condensed to the heterocyclic ring. The divalent heterocyclic group may have a substituent, Examples of the substituent include a halogen atom, a hydroxy group, an oxo group (—O), a thioxo group (═S), an imino group (═NH), a substituted imino group (═N—R, wherein R is an aliphatic group, an aromatic group or a heterocyclic group), an aliphatic group, an aromatic group and a heterocyclic group.

In the present invention, L is preferably a divalent linking group containing a plurality of polyoxyalkylene structures. The polyoxyalkylene structure is preferably a polyoxyethylene structure. In other words, L preferably contains —(OCH₂CH₂)ₙ— (wherein n is an integer of 2 or more).

In Formula (U1), X represents an oxygen atom (—O—) or an imino group (—NH—). X is preferably an oxygen atom.

In Formula (U2), Y represents a carbon atom or a nitrogen atom. When Y is a nitrogen atom and L is bound on Y to form a quaternary pyridinium group, the quaternary pyridinium group itself exhibits adsorbing property. In this case, therefore, the functional group of Z is not essential, and Z may be a hydrogen atom.

Representative examples of the compounds of formulae (U1) and (U2) are set forth below.

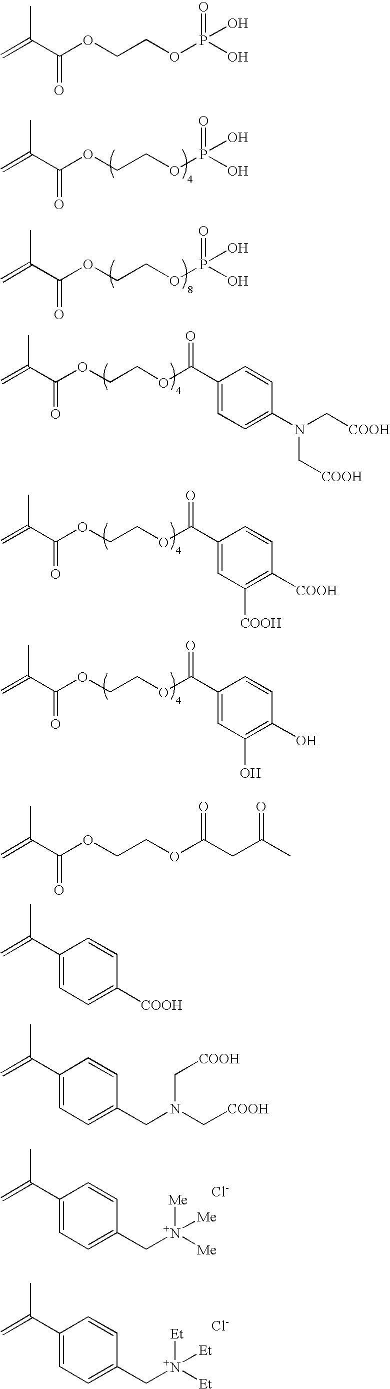

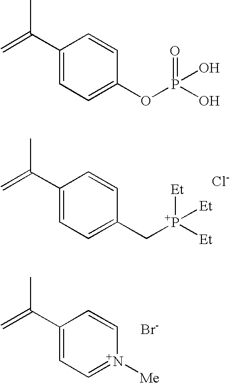

The polymer resin suitable as the compound for the undercoat layer preferably has a hydrophilic group. Suitable examples of the hydrophilic group include a hydroxy group, a carboxyl group, a carboxylate group, a hydroxyethyl group, a polyoxyethyl group, a hydroxypropyl group, a polyoxypropyl group, an amino group, an aminoethyl group, an aminopropyl group, an ammonium group, an amido group, a carboxymethyl group, a sulfo group and a phosphoric acid group. Among these, a sulfo group exhibiting high hydrophilicity is preferred.

Specific examples of the monomer having a sulfo group include sodium salts and amine salts of methallyl oxybenzenesulfonic acid, allyloxybenzenesulfonic acid, allylsulforic acid, vinylsulfonic acid, p-styrenesulfonic acid, methallylsulfonic acid, acrylamide tert-butylsulfonic acid, 2-acrylamido-2-methylpropanesulfonic acid and (3-acryloyloxypropyl)butylsulfonic acid. Among these, sodium 2-acrylamido-2-methylpropanesulfonate is preferred in view of hydrophilic performance and handling in the synthesis.

Such a monomer is appropriately used in synthesizing a polymer resin suitable as the compound for the undercoat layer.

The polymer resin for the undercoat layer used in the present invention preferably has a crosslinking group. By virtue of the crosslinking group, adherence to the image part is enhanced. In order to impart crosslinking property to the polymer resin for the undercoat layer, this may be attained by introducing a crosslinking functional group such as ethylenically unsaturated bond into the side chain of the polymer, or by forming a salt structure from a compound containing an ethylenically unsaturated bond and a substituent having an opposite charge to the charge of the polar substituent on the polymer resin.

Examples of the polymer having an ethylenically unsaturated bond in the side chain of the molecule include a polymer which is a polymer of acrylic or methacrylic acid ester or amide and in which the ester or amide residue (R in —COOR or —CONHR) has an ethylenically unsaturated bond.

Examples of the residue (R above) having an ethylenically unsaturated bond include —CH═CH₂, —C(CH₃)═CH₂, —(CH₂)ₙCR¹═CR²R³, —(CH₂O)ₙCH₂CR¹═CR²R³, —(CH₂CH₂O)ₙCH₂CR¹═CR²R³, —(CH₂)ₙNH—CO—O—CH₂CR¹═CR²R³, —(CH₂)ₙ—O—CO—CR¹═CR²R³ and (CH₂CH₂O)₂—X (wherein R¹ to R³ each represents a hydrogen atom, a halogen atom or an alkyl, aryl, alkoxy or aryloxy group having a carbon number of 1 to 20, R¹ and R² or R³ may combine together to form a ring, n represents an integer of 1 to 10, and X represents a dicyclopentadienyl residue).

Specific examples of the ester residue include —CH═CH₂, —C(CH₃)═CH₂, —CH₂CH═CH₂ (described in JP-B-7-21633), —CH₂CH₂O—CH₂CH═CH₂, —CH₂C(CH₃)═CH₂, —CH₂CH═CH—C₆H₅, —CH₂CH₂OCOCH═CH—C₆H₅, —CH₂CH₂—NHCOO—CH₂CH═CH₂ and CH₂CH₂O—X (wherein X represents a dicyclopentadienyl residue).

Specific examples of the amide residue include —CH═CH₂, —C(CH₃)═CH₂, —CH₂CH═CH₂, —CH₂CH₂O—Y (wherein Y represents a cyclohexene residue) and —CH₂CH₂OCO—CH═CH₂.

The monomer having a crosslinking group of the polymer resin for the undercoat layer is preferably the above-described acrylic or methacrylic acid ester or amide having a crosslinking group.

The content of the crosslinking group (content of radical-polymerizable unsaturated double bond determined by iodine titration) in the polymer resin for the undercoat layer is preferably from 0.1 to 10.0 mmol, more preferably from 1.0 to 7.0 mmol, and most preferably from 2.0 to 5.5 mmol, per g of the polymer resin. Within this range, both good sensitivity and good staining resistance can be satisfied, and good storage stability can be obtained.

The mass average molar mass of the polymer resin for the undercoat layer is preferably 5,000 or more, more preferably from 10,000 to 300,000, and the number average molar mass is preferably 1,000 or more, more preferably from 2,000 to 250,000. The polydispersity (mass average molar mass/number average molar mass) is preferably from 1.1 to 10.

The polymer resin for the undercoat layer may be any polymer such as random polymer, block polymer or graft polymer, but is preferably a random polymer.

One of polymer resins for undercoating may be used alone, or two or more kinds thereof may be mixed and used.

The coating solution for undercoat layer is obtained by dissolving the above-described polymer resin for undercoating in an organic solvent (e.g., methanol, ethanol, acetone, methyl ethyl ketone) and/or water.

The coating solution for undercoat layer may also contain an ultraviolet absorbent.

As for the method of coating the coating solution for undercoat layer on a support, various known methods may be used. Examples thereof include bar coater coating, spin coating, spray coating, curtain coating, dip coating, air knife coating, blade coating and roll coating.

The coated amount (as solid content) of the undercoat layer is preferably from 0.1 to 100 mg/m², more preferably from 1 to 30 mg/m².

### [Printing Method]

The lithographic printing plate produced by applying the development of the present invention after exposure is loaded on a plate cylinder of a printing press and used for printing a large number of sheets by supplying a fountain solution and a printing ink.

### EXAMPLES

The present invention is described in greater detail below by referring to the Examples, but the present invention should not be construed as being limited thereto.

### <Production of Lithographic Printing Plate Precursor (1)>

### (1) Production of Support (1)

A 0.3 mm-thick aluminum plate (material: JIS A 1050) was subjected to a degrease treatment with an aqueous 10 mass % sodium aluminate solution at 50° C. for 30 seconds so as to remove rolling oil on the surface thereof. Subsequently, the aluminum plate surface was grained using three nylon brushes implanted with bundled bristles having a diameter of 0.3 mm and an aqueous suspension (specific gravity: 1.1 g/cm³) of pumice having a median diameter of 25 μm and then thoroughly washed with water. This plate was etched by dipping it in an aqueous 25 mass % sodium hydroxide solution at 45° C. for 9 seconds and after washing with water, dipped in 20 mass % nitric acid at 60° C. for 20 seconds, followed by water washing. At this time, the etching amount of the grained surface was about 3 g/m².

Thereafter, the aluminum plate was subjected to a continuous electrochemical surface-roughening treatment using an AC voltage of 60 Hz. The electrolytic solution used was an aqueous 1 mass % nitric acid solution (containing 0.5 mass % of aluminum ion) at a liquid temperature of 50° C. The electrochemical surface-roughening treatment was performed using a rectangular wave AC having a trapezoidal waveform such that the time TP necessary for the current value to reach the peek from zero was 0.8 msec and the duty ratio was 1:1, by disposing a carbon electrode as the counter electrode. The auxiliary anode used was a ferrite. The current density was 30 A/dm² in terms of the peak value of current, and 5% of the current flowing from the power source was split into the auxiliary anode. The quantity of electricity at the nitric acid electrolysis was 175 C/dm² when the aluminum plate was serving as the anode. The aluminum plate was then washed with water by spraying.

Subsequently, the aluminum plate was subjected to an electrochemical surface roughening treatment in the same manner as in the nitric acid electrolysis above by using, as the electrolytic solution, an aqueous 0.5 mass % hydrochloric acid solution (containing 0.5 mass % of aluminum ion) at a liquid temperature of 50° C. under the conditions that the quantity of electricity was 50 C/dm² when the aluminum plate was serving as the anode, and then washed with water by spraying.

Next, this plate was treated in 15 mass % sulfuric acid (containing 0.5 mass % of aluminum ion) as the electrolytic solution at a current density of 15 A/dm² to provide a DC anodic oxide film of 2.5 g/m², then washed with water and dried.

Furthermore, this plate was subjected to a pore-sealing treatment by blowing water vapor at 100° C. on the anodic oxide film under a pressure of 1.033×10⁵ Pa for 8 seconds.

Thereafter, the plate was subjected to a silicate treatment using an aqueous 2.5 mass % No. 3 sodium silicate solution at 75° C. for 6 seconds so as to ensure hydrophilicity of the non-image part. The amount of Si attached was 10 mg/m². The plate was then washed with water to obtain Support (1). The centerline average roughness (Ra) of the thus-obtained substrate was measured using a stylus of 2 μm in diameter and found to be 0.51 μm.

### (2) Formation of Undercoat Layer

Coating Solution (1) for Undercoat Layer shown below was coated on Support (1) to have a dry coated amount of 20 mg/m², whereby a support used in the following tests was produced.

-Coating Solution (1) for Undercoat Layer-

| | | |
|---|---|---|
| Compound (1) for Undercoat Layer having a structure | 0.18 | g |
| shown below | | |
| Methanol | 55.24 | g |
| Water | 6.15 | g |

Compound (1) for Undercoat Layer:

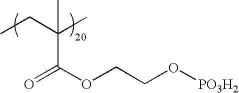

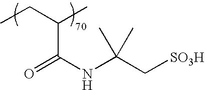

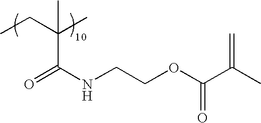

### (3) Formation of Image Forming Layer

On the undercoat layer formed as above, Coating Solution (1) for Image Forming Layer having the following composition was bar-coated and then dried in an oven at 100° C. for 60 seconds to form an image forming layer having a dry coated amount of 1.0 g/m².

Coating Solution (1) for Image Forming Layer was obtained by mixing and stirring Photosensitive Solution (1) and Microgel Solution (1) shown below immediately before coating.

-Coating Solution (1) for Image Forming Layer-

| | |
|---|---|
| Binder Polymer (1) [having a structure shown below:] | 0.240 g |
| Carboxylic acid compound of the present invention shown in | 0.060 g |
| Table 1 below | |
| Infrared Absorber (1) [having a structure shown below] | 0.030 g |
| Polymerization initiator (Compound I-28) | 0.162 g |
| Polymerizable compound | 0.192 g |
| [tris(acryloyloxyethyl)isocyanurate] (NK ESTER A-9300, | |
| produced by Shin-Nakamura Chemical Co., Ltd.) | |
| Tris(2-hydroxyethyl)isocyanurate | 0.062 g |
| Pionin A-20 (produced by Takemoto Yushi Co., Ltd.) | 0.055 g |
| Benzyl-dimethyl-octyl ammonium PF₆ salt | 0.018 g |
| Fluorine-Containing Surfactant (1) [having a structure shown | 0.008 g |
| below] | |
| Methyl ethyl ketone | 1.091 g |
| 1-Methoxy-2-propanol | 8.609 g |

<Microgel Solution (1)>

| | |
|---|---|
| Microgel (1) | 2.640 g |
| Distilled water | 2.425 g |

Structures of Infrared Absorber (1), Binder Polymer (1) and Fluorine-Containing Surfactant (1) are shown below.

### Binder Polymer (1):

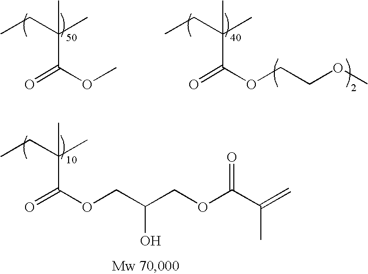

### Infrared Absorber (1):

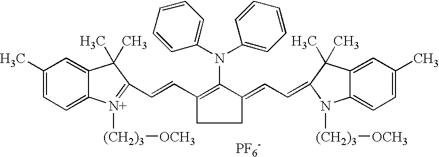

### Fluorine-Containing Surfactant (1):

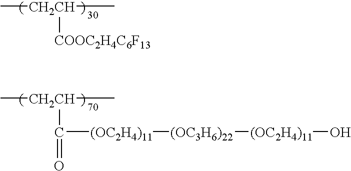

Microgel (1) was synthesized as follows.

### —Synthesis of Microgel (1)—

As the oil phase component, 10 g of trimethylolpropane and xylene diisocyanate adduct (Takenate D-110N, produced by Mitsui Takeda Chemicals, Inc.), 3.15 g of pentaerythritol triacrylate (SR444, produced by Nippon Kayaku Co., Ltd.), 0.1 g of Pionin A-41C (produced by Takemoto Yushi Co., Ltd.) were dissolved in 17 g of ethyl acetate. As the aqueous phase component, 40 g of an aqueous 4 mass % PVA-205 solution was prepared. The oil phase component and the aqueous phase component were mixed and emulsified in a homogenizer at 12,000 rpm for 10 minutes. The resulting emulsified product was added to 25 g of distilled water, and the mixture was stirred at room temperature for 30 minutes and then stirred at 50° C. for 3 hours. The thus-obtained microgel solution was diluted with distilled water to a solid content concentration of 15 mass %. This was used as Microgel (1). The average particle diameter of the microgel was measured by a light scattering method, as a result, the average particle diameter was 0.2 μm.

### (3) Formation of Protective Layer

Coating Solution (1) for Protective Layer having the following composition was bar-coated on the image forming layer formed above and then dried in an oven at 120° C. for 60 seconds to form a protective layer having a dry coated amount of 0.15 g/m², thereby obtaining Lithographic Printing Plate Precursor (1).

-Coating Solution (1) for Protective Layer-

| | |
|---|---|
| Inorganic Layered Compound Liquid Dispersion (1) | 1.5 g |
| Polyvinyl alcohol (CKS50, produced by The Nippon | 0.55 g |
| Synthetic Chemical Industry Co., Ltd., modified with sulfonic | |
| acid, saponification degree: 99 mol % or more, polymerization | |
| degree: 300), 6 mass % aqueous solution | |
| Polyvinyl alcohol (PVA-405, produced by Kuraray Co., Ltd., | 0.03 g |
| saponification degree: 81.5 mol %, polymerization degree: | |
| 500), 6 mass % aqueous solution | |
| Surfactant (Emalex 710, produced by Nihon Emulsion Co., | 0.86 g |
| Ltd.), 1 mass % aqueous solution | |
| Ion-exchanged water | 6.0 g |

### —Preparation of Inorganic Layered Compound Liquid Dispersion (1)—

In 193.6 g of ion-exchanged water, 6.4 g of synthetic mica, SOMASIF ME-100 (produced by CO-OP Chemical Co., Ltd.), was added and dispersed using a homogenizer until the average particle diameter (according to a laser scattering method) became 3 μm. The aspect ratio of the resulting dispersed particle was 100 or more.

### <Glossary of Chemicals Used in Tests Below>

Byk 335: A modified dimethyl polysiloxane copolymer in a 25 mass % xylene/methoxypropyl acetate solution, available from Byk-Chemie USA Inc. (Wallingford, Conn.).

DESMODUR N100: An aliphatic polyisocyanate resin based on hexamethylene diisocyanate, available from Bayer Corp. (Milford, Conn.).

ELVACITE 4026: A 10 mass % 2-butanone solution of highly-branched poly(methyl methacrylate), available from Lucite International, Inc. (Cordova, Tenn.).

Hydroxypropyl cellulose: A 2% aqueous solution of hydroxypropyl cellulose with 1,000 to 4,000 cP, produced by Wako Pure Chemical Industries, Ltd.

Mercapto-3-triazole: Mercapto-3-triazole-1H,2,4, available from PCAS (Paris, France)

PEGMA: Poly(ethylene glycol) methyl ether methacrylate, as a 50 mass % aqueous solution, average Mn: up to 2,080, available from Sigma-Aldrich Corp. (St. Louis, Mo.).

SARTOMER 355: Ditrimethylolpropane tetraacrylate, available from Sartomer Japan, Inc.

Urethane acrylate: A 80 mass % 2-butane solution of urethane acrylate obtained by reaction of DESMODUR N100 with hydroxyethyl acrylate and pentaerythritol triacrylate.

V-601: V-601 (dimethyl 2,2′-azobis(2-methylpropionate)) produced by Wako Pure Chemical Industries, Ltd.

### <Production of Lithographic Printing Plate Precursor (2)>

### (1) Production of Support (2)

An aluminum plate treated until electrochemical surface-roughening treatment in the same manner as in the production of Support (1) was treated in 2.5 M phosphoric acid as the electrolytic solution at a voltage of 50 V and a maximum current density of 2 A/dm² to provide a DC anodic oxide film of 1.5 g/m², then washed with water and dried.

Subsequently, this plate was subjected to a pore-sealing treatment by blowing water vapor at 100° C. on the anodic oxide film under a pressure of 1.0×10⁵ Pa for 15 seconds.

Thereafter, the plate was dipped in an aqueous 1.0 mass % polyacrylic acid solution at a liquid temperature of 25° C. for 8 seconds, then water washed and dried to obtain Support (2).

### (2) Formation of Undercoat Layer, Image Forming Layer and Protective Layer

Using Support (2), Lithographic Printing Plate Precursor (2) was obtained by providing an undercoat layer, an image forming layer and a protective layer in the same manner as in Lithographic Printing Plate Precursor (1) except for changing Coating Solution (1) for Image Forming Layer to the following Coating Solution (2) for Image Forming Layer.

Coating Solution (2) for Image Forming Layer was obtained by mixing and stirring Photosensitive Solution (2) shown below and 14.00 g of Polymer Fine Particle Liquid Dispersion (1) prepared as follows, immediately before coating.

-Photosensitive Solution (2)-

| | |
|---|---|
| Binder Polymer (2) | 3.97 g |
| Carboxylic acid compound of the present invention shown in | 0.25 g |
| Table 1 below | |
| Urethane acrylate | 2.48 g |
| Polymerization initiator (Compound I-40) | 0.32 g |
| Infrared Absorber (2) shown below | 0.13 g |
| Mercapto-3-triazole | 1.00 g |
| BYK 335 | 0.60 g |
| Hydroxypropyl cellulose | 3.31 g |
| n-Propanol | 61.97 g |
| Water | 13.41 g |

### —Synthesis of Binder Polymer (2)—

2-Butanone (384.1 g) and 8.5 g of PEGMA were charged into a 1-L four-necked flask in an N₂ atmosphere and heated at 80° C. A pre-mixture of allyl methacrylate (38.0 g) and V-601 (0.3 g) was added thereto at 80° C. over 90 minutes. After the completion of addition, 0.13 g of V-601 was added. Thereafter, 0.13 g of V-601 was further added two times. The conversion to polymer was >98 mass % based on the percent nonvolatile content.

The molecular weight of Binder Polymer (2) obtained was measured, as a result, Mw was 45,000.

### —Production of Polymer Fine Particle Liquid Dispersion (1)—

A solution of 20 g of PEGMA dissolved in a mixture of 190 g of deionized water and 200 g of n-propanol was charged into a 1,000-mL four-necked flask and heated slowly to slight reflux (up to 73° C.) in an N₂ atmosphere. A mixture obtained by pre-mixing styrene (9 g), acrylonitrile (81 g) and V-601 (0.7 g) was added over 2 hours. After 6 hours, V-601 (0.5 g) was further added. The temperature was raised to 80° C. Subsequently, V-601 was further added two times (0.35 g each) over 6 hours. After the reaction over 19 hours in total, the conversion to copolymer was >98 mass % based on the measurement of percent nonvolatile content. The mass ratio of PEGMA/styrene/acrylonitrile was 10:9:81 and the ratio of n-propanol/water was 50:50. The proportion of the residual acrylonitrile in the solution was 0.08% based on the measurement by ¹H-NMR. Liquid Dispersion (1) produced in this way contained 21.6 mass % of polymer fine particle.

The particle size and molecular weight of Polymer Fine Particle (1) obtained were measured, as a result, the average particle diameter was 225 nm and Mw was 193,000.

### <Production of Lithographic Printing Plate Precursor (3)>

### (1) Production of Support (3)

The polyacrylic acid treatment in the production of Support (2) was changed to a polyvinyl phosphonic acid treatment. That is, an aluminum plate before entering the polyacrylic acid treatment in the production of Support (2) was dipped in an aqueous 0.4 mass % polyvinyl phosphonic acid solution at a liquid temperature of 50° C. for 10 seconds, then water washed and dried to obtain Support (3).

### (2) Formation of Image Forming Layer

Without providing an undercoat layer, the following Coating Solution (3) for Image Forming Layer was coated directly on Support (3) and then dried in an oven at 90° C. for 90 seconds to provide an image forming layer having a dry coated amount of 1.5 g/m², whereby Lithographic Printing Plate Precursor (3) was obtained. In Lithographic Printing Plate Precursor (3), a protective layer was not provided.

-Coating Solution (3) for Image Forming Layer-

| | |
|---|---|
| Binder Polymer (2) | 3.97 g |
| Carboxylic acid compound of the present invention shown in | 0.25 g |
| Table 1 | |
| Urethane acrylate | 2.48 g |
| ELVACITE 4026 | 3.31 g |
| Polymerization initiator (Compound I-40) | 0.32 g |
| Infrared Absorber (2) | 0.13 g |
| Mercapto-3-triazole | 0.18 g |
| BYK 335 | 0.60 g |
| Hydroxypropyl cellulose | 3.30 g |
| SARTOMER 355 | 0.33 g |
| n-Propanol | 62.42 g |
| Water | 13.37 g |

### <Production of Lithographic Printing Plate Precursor (4)>

Lithographic Printing Plate Precursor (4) of Comparative Example was obtained in the same manner as in the production of Lithographic Printing Plate Precursor (3) except for changing Binder Polymer (2) in Coating Solution (3) for Image Forming Layer to polyvinylpyrrolidone (K30, produced by Wako Pure Chemical Industries, Ltd., Mw: 400,000).

### <Exposure>

Lithographic Printing Plate Precursors (1), (2) and (4) obtained were exposed by Luxel PLATESETTER T-6000111 equipped with an infrared semiconductor laser, manufactured by Fujifilm Corp., under the conditions of a rotational number of outer surface drum of 1,000 rpm, a laser output of 70% and a resolution of 2,400 dpi. Also, Lithographic Printing Plate Precursor (3) obtained was exposed by Trendsetter 3244VX equipped with an infrared semiconductor laser, manufactured by Creo, under the conditions of an output of 10 W, a rotation number of outer surface drum of 150 rpm and a resolution of 2,400 dpi. The images used in exposure were prepared to contain a solid image and a fine line image, respectively.

### <Plate-Making Treatment>

### Examples 1 to 29 and Comparative Examples 1 to 9

The exposed printing plate precursor obtained was subjected to a plate-making treatment using an automatic developing apparatus shown in FIG. 1. In the Figure, removal of the non-image part in the developing part 14, water washing in the water washing part 16, and desensitization in the desensitization processing part 18 were performed using the developer, washing water and desensitizing solution shown in Table 1 below.

The developer of the present invention used in the developing part was circulated through a cartridge filter, “TCW-75N-PPS” (mesh size: 75 μm), produced by ADVANTEC by using a pump.

### Examples 30 to 33

The exposed printing plate precursor obtained was subjected to a plate-making treatment of processing the plate in an automatic developing apparatus shown in FIG. 2 and then drying it by a drier. In Examples 30 and 32, a single unit of this automatic developing apparatus was used, and in Examples 31 and 33, two units were connected and used. The developer used is shown in Table 1 below.

### <Evaluation>

Reattachment of the removed non-image part component, initial inking and press life in the plate-making process above were evaluated in the following manner. The evaluation results are shown in Table 1.

### (1) Reattachment of Removed Non-Image Part Component

The surface of the lithographic printing plate after the development processing above was observed with an eye and to what extent the removed non-image part component of the image forming layer reattached was evaluated according to the following indices.

A: Absolutely no reattachment of removed component and very good.

B: Removed component was very slightly observed but easily removable with rag or the like, allowable level.

C: Many removed components were observed and could not be easily removed even by wiping with rag or the like, NG level.

D: A seriously large number of removed components reattached and very bad.

The results are shown in Table 1.

### (2) Initial Inking

Subsequently, the lithographic printing plate after the development processing was loaded on a plate cylinder of a printing press, LITHRONE 26, manufactured by Komori Corp. Using a fountain solution (Ecolity-2, produced by Fujifilm Corp./tap water=2/98 (by volume)) and a black ink (Values-G(N), produced by Dainippon Ink & Chemicals, Inc.), printing was started by supplying the fountain solution and the ink according to the standard automatic printing start method of LITHRONE 26, and printing on 100 sheets of Tokubishi art paper (76.5 kg) was performed at a printing speed of 10,000 sheets per hour. At this time, a printed matter was sampled. The number of printing sheets required until the ink density on the printing sheet in the exposed area region of the image forming layer reached a specified standard density, was evaluated as initial inking. The results are shown in Table 1.

### (3) Press Life

Thereafter, printing was further continued. With an increase in the number of printed sheets, the image forming layer was gradually abraded to decrease the ink density on the printed matter. The number of sheets when the value obtained by measuring the halftone dot area ratio of FM screen 50% halftone dots in the printed matter by means of a Gretag densitometer became 5% lower than the value measured on the 100th sheet was defined as the printing termination and used for the evaluation of press life. The results are shown in Table 1.

As seen from Table 1, in all of Examples 1 to 33 employing the plate-making method using a lithographic printing plate precursor of the present invention, a plate-making method using a lithographic printing plate precursor, in which a good effect of preventing reattachment of a removed component as well as excellent performance in terms of inking property and press life are exhibited, can be obtained.

### Examples 34 to 39 and Comparative Examples 10 and 11

Lithographic Printing Plate Precursors (5) to (11) were produced by coating the coating solution for protective layer of Lithographic Printing Plate Precursor (1) to give a dry coated amount shown in Table 3 and exposed in the same manner as in Example 30.

The exposed printing precursors were processed in the same manner as in Example 30.

Reattachment of the removed non-image part component, initial inking and fine line reproducibility in the plate-making process above were evaluated in the following manner.

### (1) Reattachment of Removed Non-Image Part Component

The surface of the lithographic printing plate after the development processing above was observed with an eye and to what extent the removed non-image part component of the image forming layer reattached was evaluated according to the following indices.

A: Absolutely no reattachment of removed component and very good.

B: Removed component was very slightly observed but easily removable with rag or the like, allowable level.

B′: Many removed components were observed but easily removable with rag or the like, allowable limit level.

C: Many removed components were observed and could not be easily removed even by wiping with rag, NG level.

The results are shown in Table 2.

Subsequently, the lithographic printing plate after the development processing was loaded on a plate cylinder of a printing press, LITHRONE 26, manufactured by Komori Corp. Using a fountain solution (Ecolity-2, produced by Fujifilm Corp./tap water=2/98 (by volume)) and a black ink (Values-G(N), produced by Dainippon Ink & Chemicals, Inc.), printing was started by supplying the fountain solution and the ink according to the standard automatic printing start method of LITHRONE 26, and printing on 100 sheets of Tokubishi art paper (76.5 kg) was performed at a printing speed of 10,000 sheets per hour.

### (2) Initial Inking

Thereafter, the lithographic printing plate after the development processing was loaded on a plate cylinder of a printing press, LITHRONE 26, manufactured by Komori Corp. Using a fountain solution (Ecolity-2, produced by Fujifilm Corp./tap water=2/98 (by volume)) and a black ink (Values-G(N), produced by Dainippon Ink & Chemicals, Inc.), printing was started by supplying the fountain solution and the ink according to the standard automatic printing start method of LITHRONE 26, and printing on 100 sheets of Tokubishi art paper (76.5 kg) was performed at a printing speed of 10,000 sheets per hour. At this time, a printed matter was sampled. The number of printing sheets required until the ink density on the printing sheet in the exposed area region of the image forming layer reached a specified standard density, was evaluated as initial inking. The results are shown in Table 2.

### (2) Fine Line Reproducibility (Adhesion of Image Part)

Printing of 10,000 sheets was performed in the same manner as above. Adhesion of the fine line in the image part on the 10,000th printed matter was examined. That is, in not less than which size (μm) the fine line could be printed was evaluated using a test chart where the size was varied in steps of 5 μm from 5 to 50 μm. A smaller value indicates reproduction of a finer line. It is considered that the oxygen amount in the image forming layer was reduced by virtue of oxygen-blocking effect of the protective layer and good fine line reproducibility was obtained. When 10 μm was reproduced, this is in the allowable range. The results are shown in Table 2.

TABLE 1

| | | Carboxylic | | | | Printing Evaluation Results | | |
|---|---|---|---|---|---|---|---|---|
| | Lithographic | Acid | Development Processing Conditions | | | Reattachment | Initial | Press Life |
| | Printing Plate | Compound* of | Non-Image Part | Water Washing | Desensitizing | of Removed | Inking | (ten thousands |
| Example | Precursor | Invention | Removing Step | Step | Step | Component | (sheets) | of sheets) |
| Example 1 | (1) | C-1 | Developer 1 | fresh water | gum solution | A | 8 | 5.0 |
| Example 2 | (1) | C-4 | Developer 1 | fresh water | gum solution | A | 8 | 4.5 |
| Example 3 | (1) | C-13 | Developer 1 | fresh water | gum solution | A | 5 | 5.0 |
| Example 4 | (1) | A-13 | Developer 1 | fresh water | gum solution | A | 5 | 4.5 |
| Example 5 | (1) | A-25 | Developer 1 | fresh water | gum solution | A | 5 | 5.0 |
| Example 6 | (1) | T-1 | Developer 1 | fresh water | gum solution | A | 5 | 4.5 |
| Example 7 | (1) | T-7 | Developer 1 | fresh water | gum solution | A | 5 | 5.0 |
| Example 8 | (2) | C-1 | Developer 2 | fresh water | gum solution | A | 8 | 4.5 |
| Example 9 | (2) | C-4 | Developer 2 | fresh water | gum solution | B | 8 | 4.0 |
| Example 10 | (2) | C-13 | Developer 2 | fresh water | gum solution | A | 5 | 4.5 |
| Example 11 | (2) | A-13 | Developer 2 | fresh water | gum solution | B | 5 | 4.0 |
| Example 12 | (2) | A-25 | Developer 2 | fresh water | gum solution | A | 5 | 4.5 |
| Example 13 | (2) | T-1 | Developer 2 | fresh water | gum solution | B | 5 | 4.0 |
| Example 14 | (2) | T-7 | Developer 2 | fresh water | gum solution | A | 5 | 4.5 |
| Example 15 | (3) | C-1 | Developer 1 | circulated water | none | A | 15 | 4.0 |
| Example 16 | (3) | C-4 | Developer 1 | circulated water | none | B | 15 | 3.5 |
| Example 17 | (3) | C-13 | Developer 1 | circulated water | none | A | 10 | 4.0 |
| Example 18 | (3) | A-13 | Developer 1 | circulated water | none | B | 10 | 3.5 |
| Example 19 | (3) | A-25 | Developer 1 | circulated water | none | A | 10 | 4.0 |
| Example 20 | (3) | T-1 | Developer 1 | circulated water | none | B | 10 | 3.5 |
| Example 21 | (3) | T-7 | Developer 1 | circulated water | none | A | 10 | 4.0 |
| Example 22 | (1) | C-1 | Developer 3 | fresh water | gum solution | B | 8 | 5.0 |
| Example 23 | (1) | T-7 | Developer 3 | fresh water | gum solution | B | 5 | 5.0 |
| Example 24 | (3) | C-1 | Developer 3 | circulated water | none | B | 15 | 4.0 |
| Example 25 | (3) | T-7 | Developer 3 | circulated water | none | B | 10 | 4.0 |
| Example 26 | (1) | C-1 | Developer 4 | fresh water | gum solution | A | 8 | 4.5 |
| Example 27 | (1) | T-7 | Developer 4 | fresh water | gum solution | A | 5 | 4.5 |
| Example 28 | (3) | C-1 | Developer 4 | circulated water | none | A | 15 | 3.5 |
| Example 29 | (3) | T-7 | Developer 4 | circulated water | none | A | 10 | 3.5 |
| Example 30 | (1) | C-1 | Developer 1 | none | none | B | 8 | 5.0 |
| Example 31 | (1) | C-1 | Developer 1***⁾ | none | none | A | 8 | 5.0 |
| Example 32 | (3) | T-7 | Developer 1 | none | none | B | 10 | 4.0 |
| Example 33 | (3) | T-7 | Developer 1***⁾ | none | none | A | 10 | 3.5 |
| Comparative | (1) | none | Developer 1 | fresh water | gum solution | D | 5 | 4.0 |
| Example 1 | | | | | | | | |
| Comparative | (1) | A**⁾ | Developer 1 | fresh water | gum solution | D | 40 | 3.0 |
| Example 2 | | | | | | | | |
| Comparative | (1) | B**⁾ | Developer 1 | fresh water | gum solution | B | 35 | 3.0 |
| Example 3 | | | | | | | | |
| Comparative | (4) | C-1 | Developer 1 | fresh water | gum solution | B | 35 | 0.5 |
| Example 4 | | | | | | | | |
| Comparative | (3) | C-1 | circulated water | circulated water | none | Development was impossible. | | |
| Example 5 | | | | | | | | |
| Comparative | (3) | none | Aqueous Solution 1 | circulated water | none | D | 5 | 4.0 |
| Example 6 | | | | | | | | |
| Comparative | (3) | C-1 | Aqueous Solution 1 | circulated water | none | D | 10 | 4.0 |
| Example 7 | | | | | | | | |
| Comparative | (3) | none | Aqueous Solution 2 | circulated water | none | D | 5 | 2.0 |
| Example 8 | | | | | | | | |
| Comparative | (3) | C-1 | Aqueous Solution 2 | circulated water | none | D | 10 | 2.0 |
| Example 9 | | | | | | | | |

*Carboxylic acid compound of the present invention; compounds shown in the specification.
**⁾A: Iminodiacetic acid, B: benzoic acid.
***⁾Automatic developing apparatus of FIG. 2 was used by connecting two units.

TABLE 2

| | | Coated | Development Processing Conditions | | | Printing Evaluation Results | | |
|---|---|---|---|---|---|---|---|---|
| | Lithographic | Amount of | | Water | | Reattachment of | Fine Line | Initial |
| | Printing Plate | Protective | Non-Image Part | Washing | Desensitizing | Removed | Reproducibility | Inking |
| Example | Precursor | Layer, g/m² | Removing Step | Step | Step | Component | [μm] | (sheets) |
| Example 34 | (4) | 0.02 | Developer 1 | none | none | B | 10 | 8 |
| Example 35 | (5) | 0.10 | Developer 1 | none | none | B | 5 | 8 |
| Example 30 | (1) | 0.15 | Developer 1 | none | none | B | 5 | 8 |
| Example 36 | (6) | 0.40 | Developer 1 | none | none | B | 5 | 8 |
| Example 37 | (7) | 0.50 | Developer 1 | none | none | level between B | 5 | 8 |
| | | | | | | and B′ | | |
| Example 38 | (8) | 1.00 | Developer 1 | none | none | B′ | 5 | 10 |
| Example 39 | (9) | 3.00 | Developer 1 | none | none | B′ | 5 | 20 |
| Example 12 | (10) | none | Developer 1 | none | none | A | 20 | 8 |
| Example 13 | (11) | 4.00 | Developer 1 | none | none | C | 5 | 50 |

The optimal range of the coated amount of protective layer is from 0.10 to 0.40 g/m² as described above, and the allowable range is from 0.02 to 3.00.

### [Composition of Processing Solution Used in Developing Step]

<Developer 1>

| | | |
|---|---|---|
| Gum arabic | 1.6 | mass % |
| Enzyme-modified potato starch | 8.8 | mass % |
| Phosphorylated waxy corn starch | 0.80 | mass % |
| Sodium salt of dioctylsulfosuccinic acid ester | 0.10 | mass % |
| Citric acid | 0.14 | mass % |
| α-Alanine | 0.11 | mass % |
| EDTA-tetrasodium salt | 0.10 | mass % |
| Disodium salt of dodecyldiphenyl ether disulfonic acid | 0.18 | mass % |
| Ethylene glycol | 0.72 | mass % |
| Benzyl alcohol | 0.87 | mass % |
| Sodium dehydroacetate | 0.04 | mass % |
| Emulsion-type silicone defoaming agent | 0.01 | mass % |
| Water to make | 100 | mass % |

pH: 5.0

<Developer 2>

| | | |
|---|---|---|
| Dowfax 3B2 (produced by Dow Chemical) | 100 | ml |
| Disodium salt of 1,3-benzenesulfonic acid (produced by | 31.25 | g |
| Riedel de Haan) | | |
| Versa TL77 (produced by Alco Chemical, | 31.25 | g |
| polystyrenesulfonic acid) | | |
| Trisodium citrate dihydrate | 10.4 | g |
| Acticide LA1206 (antiseptic produced by Thor) | 2 | ml |
| Polyox WSRN-750 (produced by Union Carbide) | 2.08 | g |
| Penon JE-66 (produced by Nippon Starch Chemical, | 50.0 | g |
| hydroxypropylated enzyme-modified dextrin) | | |
| Water | 1,750 | g |

pH: 7.5

### <Developer 3>

Developer 3 was obtained by adding p-toluenesulfonic acid to Developer 1 to give a pH of 3.0.

### <Developer 4>

Developer 4 was obtained by adding sodium hydroxide to Developer 1 to give a pH of 9.5.

<Aqueous Solution 1>

| | |
|---|---|
| Sodium 7-n-butylnaphthalene-2-sulfate | 300 g |
| Polyethylene oxide-2-naphthyl ether | 100 g |
| Benzyl alcohol | 50 g |
| Water | 9,550 g |

<Aqueous Solution 2>

| | |
|---|---|
| Carboxymethyl cellulose (Mw: 20,000) | 450 g |
| Polyvinylpyrrolidone (K30, produced by Wako Pure | 200 g |
| Chemical, Mw: 400,000) | |
| Pionin D-1305 (produced by Takemoto Yushi Co., Ltd., | 100 g |
| nonionic surfactant) | |
| Water | 9,250 g |

### [Quality of Washing Water Used in Water Washing Step]

### <Fresh Water>

Fresh tap water was always used (no reuse).

### <Circulated Water>

Reused water which was circulated using a pump. After once used in water washing, the water was passed through a cartridge filter, “TCW-75N-PPS” (mesh size: 75 μm), manufactured by ADVANTEC and then reused.

### [Gum Solution in Desensitizing Step]

### <Gum Solution>

Gum solution “FN-6” produced by Fujifilm Corp./tap water 1/1.

What is claimed is:

1. A plate-making method of a lithographic printing plate precursor comprising an image forming layer and a support, the method comprising:
(a) a step of preparing a lithographic printing plate precursor comprising, in the image forming layer, an infrared absorber, a polymerization initiator, a polymerizable compound, a hydrophobic binder polymer and a compound represented by the following formula (1) or (2);
(b) a step of imagewise exposing the lithographic printing plate precursor; and
(C) a step of developing the exposed lithographic printing plate precursor with an aqueous solution comprising at least one water-soluble polymer selected from the group consisting of gum arabic and starch with an automatic processor equipped with a rubbing member: 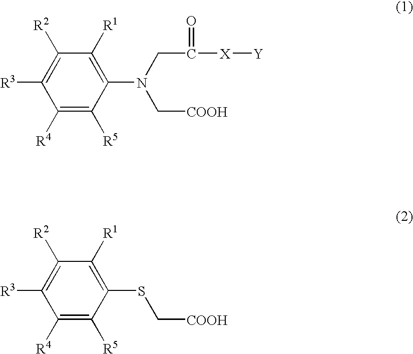
wherein R¹ to R⁵ each independently represents a hydrogen atom, an alkyl group having from 1 to 6 carbon atoms, an alkoxy group having from 1 to 6 carbon atoms, a phenyl group, a halogen atom, an amino group or a nitro group, each of these groups may be partially substituted by an alkyl group having 4 or less carbon atoms or a hydroxyl group, at least two of R¹ to R⁵ may be combined to form an aliphatic or aromatic ring, X represents —O— or —NH—, Y represents a hydrogen atom, an alkyl group having from 1 to 6 carbon atoms, a phenyl group or a benzyl group, and each of these groups may be partially substituted by an alkyl group having 4 or less carbon atoms or a hydroxyl group.

2. The plate-making method of a lithographic printing plate precursor as claimed in claim 1, wherein the compound represented by formula (1) or (2) is at least one compound selected from the group consisting of N-phenyliminodiacetic acid, monomethyl N-phenyliminodiacetate, N-phenyliminodiacetic acid monoanilide and (3,4-dimethoxyphenylthio)acetic acid.

3. The plate-making method of a lithographic printing plate precursor as claimed in claim 1, wherein the aqueous solution has a pH of from 2 to 9.8.

4. The plate-making method of a lithographic printing plate precursor as claimed in claim 1, wherein the aqueous solution comprises gum arabic.

5. The plate-making method of a lithographic printing plate precursor as claimed in claim 1, wherein the step (c) is continuously performed two or more times.

6. The plate-making method of a lithographic printing plate precursor as claimed in claim 1, which further comprises (d) a step of water-washing a surface of the developed lithographic printing plate after the step (c).

7. The plate-making method of a lithographic printing plate precursor as claimed in claim 1, wherein the aqueous solution used in the step (c) is used repeatedly by passing the solution through a filter.

8. The plate-making method of a lithographic printing plate precursor as claimed in claim 1, wherein the infrared absorber is a cyanine dye and the polymerization initiator is an onium salt.

9. The plate-making method of a lithographic printing plate precursor as claimed in claim 1, wherein the lithographic printing plate precursor further comprises a protective layer so that the support, the image forming layer and the protective layer are provided in this order, and the protective layer comprises an anion-modified polyvinyl alcohol in an amount of from 10 to 50 mass % based on an entire solid content of the protective layer.

10. The plate-making method of a lithographic printing plate precursor as claimed in claim 1, wherein the lithographic printing plate precursor further comprises, between the support and the image forming layer, an undercoat layer comprising a compound having a substrate-adsorbing group and a crosslinking group.

11. The plate-making method of a lithographic printing plate precursor as claimed in claim 1, wherein the lithographic printing plate precursor comprises a support treated by anodization with a phosphoric acid.

12. The plate-making method of a lithographic printing plate precursor as claimed in claim 1, wherein the lithographic printing plate precursor comprises a support hydrophilic-treated with a polyvinylsulfonic acid.
